(19) United States
(12) Patent Application Publication
(10) Pub. No.: US 2024/0124770 A1
(43) Pub. Date: Apr. 18, 2024

(54) COMPOUND, GUEST MATERIAL OF LIGHT-EMITTING LAYER, ORGANIC ELECTROLUMINESCENT DEVICE, AND DISPLAY DEVICE

(71) Applicants: Beijing Normal University, Beijing (CN); Yantai-Jingshi Institute of Material Genome Engineering, Yantai, Shandong (CN)

(72) Inventors: Xuebo Chen, Beijing (CN); Chu Wang, Beijing (CN); Lin Shen, Beijing (CN); Juanjuan Wang, Beijing (CN); Yue Chen, Yantai (CN); Weihai Fang, Beijing (CN); Peichuan Feng, Yantai (CN)

(21) Appl. No.: 18/276,166

(22) PCT Filed: Jan. 29, 2022
(86) PCT No.: PCT/CN2022/075003

§ 371 Date: Aug. 7, 2023

(30) Foreign Application Priority Data
Feb. 8, 2021 (CN) 202110183618.6

(51) Int. Cl. C09K 11/06; H10K 50/12

(52) U.S. Cl. CPC C09K 11/06; H10K 50/12; C09K 2211/185

(57) ABSTRACT

The present application provides a compound of general formula (I), capable of being used for an organic electroluminescent device as a guest material of a light-emitting layer. The compound contains a structure in which a natural heterocyclic ring coordinates with iridium (Ir), and a light-emitting wavelength of the compound can be effectively regulated. Using the compound as the guest material of the light-emitting layer facilitates the improvement of luminous efficiency and light stability of the organic electroluminescent device. In addition, the compound provided by the present application has a small molecular weight, is applied to a light-emitting layer, has a low evaporation temperature, and facilitates processing. The present application also provides a guest material of a light-emitting layer containing the compound of general formula (I), an organic electroluminescent device, and a display device.

The present application claims the priority of the Chinese patent application No. 202110183618.6, with the title of “COMPOUND, GUEST MATERIAL OF LIGHT-EMITTING LAYER, ORGANIC ELECTROLUMINESCENT DEVICE, AND DISPLAY DEVICE” filed on Feb. 8, 2021 before the China National Intellectual Property Administration, which is incorporated herein by reference in its entirety.

### TECHNICAL FIELD

The present application relates to the field of organic light-emitting display; in particular to a compound, a guest material of light-emitting layer, an organic electroluminescent device and a display device.

### BACKGROUND OF THE INVENTION

Organic electroluminescent display device (hereinafter referred to as OLED) has a series of advantages, such as self-emission, low-voltage direct current drive, completely curing, wide viewing angle, light weight, simple composition and process and the like. Compared with the liquid crystal display, the organic electroluminescent display does not require backlight, and has a large viewing angle and low power. The response speed of the organic electroluminescent display can reach 1000 times that of the liquid crystal display, while the manufacturing cost is lower than that of the liquid crystal display with the same resolution. Therefore, organic electroluminescent device has a very broad application prospect. With the continuous development of OLED technology in the fields of lighting and display, organic electroluminescent device with a high efficiency and a long lifetime is usually the result of optimal combination of device structure and material. Specifically; the luminescent layer contains a host material and a doped guest material, and the guest material is mainly used to improve the intersystem crossing efficiency between singlet state and triplet state of molecules. However, the guest material of the luminescent layer currently used in OLED has poor luminous efficiency and light stability, and high evaporation temperature of the material, which restricts the display function and development of OLED display device.

### SUMMARY OF THE INVENTION

The objective of the present application is to provide a compound which allows effectively regulating the light-emitting wavelength of the compound, improving the luminous efficiency and light stability of the organic electroluminescent device, and decreasing the evaporation, temperature.

The first aspect of the present application provides a compound having a structure as shown in formula (I):

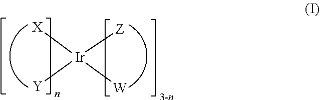

wherein,

X-Y is a diaryl bidentate ligand, a ligating atom for X and Y is C or N, and X-Y is a bivalent radical of a compound or a bivalent radical of a derivative of a compound selected from the group consisting of: 2-(1-naphthyl)benzoxazole, 2-phenylbenzoxazole, 2-phenylbenzothiazole, thienylpyridine, phenylpyridine, benzothiophenpyridine, phenylimine, vinylpyridine, arylquinoline, arylisoquinoline, pyridylnaphthalene, pyridylpyrrole, pyridylimidazole, pyridylindazole, phenylimidazole, phenyltriazole, phenylindole, phenylpyrimidine, phenylpyridazine, bipyridine and biphenyl;

Z-W is a diaryl bidentate ligand containing a natural heterocyclic ring, a ligating atom for Z is C or N, and Z is a bivalent radical of a compound or a bivalent radical of a derivative of a compound selected from the group consisting of: benzene, naphthalene, pyridine, imidazole, pyrrole, tetrahydropyrrole, piperidine, morpholine, quinoline, isoquinoline, pyrimidine, pyrazine, pyridazine, 1,3,4-triazole, tetrazole, oxazole and thiazole; a ligating atom for W is N, and W is a bivalent radical of a compound or a bivalent radical of a derivative of a compound selected from the group consisting of: adenine, guanine, thymine, cytosine and uracil;

n is selected from the group consisting of 0, 1 and 2.

The second aspect of the present application provides a use of the compound provided by the present application as a material for a functional layer of an organic electroluminescent device.

The third aspect of the present application provides a guest material of luminescent layer, comprising at least one of the compound provided by the present application.

The fourth aspect of the present application provides an organic electroluminescent device, comprising at least one of the guest material of luminescent layer provided by the present application.

The fifth aspect of the present application provides a display device, comprising the organic electroluminescent device provided by the present application.

The compound provided by the present application contains a structure in which a natural heterocyclic ring coordinates with iridium (Ir), and a light-emitting wavelength of the compound. can be effectively regulated. The compound is used as the guest material of the light-emitting layer, which facilitates the improvement of luminous efficiency, light stability and service life of the organic electroluminescent device. The display device provided by the present application has excellent display effects. In addition, the compound provided by the present application with a small molecular weight is applied to a light-emitting layer, has a low evaporation temperature, and facilitates processing.

Of course, it is not necessary to achieve all the advantages mentioned above at the same time to implement any product or method of the present application.

### BRIEF DESCRIPTION OF DRAWING

In order to illustrate the technical solution of the present application more clearly, the drawing mentioned in the example is briefly introduced below. Obviously, the drawing in the following description is only an example of the present application.

FIG. 1 is a schematic diagram of the structure of a typical organic electroluminescent device.

### DETAILED DESCRIPTION OF THE INVENTION

In order to make the objective, technical solution and advantage of the present application more clear, the present application will be further described in detail with reference to the drawing and examples. Obviously, the described examples are only a part of the examples of the present application, not all of the examples. Based on the examples of the present application, all other technical solutions obtained by those of ordinary skills in the art belong to the protection, scope of the present application.

The first aspect of the present application provides a compound having a structure as shown in formula (I):

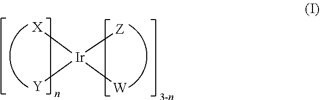

wherein,

X-Y is a diaryl bidentate ligand, a ligating atom for X and Y is C or N, and X-Y is a bivalent radical of a compound or a bivalent radical of a derivative of a compound selected from the group consisting of: 2-(1-naphthyl)benzoxazole, 2-phenylbenzoxazole, 2-phenylbenzothiazole, thienylpyridine, phenylpyridine, benzothiophenpyridine, phenylimine, vinylpyridine, arylquinoline, arylisoquinoline, pyridylnaphthalene, pyridylpyrrole, pyridylimidazole, pyridylindazole, phenylimidazole, phenyltriazole, phenylindole, phenylpyrimidine, phenylpyridazine, bipyridine and biphenyl;

Z-W is a diaryl bidentate ligand containing a natural heterocyclic ring, a ligating atom for Z is C or N, and Z is a bivalent radical of a compound or a bivalent radical of a derivative of a compound selected from the group consisting of: benzene, naphthalene, pyridine, imidazole, pyrrole, tetrahydropyrrole, piperidine, morpholine, quinoline, isoquinoline, pyrimidine, pyrazine, pyridazine, 1,3,4-triazole, tetrazole, oxazole and thiazole; a ligating atom for W is N, and W is a bivalent radical of a compound or a bivalent radical of a derivative of a compound selected from the group consisting of: adenine, guanine, thymine, cytosine and uracil;

n is selected from the group consisting of 0, 1 and 2.

The compound provided by the present application contains a structure in which a natural heterocyclic ring coordinates with iridium (Ir), and a light-emitting wavelength of the compound can be effectively regulated. The compound is used as the guest material of the light-emitting layer, which facilitates the improvement of luminous efficiency, light stability and service life of the organic electroluminescent device.

Preferably, when X-Y is the bivalent radical of a derivative of the compound selected from the group consisting of: 2-(1-naphthyl)benzoxazole, 2-phenylbenzoxazole, 2-phenylbenzothiazole, thienylpyridine, phenylpyridine, benzothiophenpyridine, phenylimine, vinylpyridine, arylquinoline, mylisoquinoline, pyridylnaphthalene, pyridylpyrrole, pyridylimidazole, pyridylindazole, phenylimidazole, phenyltriazole, phenylindole, phenylpyrimidine, phenylpyridazine, bipyridine and biphenyl, the derivative of the compound is a substituted compound, and the substituent is each independently selected from the group consisting of: halogen, unsubstituted alkyl or C₁-C₁₀ alkyl substituted by halogen, unsubstituted C₆-C₁₄ aryl or C₆-C₁₄ aryl substituted by halogen, and unsubstituted C₆-C₁₄ arylalkoxy or C₆-C₁₄ arylalkoxy substituted by halogen;

when Z is the bivalent radical of a derivative of the compound selected from the group consisting of; benzene, naphthalene, pyridine, imidazole, pyrrole, tetrahydropyrrole, piperidine, morpholine, quinoline, isoquinoline, pyrimidine, pyrazine, pyridazine, 1,3,4-triazole, tetrazole, oxazole and thiazole, the derivative of the compound is a substituted compound, and the substituent is each independently selected from the group consisting of: hydrogen, deuterium, halogen, unsubstituted C₁-C₁₀ alkyl or C₁-C₁₀ alkyl substituted by Ra, unsubstituted C₃-C₁₀ cycloalkyl or C₃-C₁₀ cycloalkyl substituted by Ra, unsubstituted C₆-C₁₄ aryl or C₆-C₁₄ aryl substituted by Ra, unsubstituted C₂-C₁₄ heteroaryl or C₂-C 14 heteroaryl substituted by Ra, unsubstituted alkoxy or C₁-C₁₀ alkoxy substituted by Ra, and unsubstituted amino or amino substituted by Ra; the heteroatom in the heteroaryl is selected from the group consisting of O, S and N; the substituent Ra of each group is each independently selected from the group consisting of deuterium, halogen, nitro, cyano, C₁-C₄ alkyl, phenyl, biphenyl, terphenyl and naphthyl;

when W is the bivalent radical of a derivative of the compound selected from the group consisting of: adenine, guanine, thymine, cytosine and uracil, the derivative of the compound is a substituted compound, and the substituent is each independently selected from the group consisting of: hydrogen, deuterium, halogen, unsubstituted alkyl or C₁-C₁₀ alkyl substituted by Ra, unsubstituted. cycloalkyl or C₃-C₁₀ cycloalkyl substituted by Ra, unsubstituted C₆-C₁₄ aryl or C₆-C₁₄ aryl substituted by Ra, unsubstituted C₂-C₁₄ heteroaryl or C₂-C_{1 4} heteroaryl substituted by Ra, unsubstituted alkoxy or C₁-C₁₀ alkoxy substituted by Ra, and unsubstituted amino or amino substituted by Ra; the heteroatom in the heteroaryl is selected from the group consisting of O, S and N; the substituent Ra of each group is each independently selected from the group consisting of deuterium, halogen, nitro, cyano, C₁-C₄ alkyl, phenyl, biphenyl, terphenyl and naphthyl.

In the present application, the above derivative of the compound refer to a compounds in which one or more hydrogen atoms are substituted by the substituent.

More preferably, X-Y is the bivalent radical of the compound selected from the group consisting of: 2-(1-naphthyl)benzoxazole, 2-phenylbenzoxazole, 2-phenylbenzothiazole, thienylpyridine, phenylpyridine, benzothiophenpyridine, phenylimine, vinylpyridine, arylquinoline, arylisoquinoline, pyridylnaphthalene, pyridylpyrrole, pyridylimidazole, pyridylindazole, phenylimidazole, phenyltriazole, phenylindole, phenylpyrimidine, phenylpyridazine, bipyridine, biphenyl, 5-methyl-2-phenylpyridine, 5-methyl-2-(2,4-difluorophenyl)pyridine, 2-(2,4-difluorophenyl)-5-trifluoromethylpyridine, 2-(2,4-difluorophenyl)pyrimidine, 2-(3,4-difluorophenyl)-1-(2,4,6-trimethylphenyl)imidazole, 1,3-diethyl-5-(3-fluorophenyl)triazole, 1-(3,5-dimethylphenyl)isoquinoline, 6-isopropyl-1-(3,5-dimethylphenyl)isoquinoline, 2-(3,5-dimethylphenyl)quinoline, 4-methyl-2-(3,5-dimethylphenyl)quinoline, 2′,4′-difluoro-2,3′-bipyridine, 1-methyl-3-(4-methylphenyl)-2,3-dihydroimidazole, 6-phenyl-3-(2,4,6-trimethylphenoxy)pyridazine, 1-(4-sec-butylphenyl)isoquinoline, 3-isopropyl-2-(3-methylphenyl)quinoline, and 5-methyl-2-(3,5-dimethylphenyl)pyridine.

Preferably, the compound has one of the following general formulae:

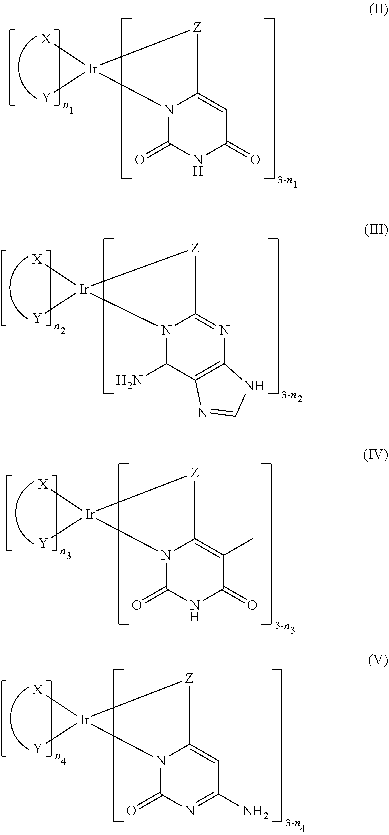

wherein, n₁-n₄ are each independently selected from the group consisting of 0, 1 and 2.

More preferably, the compound has one of the following general formulae:

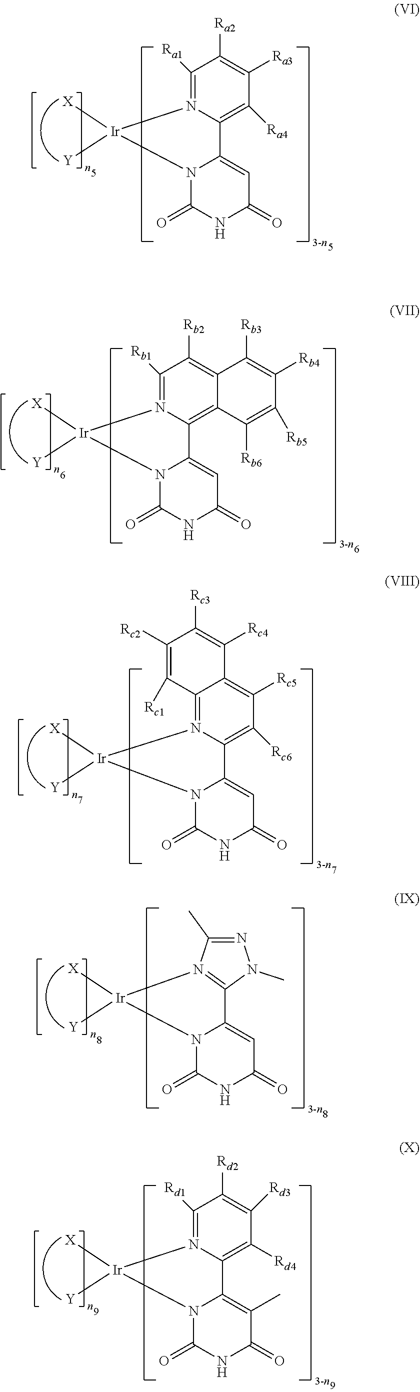

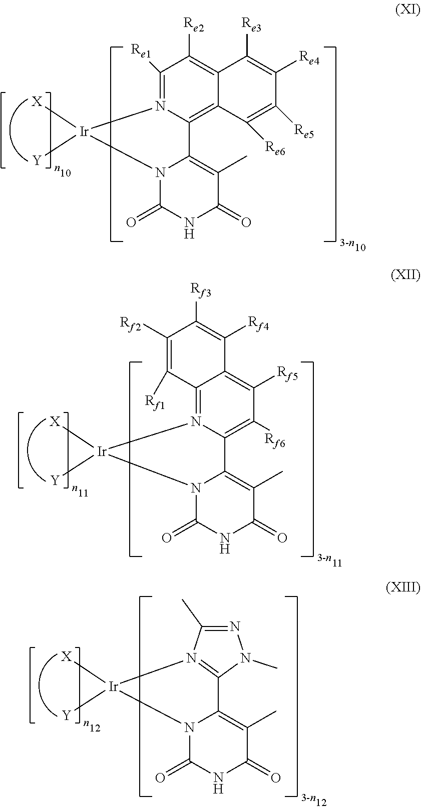

wherein,

Rₐ₁-Rₐ₄, R_{b1}-R_{b6}, R_{c1}-R_{c6}, R_{d1}-R_{d4}, Rₑ₁-Rₑ₆, and R_{f1}-R_{f6} are each independently selected from the group consisting of hydrogen, deuterium, halogen, unsubstituted C₁-C₁₀ alkyl or C₁-C₁₀ alkyl substituted by Ra, unsubstituted C₃-C₁₀ cycloalkyl or C₃-C₁₀ cycloalkyl substituted by Ra, unsubstituted C₆-C₁₄ aryl or C₆-C₁₄ aryl substituted by Ra, unsubstituted C₂-C₁₄ heteroaryl or C₂-C₁₄ heteroaryl substituted by Ra, unsubstituted C₃-C₁₀ alkoxy or C₁-C₁₀ alkoxy substituted by Ra, and unsubstituted amino or amino substituted by Ra;

the heteroatom in the heteroaryl is selected from the group consisting of O, S and N;

the substituent Ra of each group is each independently selected from the group consisting of deuterium, halogen, nitro, cyano, C₁-C₄ alkyl, phenyl, biphenyl, terphenyl and naphthyl;

n₅-n₁₂ are each independently selected from the group consisting of 0, 1 and 2.

For example, the compound is selected from the following structures G1-G30:

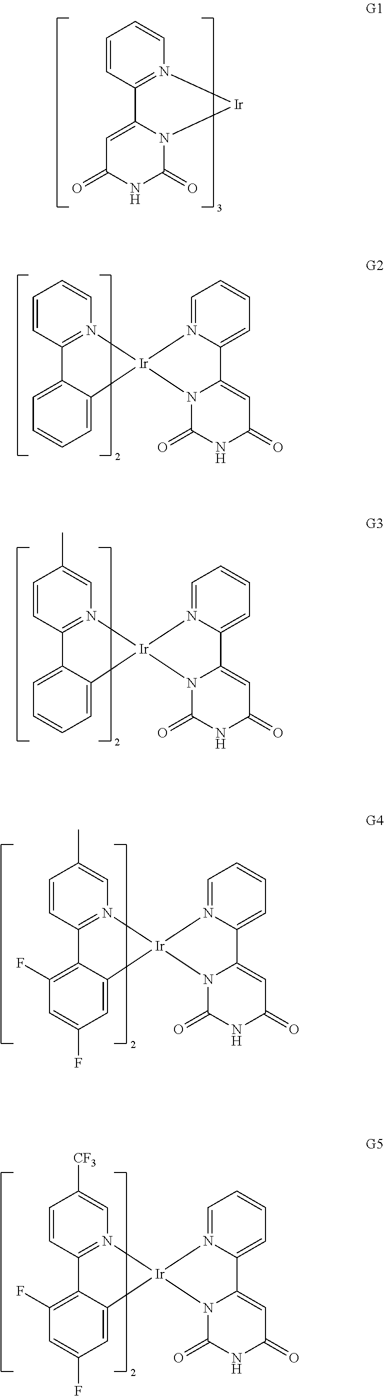

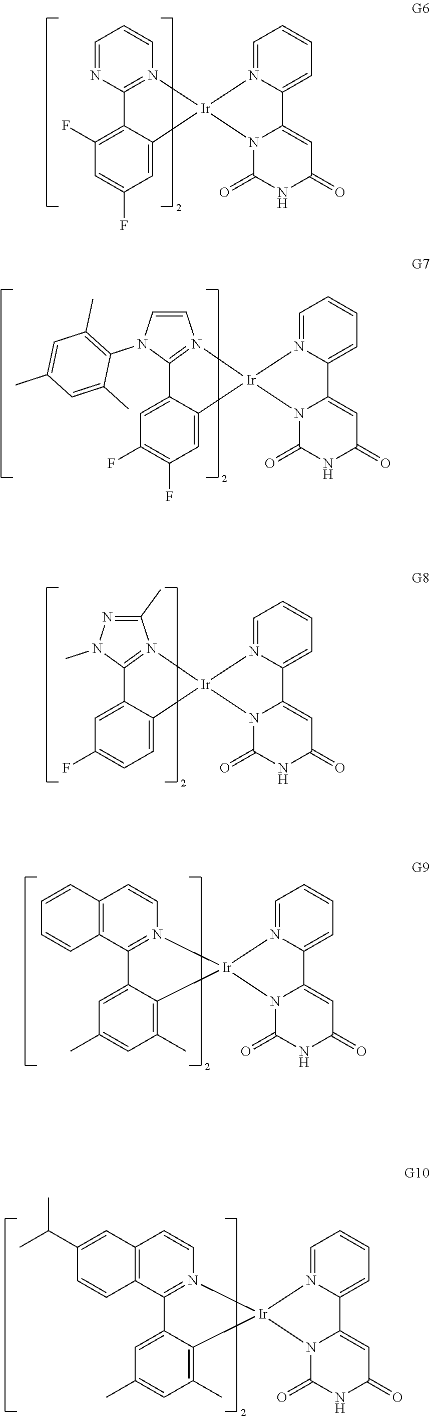

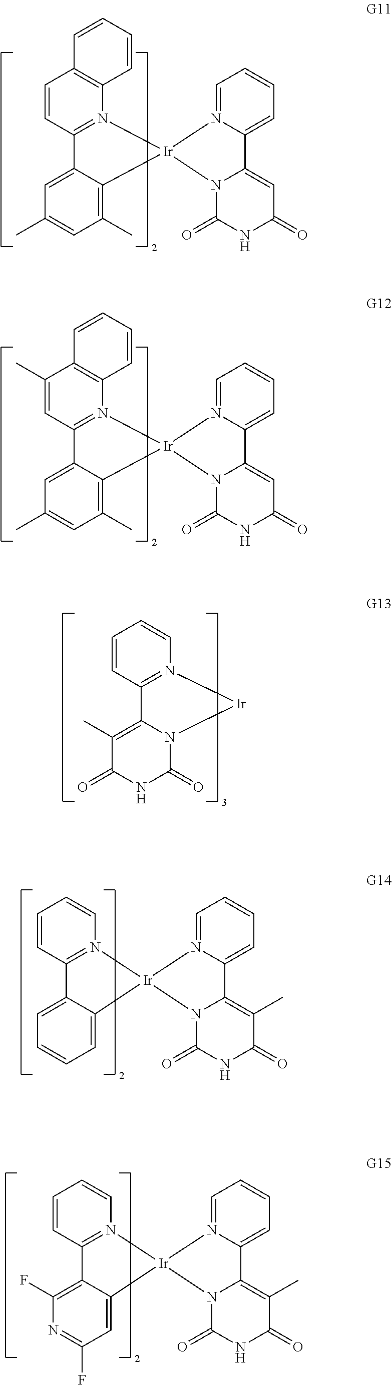

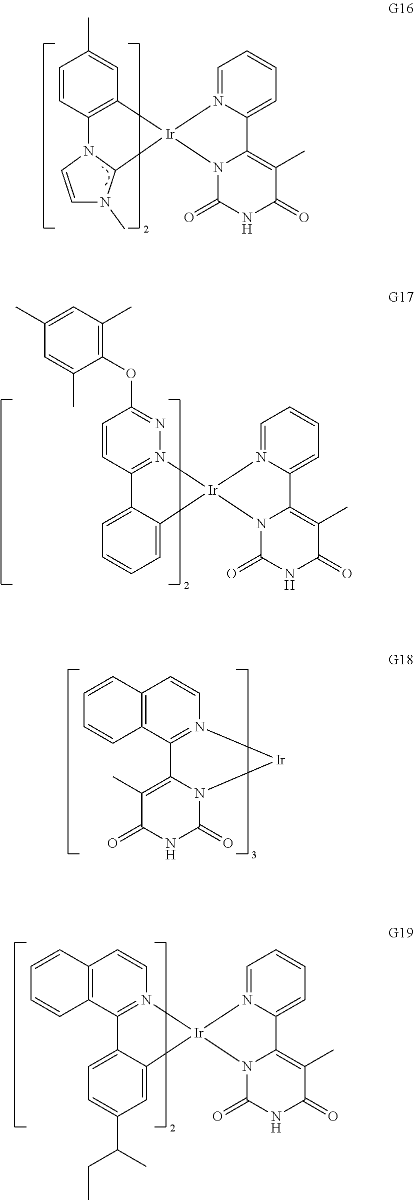

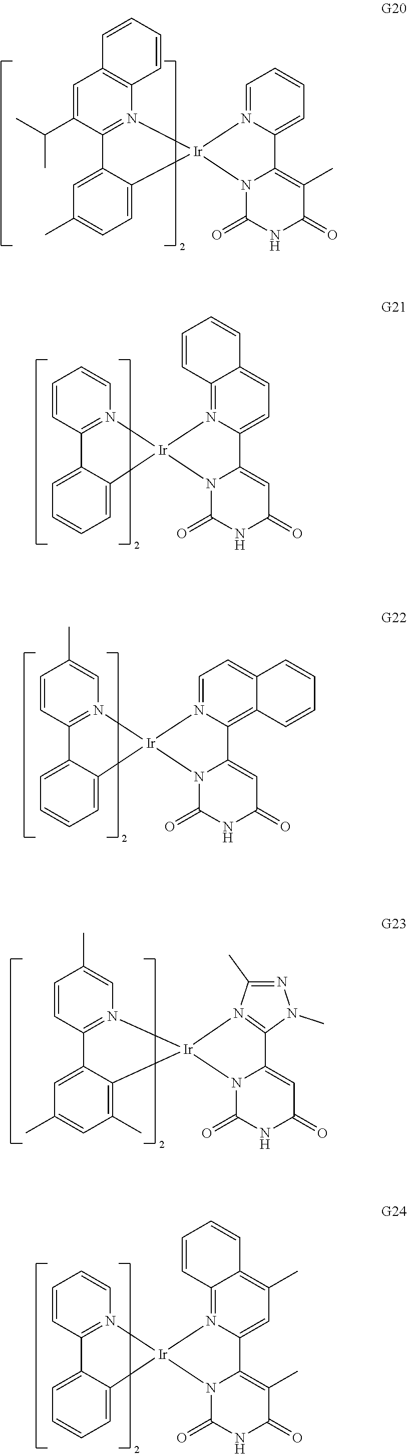

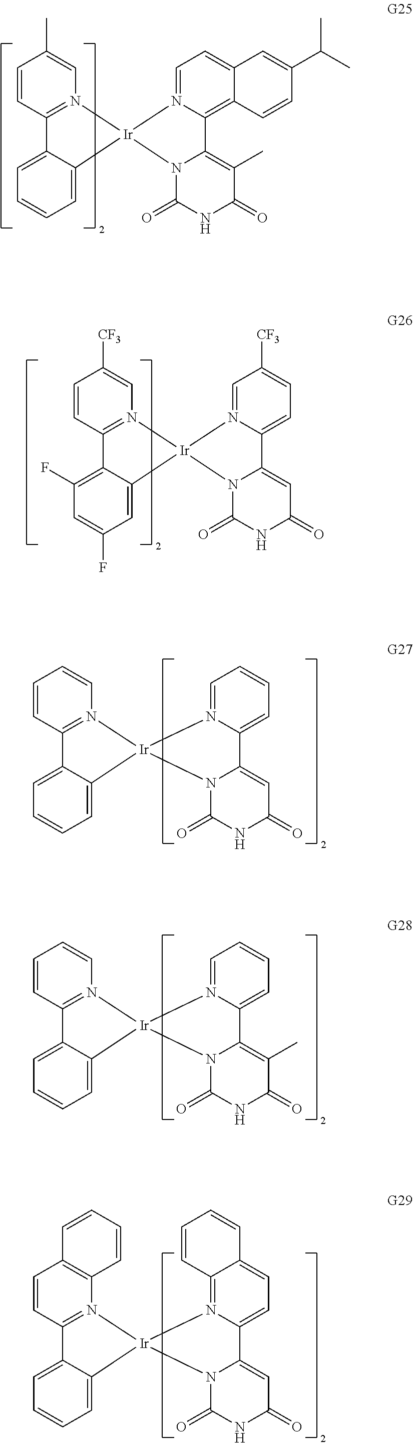

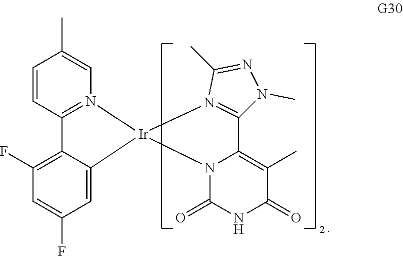

The second aspect of the present application provides a use of the compound provided by the present application as a material for a functional layer of an organic electroluminescent device.

In the present application, the above-mentioned functional layer of the organic electroluminescent device may include a hole injection layer, a hole transport layer, an electron blocking layer, a luminescent layer, a hole blocking layer, an electron transport layer and an electron injection layer and the like, preferably, the functional layer is the luminescent layer, and an evaporation temperature of the luminescent: layer is 330 to 370° C. The compound provided by the present application has a low molecular weight, and thus the evaporation temperature is low, which is beneficial. to the processing of the luminescent layer.

The third aspect of the present application provides a guest material of luminescent layer, comprising at least one of the compound provided by the present application.

The fourth aspect of the present application provides an organic electroluminescent device, comprising at least one of the guest material of luminescent layer provided by the present application.

In the present application, the type and structure of the organic electroluminescent device are not particularly limited, and the organic electroluminescent device can have various types and structures known in the art, as long as at least one of the guest material of the luminescent layer provided by the present application can be used.

The organic electroluminescent device of the present application can be a light-emitting device with a top light-emitting structure, and it can be exemplified that an anode, a hole injection layer, a hole transport layer, a luminescent layer, an electron transport layer, an electron injection layer, and a transparent or translucent cathode are successively included on a substrate.

The organic electroluminescent device of the present application can be also a light-emitting device with a bottom light-emitting structure, and it can be exemplified that a transparent or translucent anode, a hole injection layer, a hole transport layer, a luminescent layer, an electron transport layer, an electron injection layer, and a cathode are successively included on a substrate.

The organic electroluminescent device of the present application can be also a light-emitting device with a two-side light-emitting structure, and it can be exemplified that a transparent or translucent anode, a hole injection layer, a hole transport layer, a luminescent layer, an electron transport layer, an electron injection layer, and a transparent or translucent cathode are successively included on a substrate.

In addition, there is an electron blocking layer between the hole transport layer and the luminescent layer. There is a hole blocking layer between the luminescent layer and the electron transport layer. A light extraction layer is arranged on the transparent electrode on a light-emitting side. However, the structure of the organic electroluminescent device of the present application is not limited to the above specific structure, and if it is necessary, the above layers may be omitted or provided at the same time. For example, the organic electroluminescent device may include an anode made of metal, a hole injection layer (5 nm to 20 nm), a hole transport layer (80 nm to 140 nm), an electron blocking layer (5 nm to 20 nm), a luminescent layer (20 nm to 45 nm), a hole blocking layer (5 nm to 20 nm), an electron transport layer (30 nm to 40 nm), an electron injection layer (0.3 nm to 1 nm), a transparent or translucent cathode and a light extraction layer structure successively on a substrate.

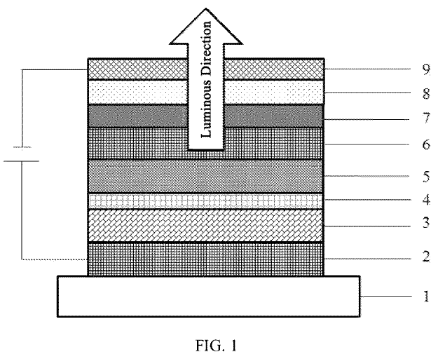

FIG. 1 shows a schematic diagram of a typical organic electroluminescent device, in which a substrate 1, a reflective anode electrode 2, a hole injection layer 3, a hole transport layer 4, an electron blocking layer 5, a luminescent layer 6, a hole blocking layer 7, an electron transport layer 8 and a cathode electrode 9 are successively arranged from bottom to top.

It can be understood that FIG. 1 only schematically shows the structure of a typical organic electroluminescent device. The present application is not limited to this structure, and the guest material of the luminescent layer of the present application can be used for any type of organic electroluminescent device. For example, the organic electroluminescent device can further include an electron injection layer, a light extraction layer and the like. In practical application, these layers can be added or omitted according to specific conditions.

For convenience, the organic electroluminescent device of the present application will be described below with reference to FIG. 1. However, it does not limit the protection scope of the present application. It can be understood that all of organic electroluminescent devices that can use the guest material of the luminescent layer in the present application are within the protection scope of the present application.

In the present application, the material of the substrate 1 is not particularly limited, and conventional substrate used for organic electroluminescent device in the prior art can be used, such as glass, polymer material, glass and polymer material with TFT component, and the like.

In the present application, the material of the reflective anode electrode 2 is not particularly limited, and can be selected from the group consisting of transparent conductive material known. in the prior art, such as indium tin oxide (ITO), indium zinc oxide (IZO), tin dioxide (SnO₂), zinc oxide (ZnO), low-temperature polysilicon (LTPS); metallic material such as silver and alloys thereof, aluminum and alloys thereof; and organic conductive material such as poly 3,4-ethylenedioxythiophene (PEDOT); or the reflective anode electrode is a multi-layer structure made of the above materials. The number of layers of the multi-layer structure is not particularly limited in the present application, which can be selected according to the actual requirements, as long as the objective of the present application can be achieved. For example, there can be 1 layer, 2 layers, 3 layers or more layers.

In the present application, the material of the hole injection layer 3 is not particularly limited, and the hole injection layer material known in the art can be used. For example, a hole transport material (HTM) is selected as the hole injection material.

In the present application, the hole injection layer 3 may further include a p-type dopant. The type of the p-type dopant is not particularly limited, and various p-type dopants known in the art can be used. For example, the following p-type dopants can be used:

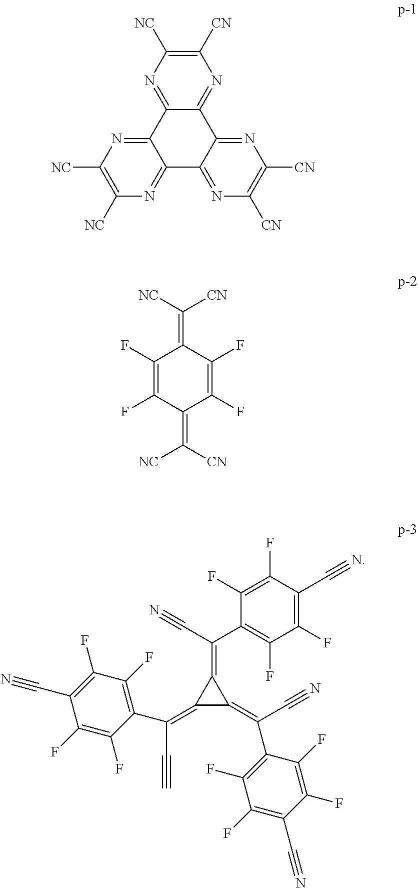 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; C#C/C(=C1\C(=C(\C#N)c2c(F)c(F)c(C#N)c(F)c2F)\C1=C(\C#N)c1c(F)c(F)c(C#N)c(F)c1F)c1c(F)c(F)c(C#N)c(F)c1F]

In the present application, the amount of the p-type dopant is not particularly limited, and can be an amount known to those skilled in the art.

In the present application, the material of the hole transport layer 4 is not particularly limited, and can be a hole transport material (HTM) known in the art. The number of layers of the hole transport layer 4 is not particularly limited, which can be adjusted according to the actual requirements, as long as the objective of the present application can be achieved. For example, there can be 1 layer, 2 layers, 3 layers, 4 layers or more layers. For example, the material of the hole injection layer and the material of the hole transport layer may be selected from at least one of the following compounds HT-1 to HT-34:

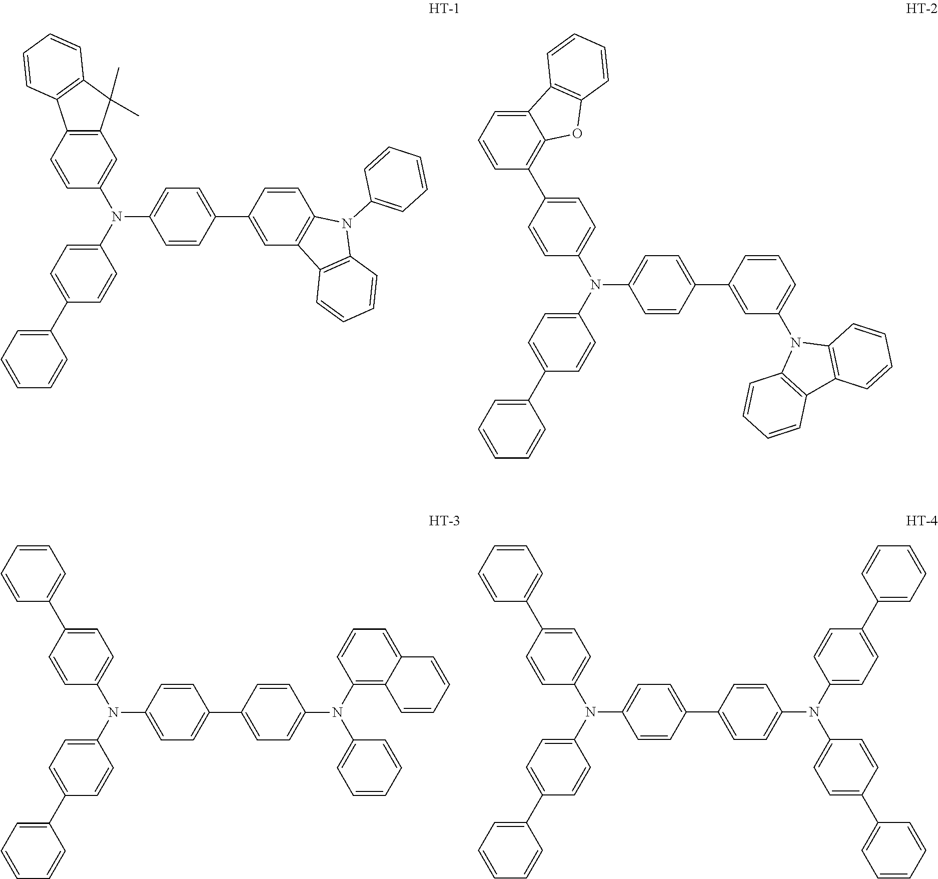 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

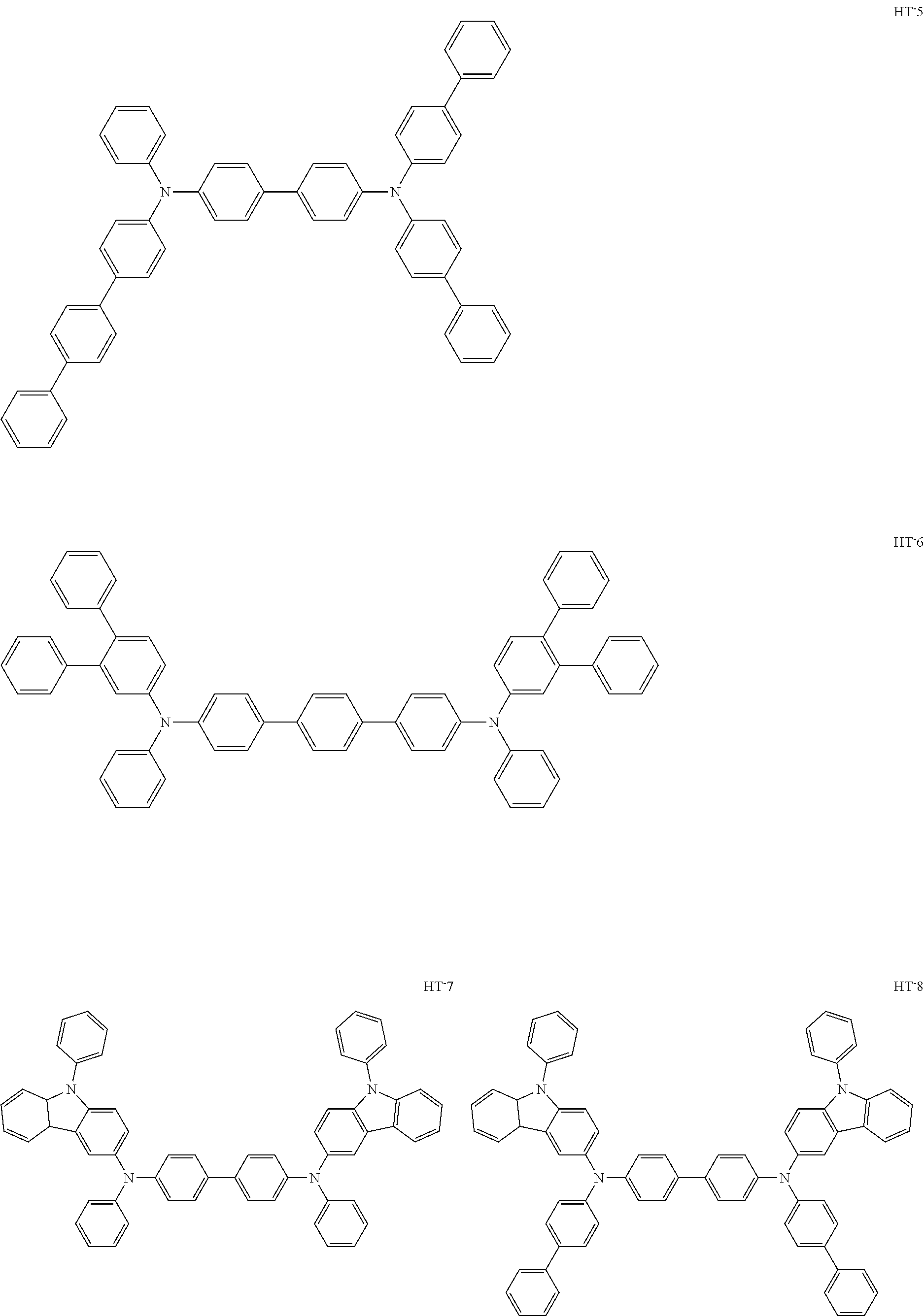

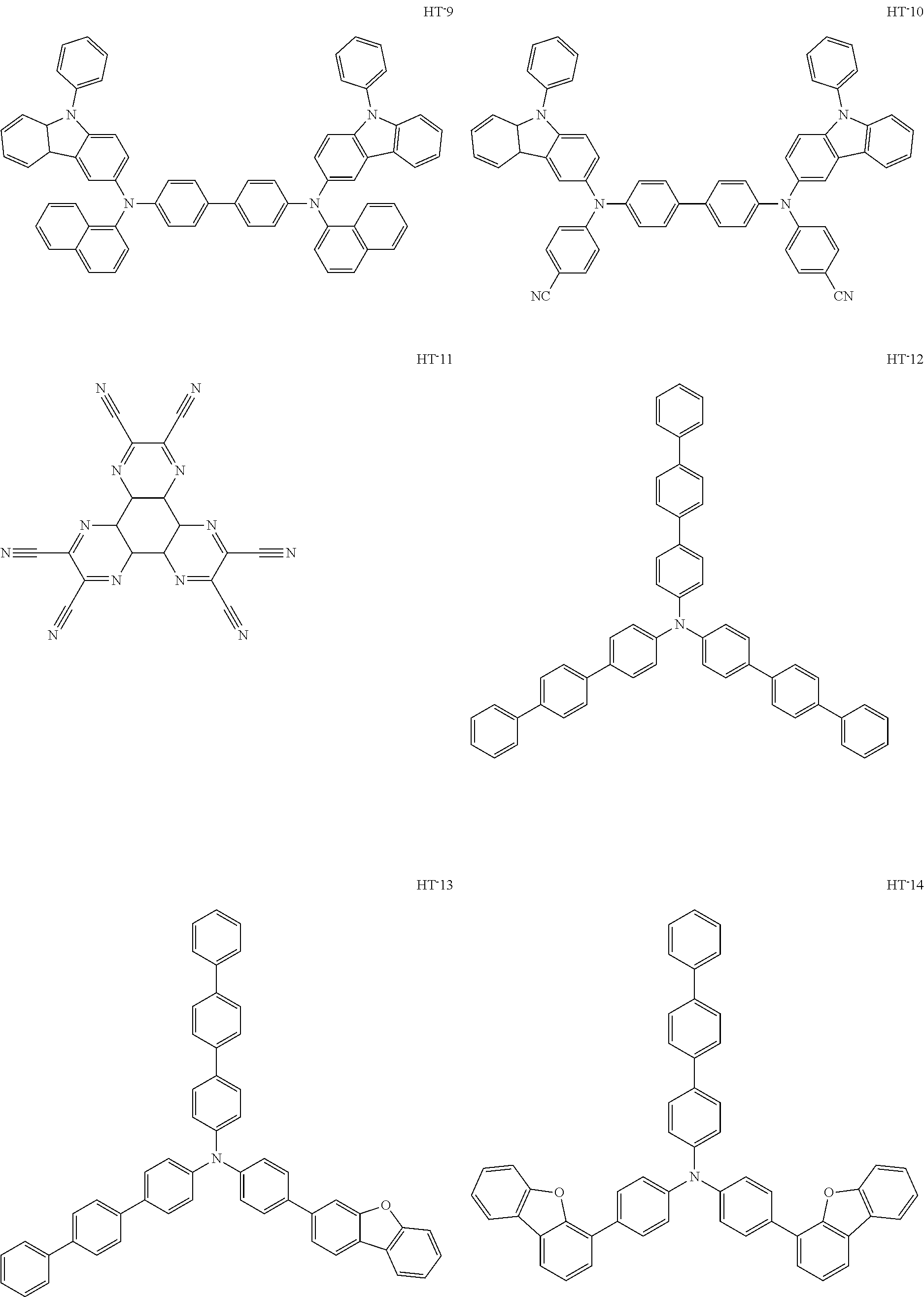

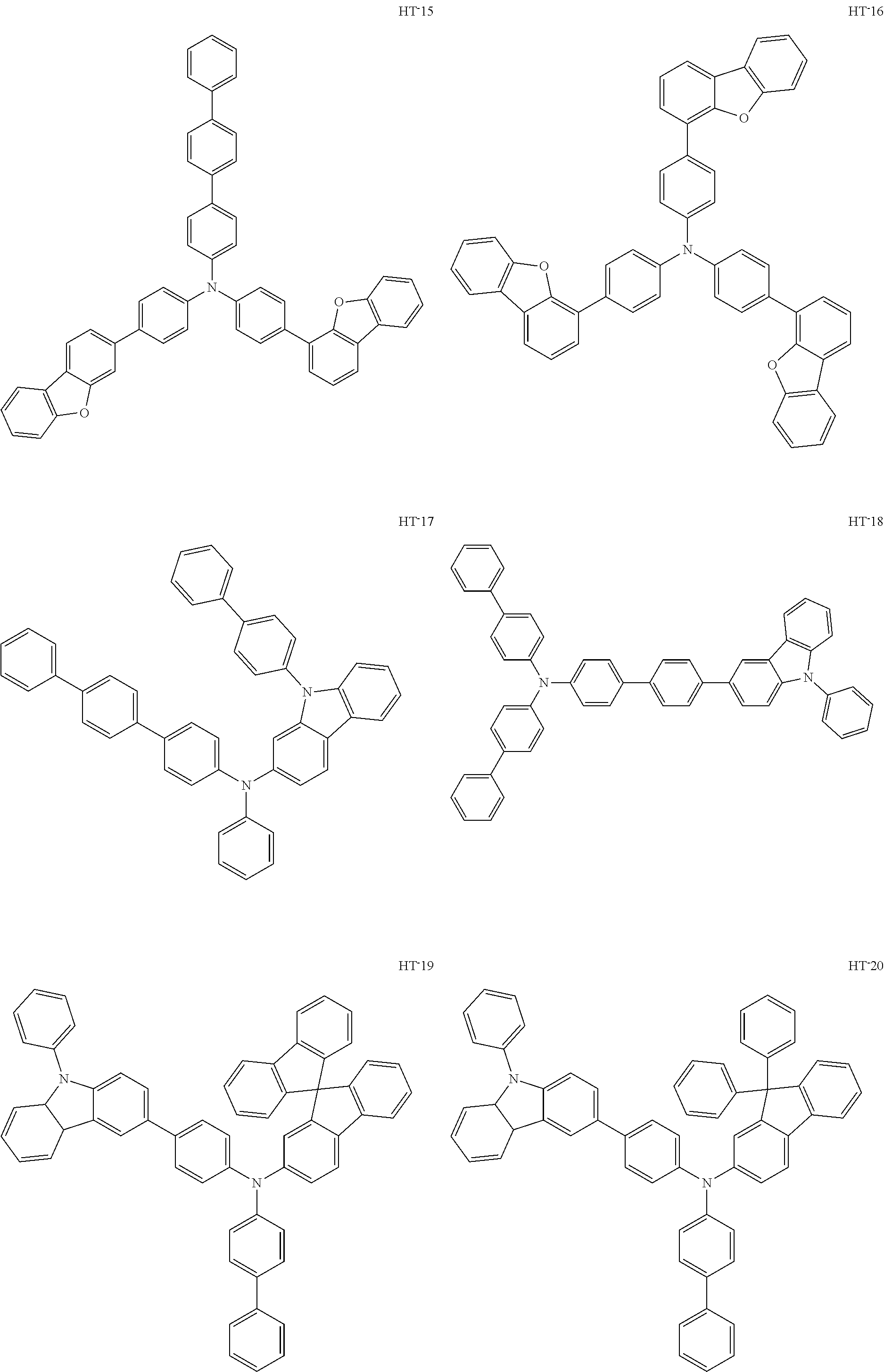

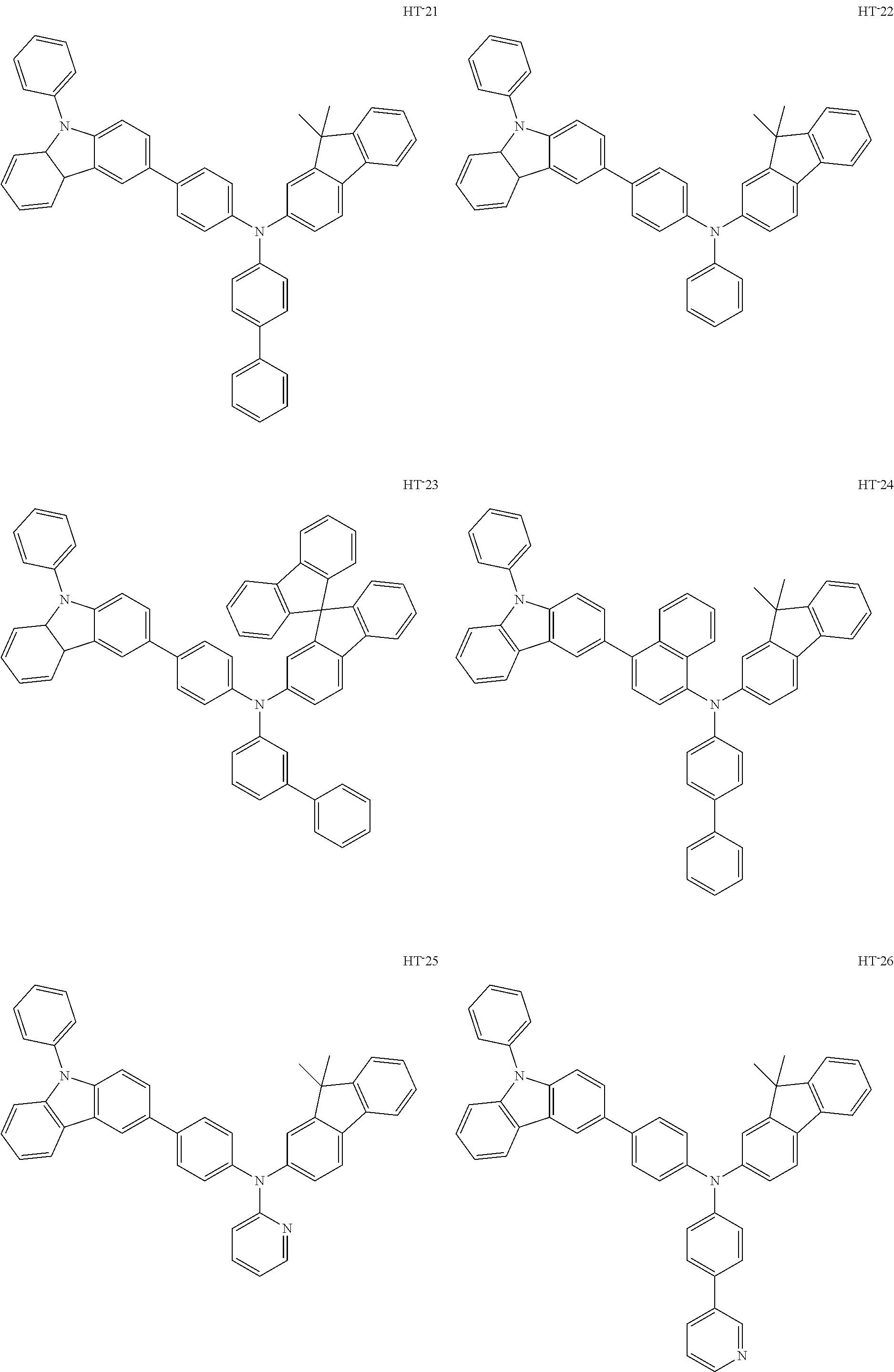

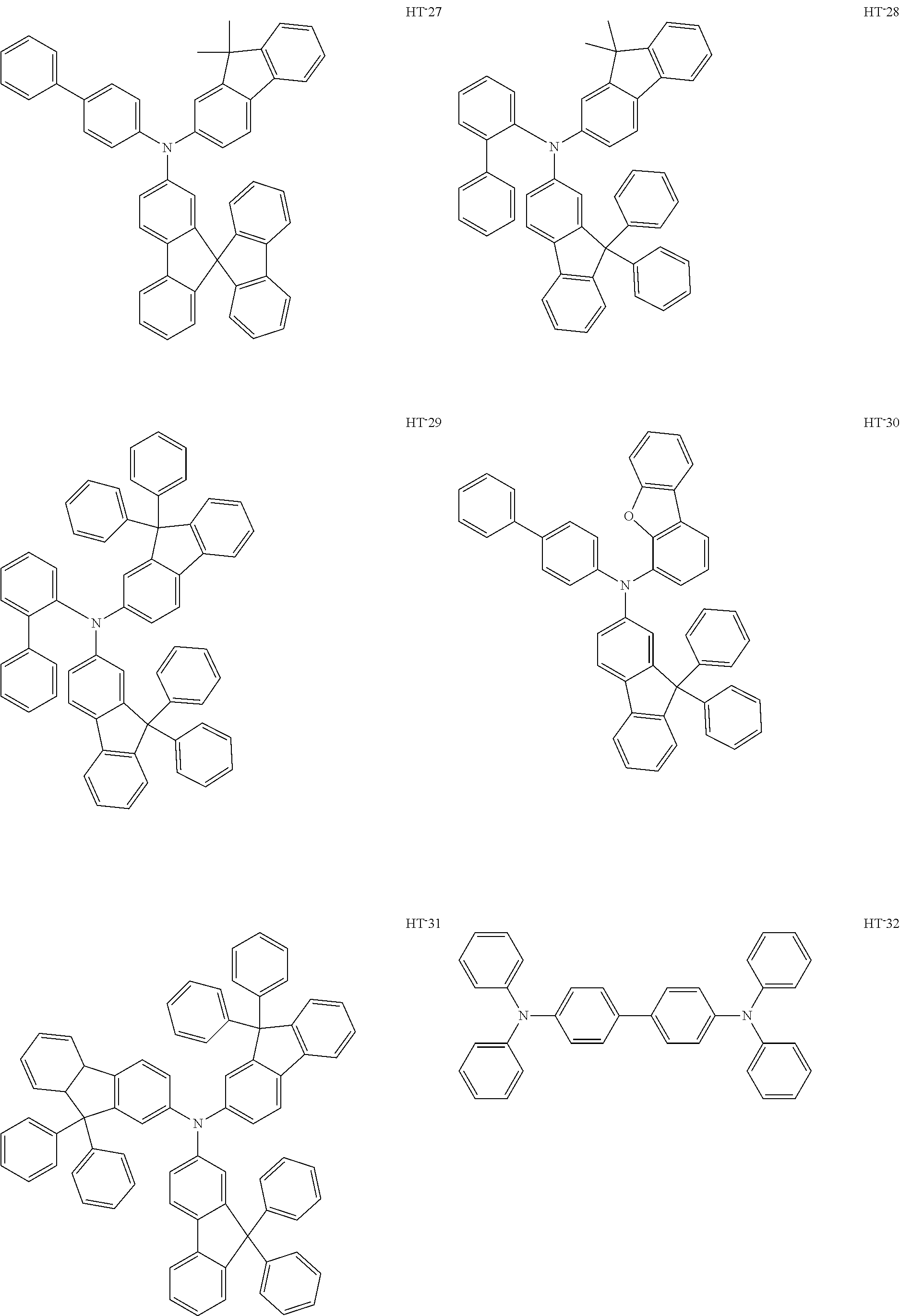

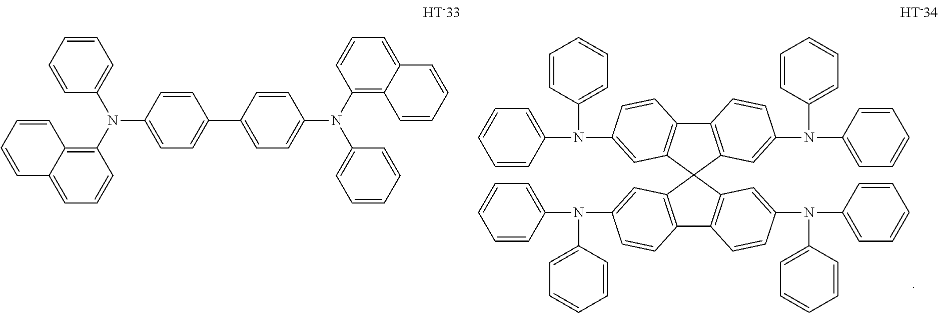 [SMILES: c1ccc(N(c2ccc(-c3ccc(N(c4ccccc4)c4cccc5ccccc45)cc3)cc2)c2cccc3ccccc23)cc1 ; c1ccc(N(c2ccccc2)c2ccc3c(c2)C2(c4cc(N(c5ccccc5)c5ccccc5)ccc4-3)c3cc(N(c4ccccc4)c4ccccc4)ccc3-c3ccc(N(c4ccccc4)c4ccccc4)cc32)cc1]

In the present application, the material of the electron blocking layer 5 is not particularly limited, and an electron blocking layer material known in the art can be used. For example, at least one of compounds EB-01 to EB-05 can be selected:

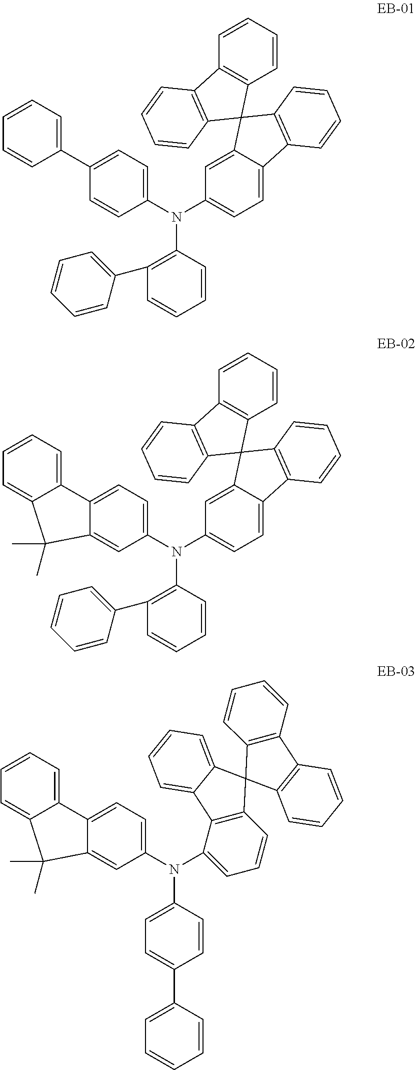 [SMILES: c1ccc(-c2ccc(N(c3ccc4c(c3)C3(c5ccccc5-c5ccccc53)c3ccccc3-4)c3ccccc3-c3ccccc3)cc2)cc1 ; CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3cccc4c3-c3ccccc3C43c4ccccc4-c4ccccc43)cc21]

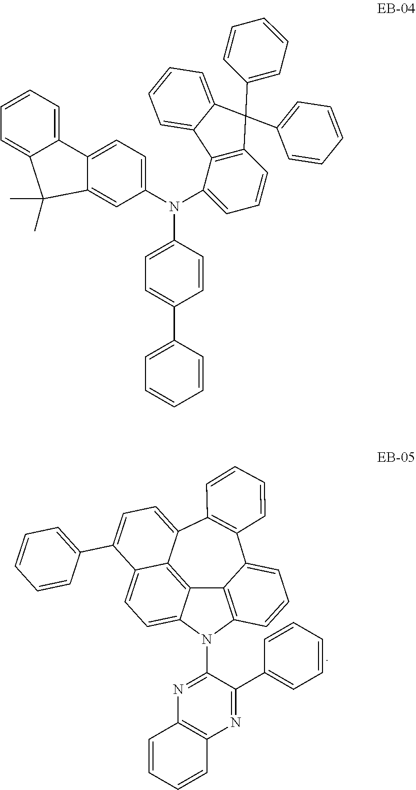 [SMILES: CC1(C)c2ccccc2-c2ccc(N(c3ccc(-c4ccccc4)cc3)c3cccc4c3-c3ccccc3C4(c3ccccc3)c3ccccc3)cc21 ; c1ccc(-c2nc3ccccc3nc2-n2c3cccc4c3c3c5c(ccc(-c6ccccc6)c5ccc32)-c2ccccc2-4)cc1]

In the present application, the material of the luminescent layer 6 comprises a host material of the luminescent layer and a guest material of the luminescent layer, wherein the amount of the host material of the luminescent layer and the guest material of the luminescent layer are not particularly limited, and can be an amount known to those skilled in the art.

For example, the host material of the luminescent layer may be selected from at least one of the following compounds RH-1 to RH-1-11:

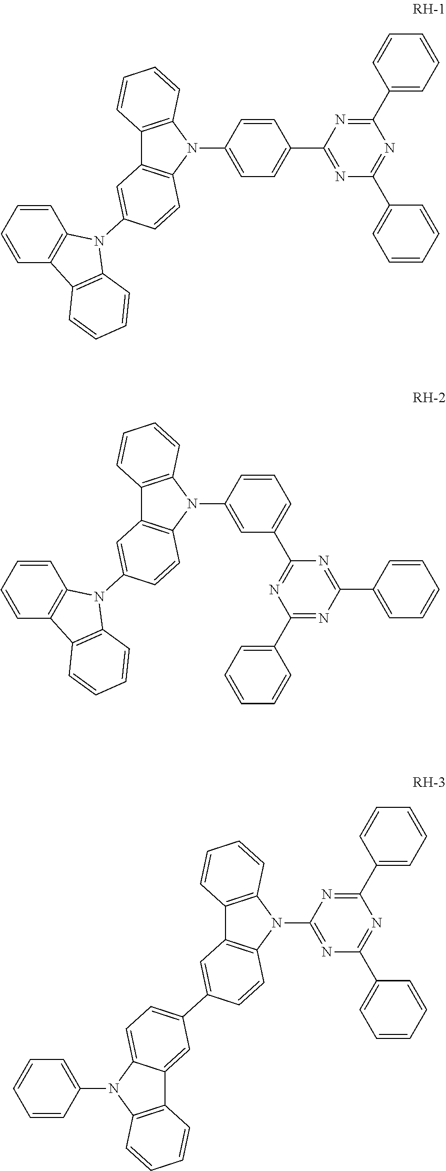 [SMILES: c1ccc(-c2nc(-c3ccccc3)nc(-c3ccc(-n4c5ccccc5c5cc(-n6c7ccccc7c7ccccc76)ccc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

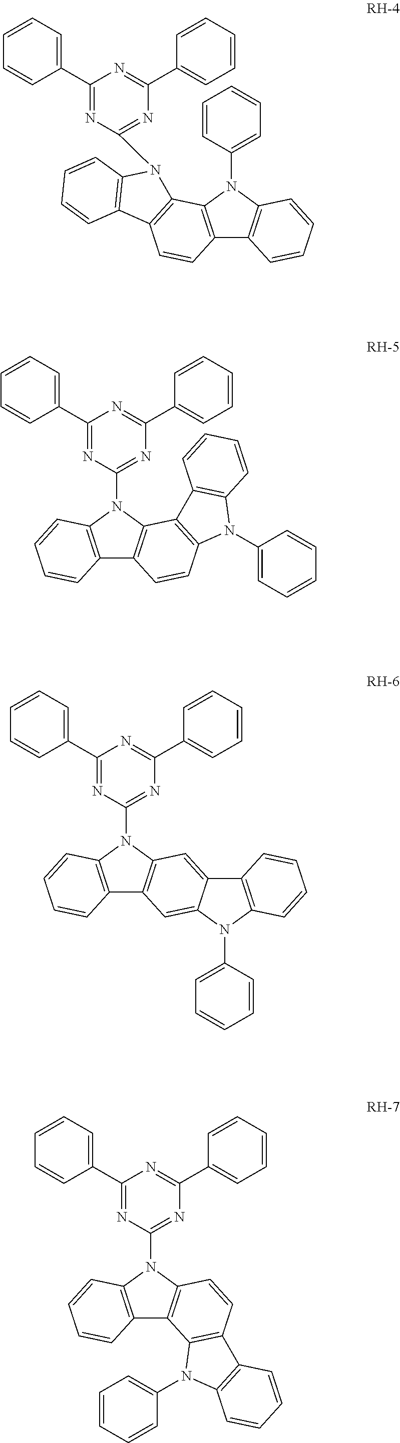 [SMILES: c1ccc(-c2nc(-c3ccccc3)nc(-n3c4ccccc4c4ccc5c6ccccc6n(-c6ccccc6)c5c43)n2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4cc5c(cc43)c3ccccc3n5-c3ccccc3)n2)cc1 ; c1ccc(-c2nc(-c3ccccc3)nc(-n3c4ccccc4c4c3ccc3c5ccccc5n(-c5ccccc5)c34)n2)cc1]

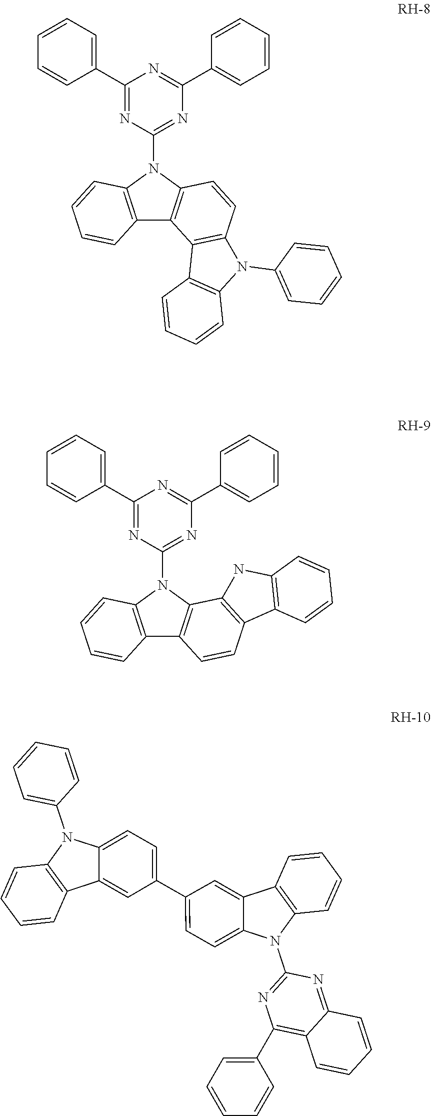 [SMILES: c1ccc(-c2nc(-c3ccccc3)nc(-n3c4ccccc4c4c5c6ccccc6n(-c6ccccc6)c5ccc43)n2)cc1 ; c1ccc(-c2nc(-c3ccccc3)nc(-n3c4ccccc4c4ccc5c6ccccc6[nH]c5c43)n2)cc1 ; c1ccc(-c2nc(-n3c4ccccc4c4cc(-c5ccc6c(c5)c5ccccc5n6-c5ccccc5)ccc43)nc3ccccc23)cc1]

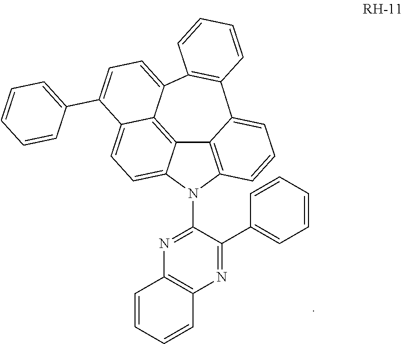 [SMILES: c1ccc(-c2nc3ccccc3nc2-n2c3cccc4c3c3c5c(ccc(-c6ccccc6)c5ccc32)-c2ccccc2-4)cc1]

In the present application, the guest material of the luminescent layer may comprises at least one of the guest material of the luminescent layer in the present application, or may also comprises a combination of at least one of the guest material of the luminescent layer in the present application and at least one of the following known guest material of the luminescent layer.

For example, the known guest material of the luminescent layer may be selected from at least one of the following compounds RPD-1 to RPD-28:

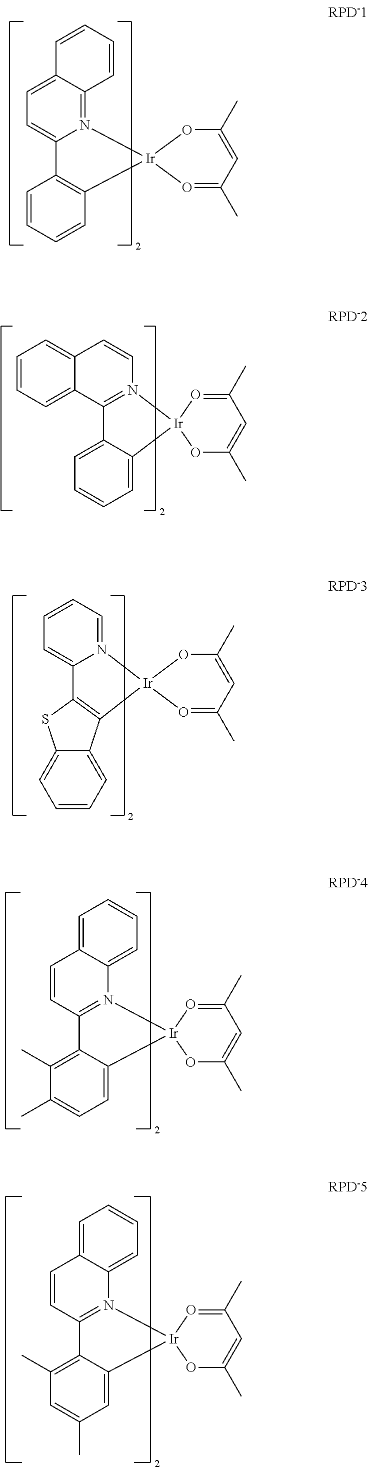

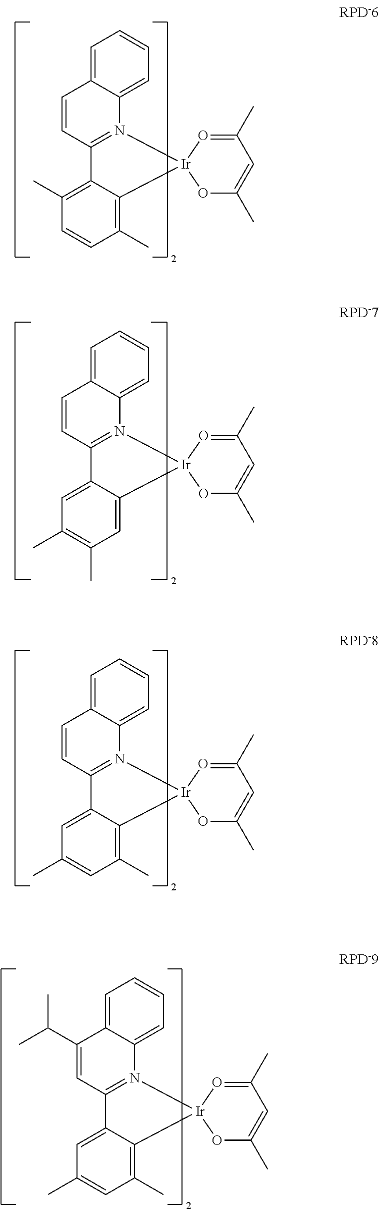

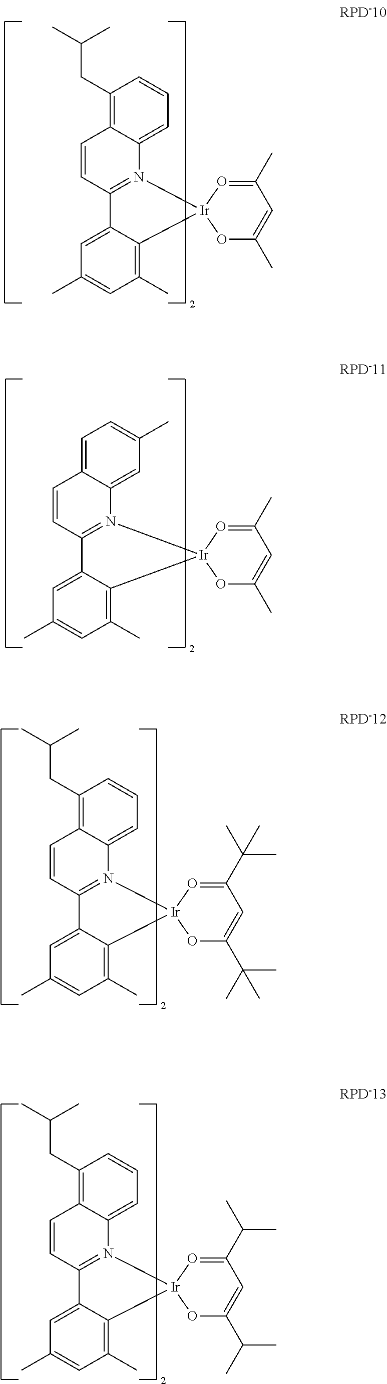

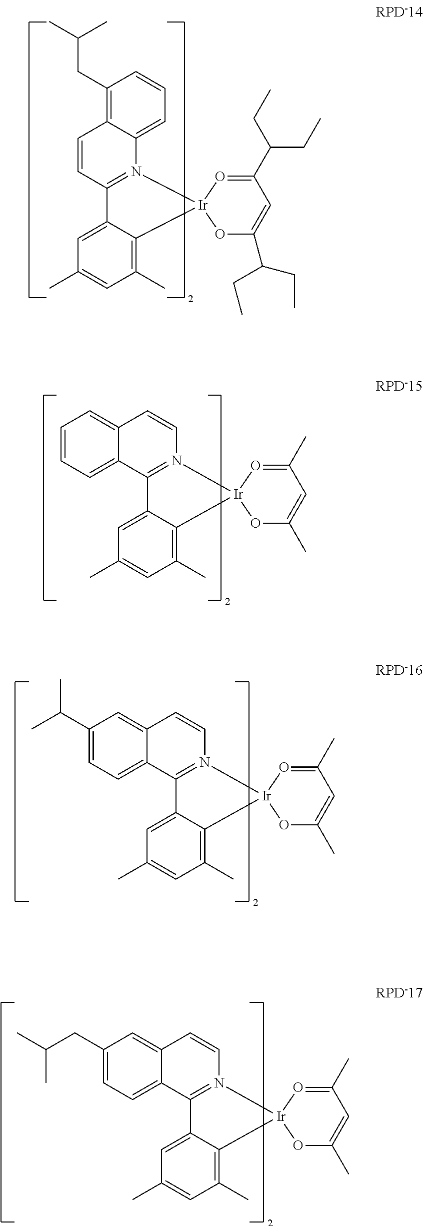

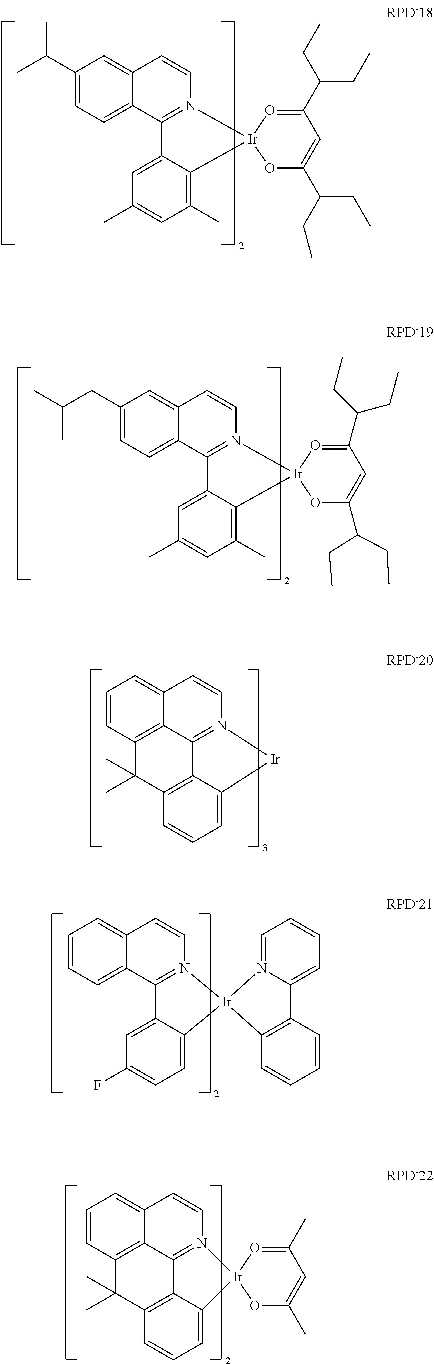

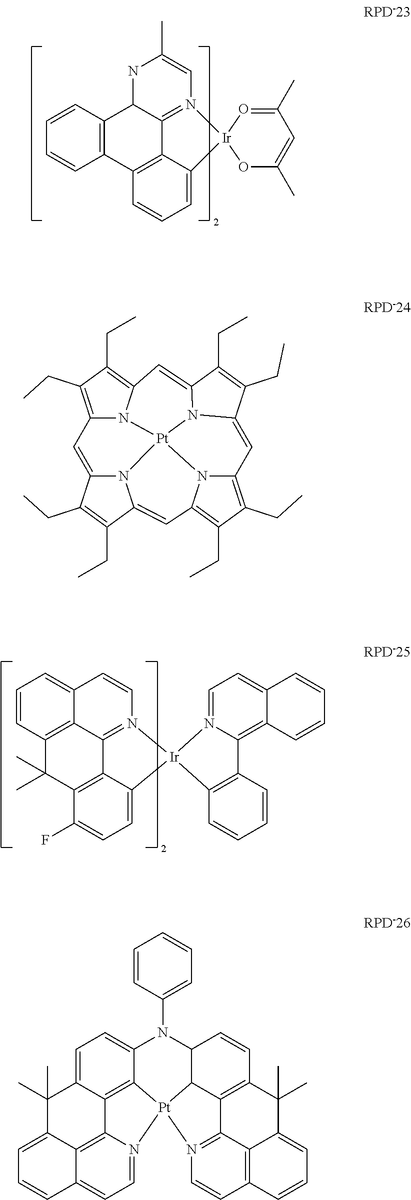

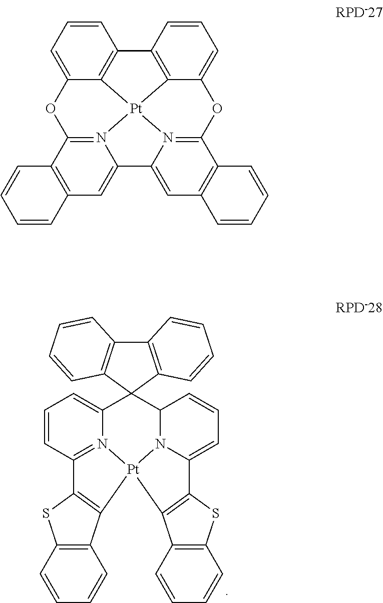

In the present application, the material of the hole blocking layer 7 is not particularly limited, and a hole blocking layer material known in the art can be used. For example, at least one of the following compounds HB-01 to HB-05 can be selected:

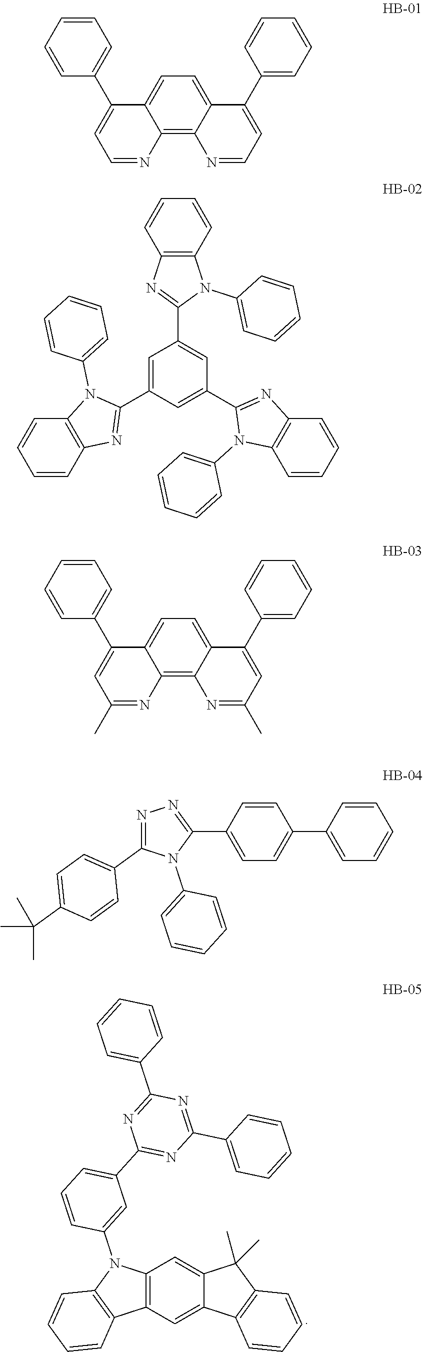

In the present application, the material of the electron transport layer 8 is not particularly limited, and an electron transport layer material known in the art can be used. For example, at least one of the following compounds ET-1 to ET-59 can be selected:

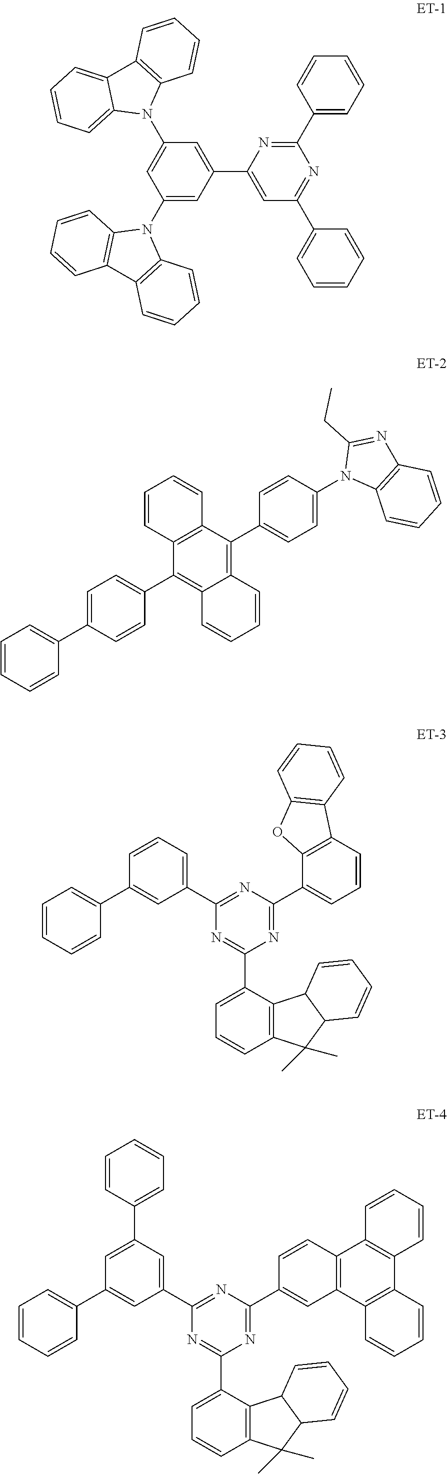 [SMILES: c1ccc(-c2cc(-c3cc(-n4c5ccccc5c5ccccc54)cc(-n4c5ccccc5c5ccccc54)c3)nc(-c3ccccc3)n2)cc1 ; CCc1nc2ccccc2n1-c1ccc(-c2c3ccccc3c(-c3ccc(-c4ccccc4)cc3)c3ccccc23)cc1 ; CC1(C)c2cccc(-c3nc(-c4cccc(-c5ccccc5)c4)nc(-c4cccc5c4oc4ccccc45)n3)c2C2C=CC=CC21 ; CC1(C)c2cccc(-c3nc(-c4cc(-c5ccccc5)cc(-c5ccccc5)c4)nc(-c4ccc5c6ccccc6c6ccccc6c5c4)n3)c2C2C=CC=CC21]

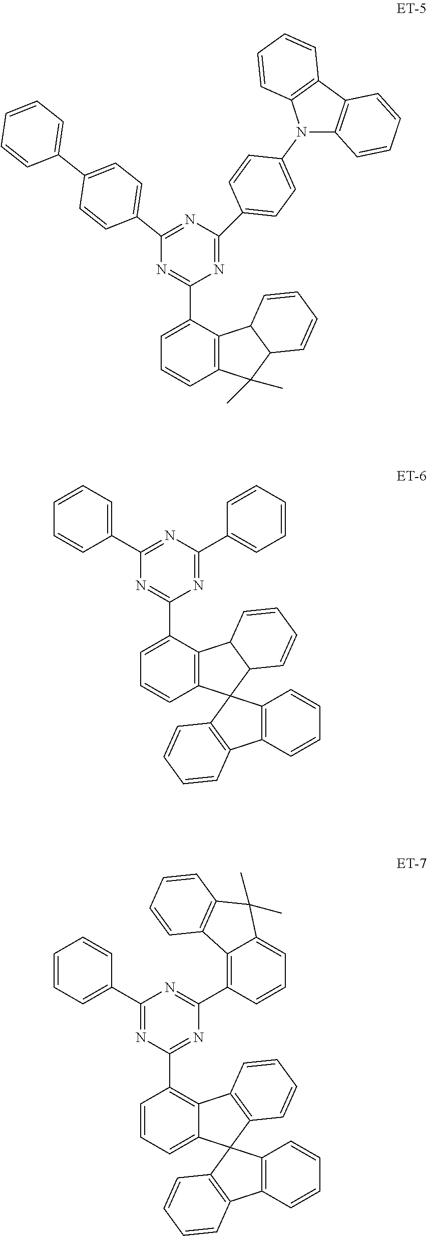 [SMILES: CC1(C)c2cccc(-c3nc(-c4ccc(-c5ccccc5)cc4)nc(-c4ccc(-n5c6ccccc6c6ccccc65)cc4)n3)c2C2C=CC=CC21 ; C1=CC2c3c(-c4nc(-c5ccccc5)nc(-c5ccccc5)n4)cccc3C3(c4ccccc4-c4ccccc43)C2C=C1 ; CC1(C)c2ccccc2-c2c(-c3nc(-c4ccccc4)nc(-c4cccc5c4-c4ccccc4C54c5ccccc5-c5ccccc54)n3)cccc21]

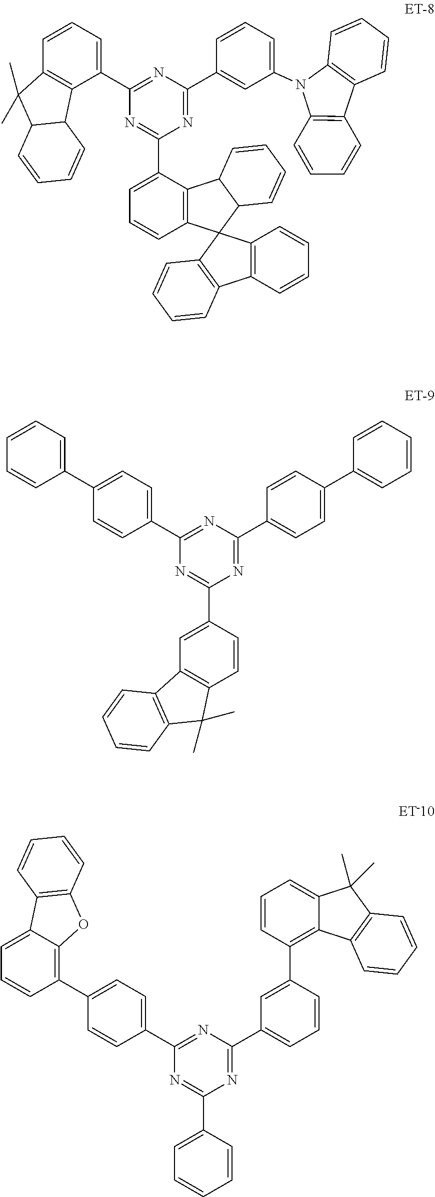 [SMILES: CC1(C)c2cccc(-c3nc(-c4cccc(-n5c6ccccc6c6ccccc65)c4)nc(-c4cccc5c4C4C=CC=CC4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21 ; CC1(C)c2ccccc2-c2c(-c3cccc(-c4nc(-c5ccccc5)nc(-c5ccc(-c6cccc7c6oc6ccccc67)cc5)n4)c3)cccc21]

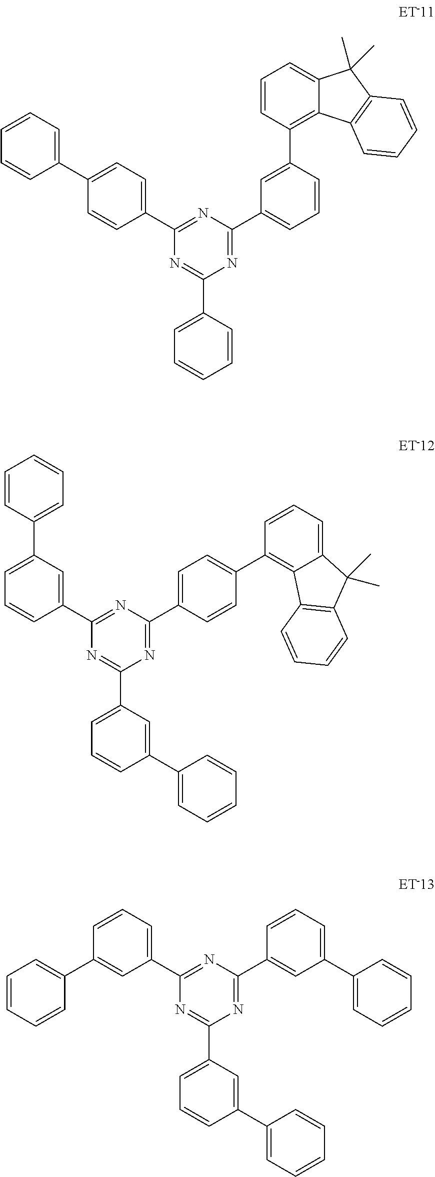 [SMILES: CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21 ; c1ccc(-c2cccc(-c3nc(-c4cccc(-c5ccccc5)c4)nc(-c4cccc(-c5ccccc5)c4)n3)c2)cc1]

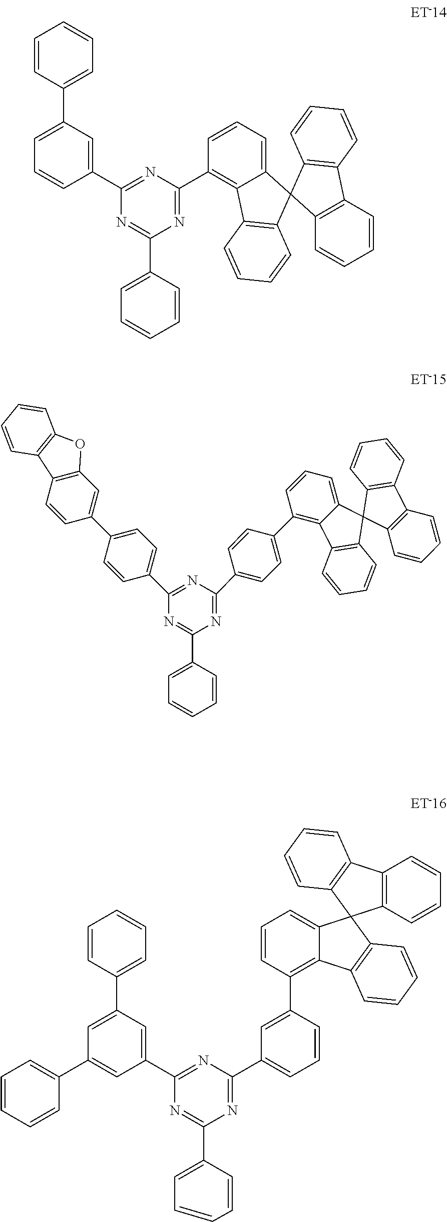 [SMILES: c1ccc(-c2cccc(-c3nc(-c4ccccc4)nc(-c4cccc5c4-c4ccccc4C54c5ccccc5-c5ccccc54)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1 ; c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1]

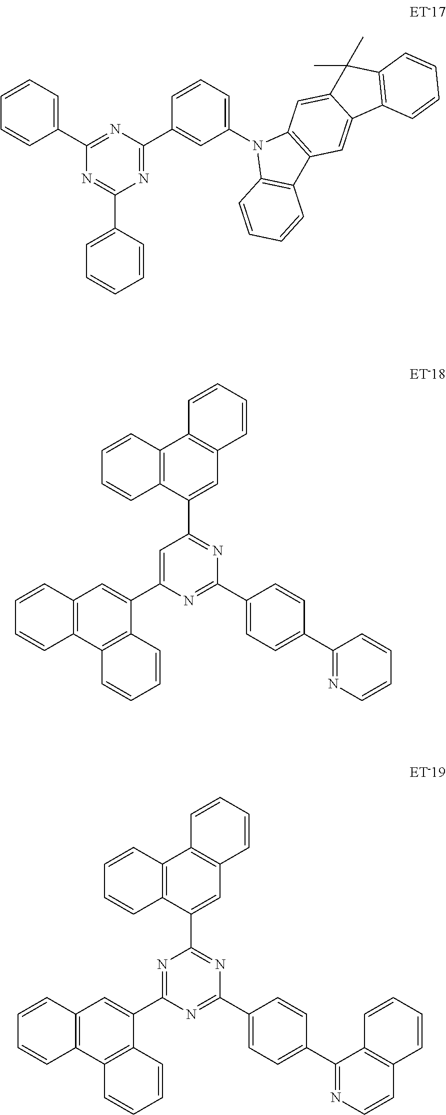 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1 ; c1ccc2c(-c3ccc(-c4nc(-c5cc6ccccc6c6ccccc56)nc(-c5cc6ccccc6c6ccccc56)n4)cc3)nccc2c1]

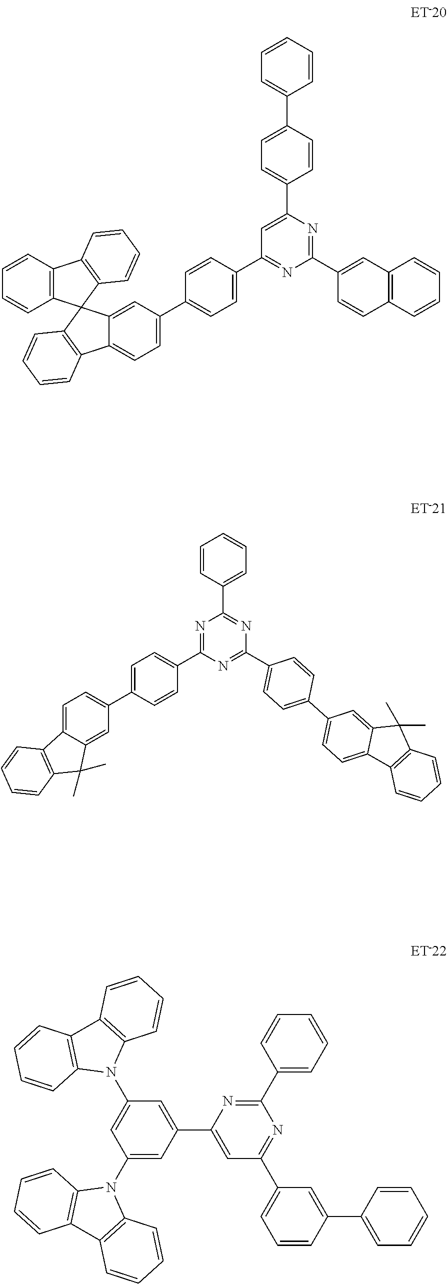 [SMILES: c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

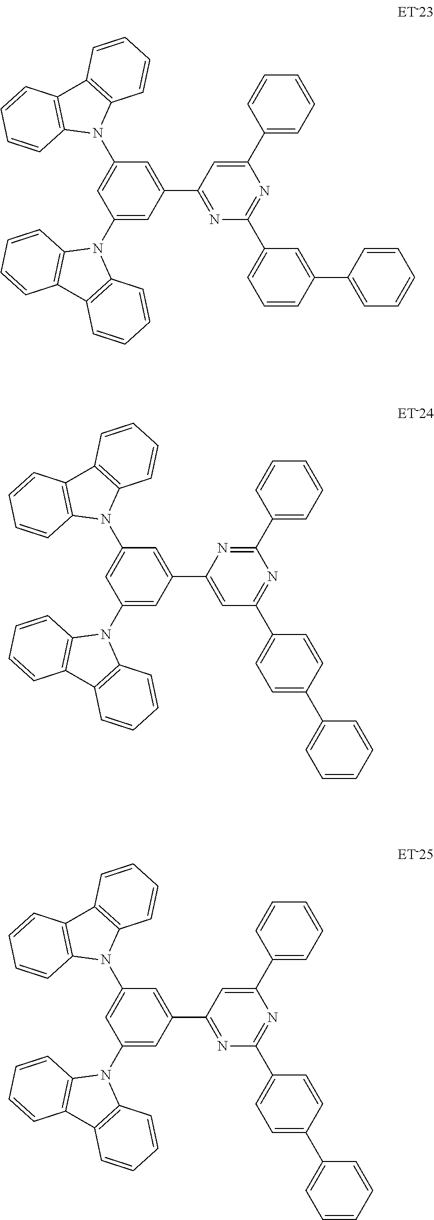 [SMILES: c1ccc(-c2cccc(-c3nc(-c4ccccc4)cc(-c4cc(-n5c6ccccc6c6ccccc65)cc(-n5c6ccccc6c6ccccc65)c4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2ccc(-c3nc(-c4ccccc4)cc(-c4cc(-n5c6ccccc6c6ccccc65)cc(-n5c6ccccc6c6ccccc65)c4)n3)cc2)cc1]

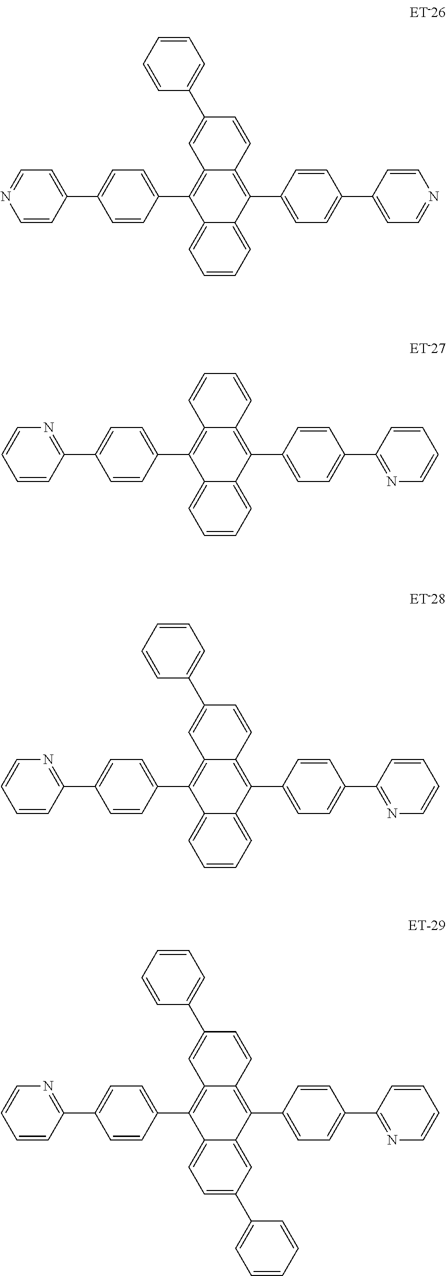 [SMILES: c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1 ; c1ccc(-c2ccc3c(-c4ccc(-c5ccccn5)cc4)c4cc(-c5ccccc5)ccc4c(-c4ccc(-c5ccccn5)cc4)c3c2)cc1]

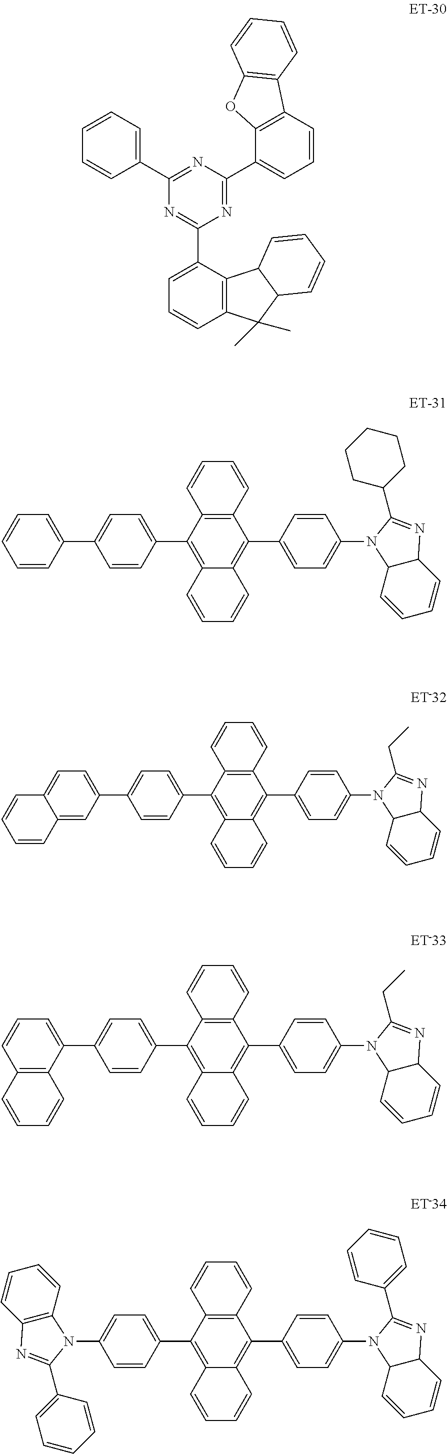 [SMILES: CC1(C)c2cccc(-c3nc(-c4ccccc4)nc(-c4cccc5c4oc4ccccc45)n3)c2C2C=CC=CC21 ; C1=CC2N=C(C3CCCCC3)N(c3ccc(-c4c5ccccc5c(-c5ccc(-c6ccccc6)cc5)c5ccccc45)cc3)C2C=C1 ; CCC1=NC2C=CC=CC2N1c1ccc(-c2c3ccccc3c(-c3ccc(-c4ccc5ccccc5c4)cc3)c3ccccc23)cc1 ; CCC1=NC2C=CC=CC2N1c1ccc(-c2c3ccccc3c(-c3ccc(-c4cccc5ccccc45)cc3)c3ccccc23)cc1 ; C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1]

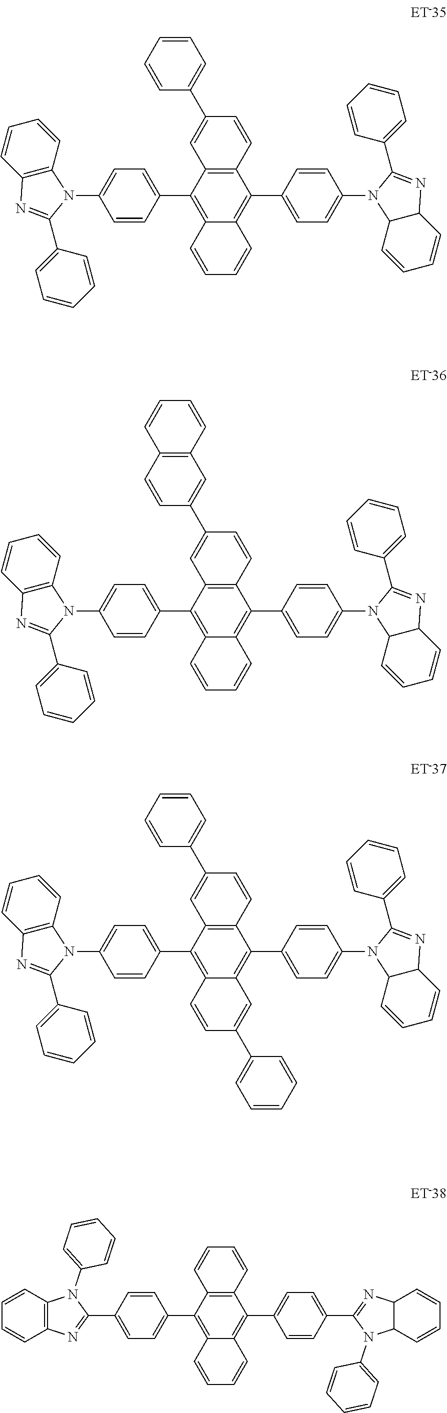 [SMILES: C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1 ; C1=CC2N=C(c3ccc(-c4c5ccccc5c(-c5ccc(-c6nc7ccccc7n6-c6ccccc6)cc5)c5ccccc45)cc3)N(c3ccccc3)C2C=C1]

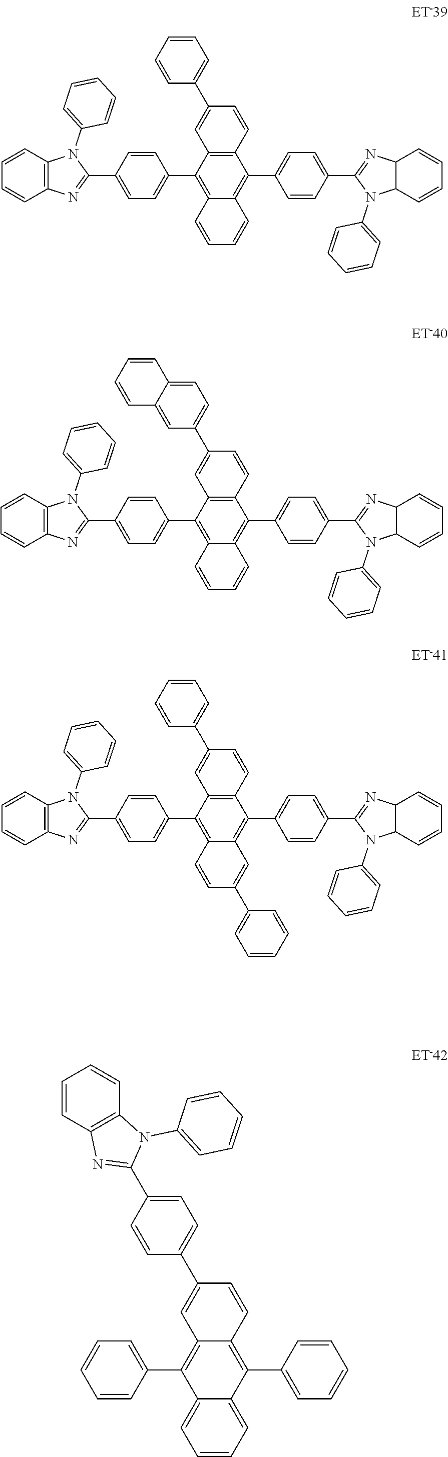 [SMILES: C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1 ; c1ccc(-c2c3ccccc3c(-c3ccccc3)c3cc(-c4ccc(-c5nc6ccccc6n5-c5ccccc5)cc4)ccc23)cc1]

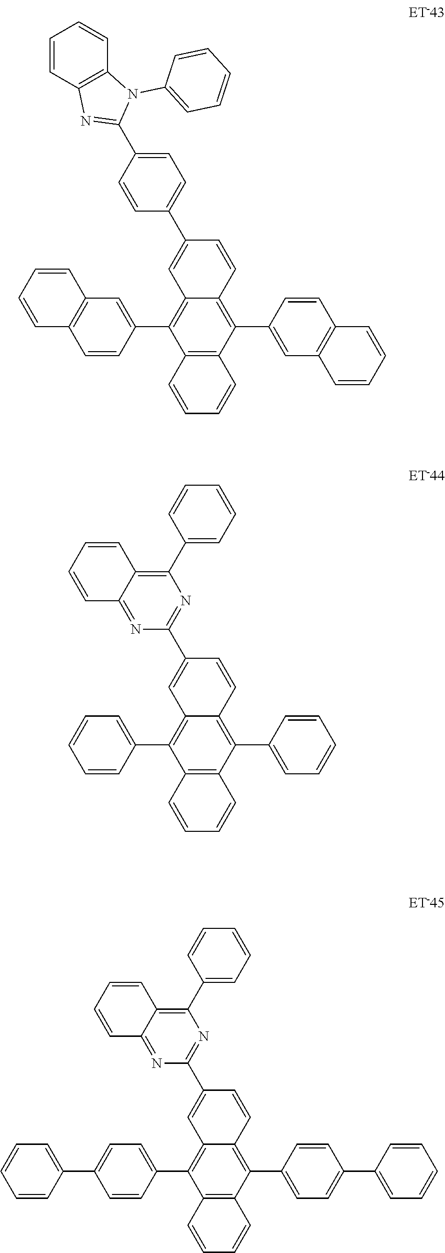 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc(-c3ccc4c(-c5ccccc5)c5ccccc5c(-c5ccccc5)c4c3)nc3ccccc23)cc1 ; c1ccc(-c2ccc(-c3c4ccccc4c(-c4ccc(-c5ccccc5)cc4)c4cc(-c5nc(-c6ccccc6)c6ccccc6n5)ccc34)cc2)cc1]

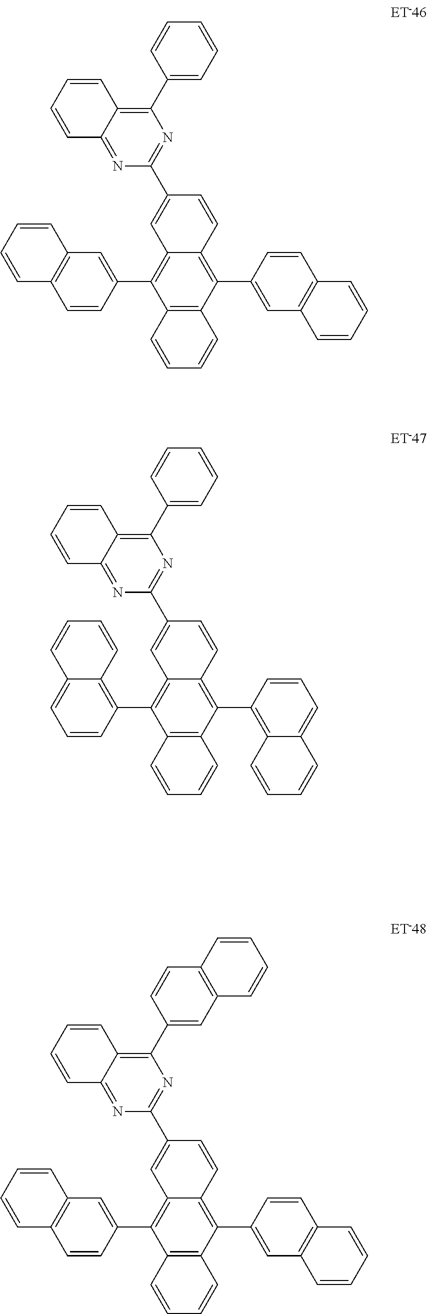 [SMILES: c1ccc(-c2nc(-c3ccc4c(-c5ccc6ccccc6c5)c5ccccc5c(-c5ccc6ccccc6c5)c4c3)nc3ccccc23)cc1 ; c1ccc(-c2nc(-c3ccc4c(-c5cccc6ccccc56)c5ccccc5c(-c5cccc6ccccc56)c4c3)nc3ccccc23)cc1 ; c1ccc2cc(-c3nc(-c4ccc5c(-c6ccc7ccccc7c6)c6ccccc6c(-c6ccc7ccccc7c6)c5c4)nc4ccccc34)ccc2c1]

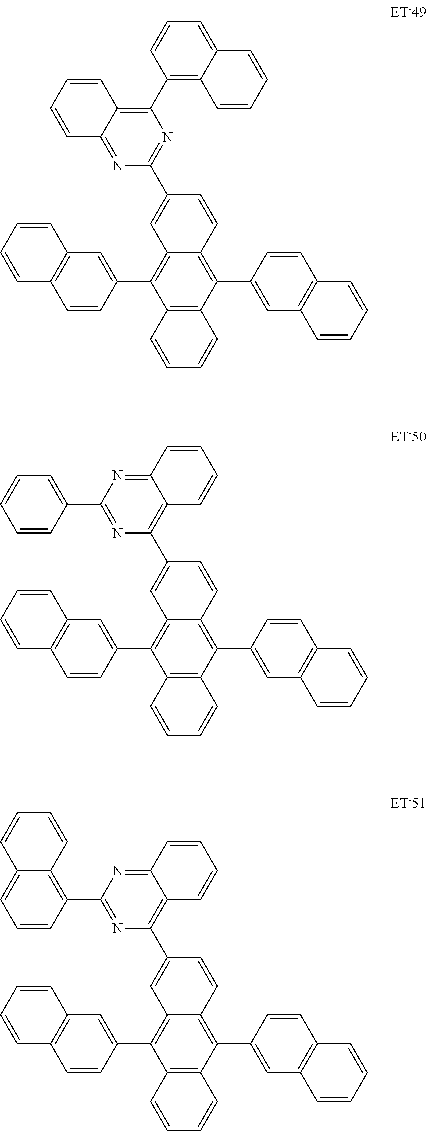 [SMILES: c1ccc2cc(-c3c4ccccc4c(-c4ccc5ccccc5c4)c4cc(-c5nc(-c6cccc7ccccc67)c6ccccc6n5)ccc34)ccc2c1 ; c1ccc(-c2nc(-c3ccc4c(-c5ccc6ccccc6c5)c5ccccc5c(-c5ccc6ccccc6c5)c4c3)c3ccccc3n2)cc1 ; c1ccc2cc(-c3c4ccccc4c(-c4ccc5ccccc5c4)c4cc(-c5nc(-c6cccc7ccccc67)nc6ccccc56)ccc34)ccc2c1]

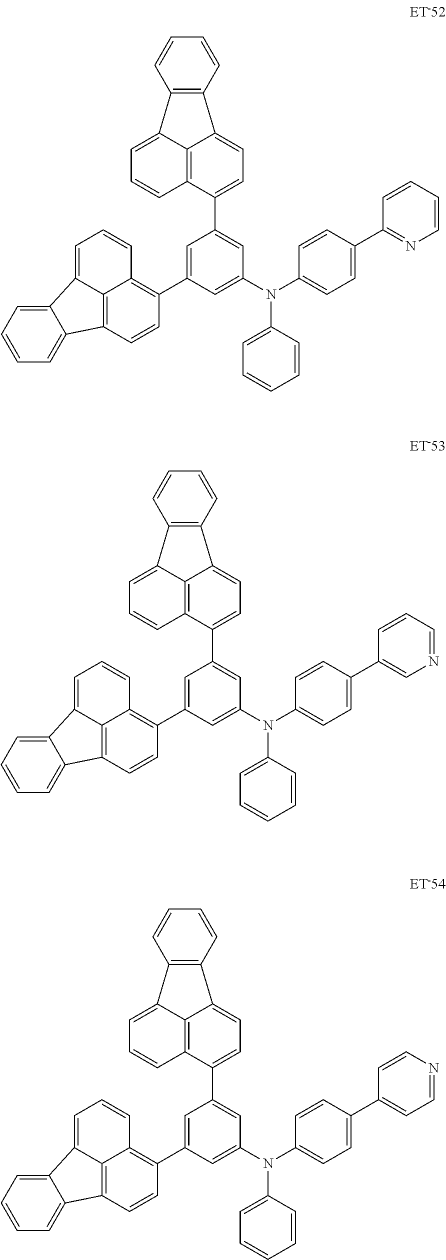 [SMILES: c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3ccncc3)cc2)c2cc(-c3ccc4c5c(cccc35)-c3ccccc3-4)cc(-c3ccc4c5c(cccc35)-c3ccccc3-4)c2)cc1]

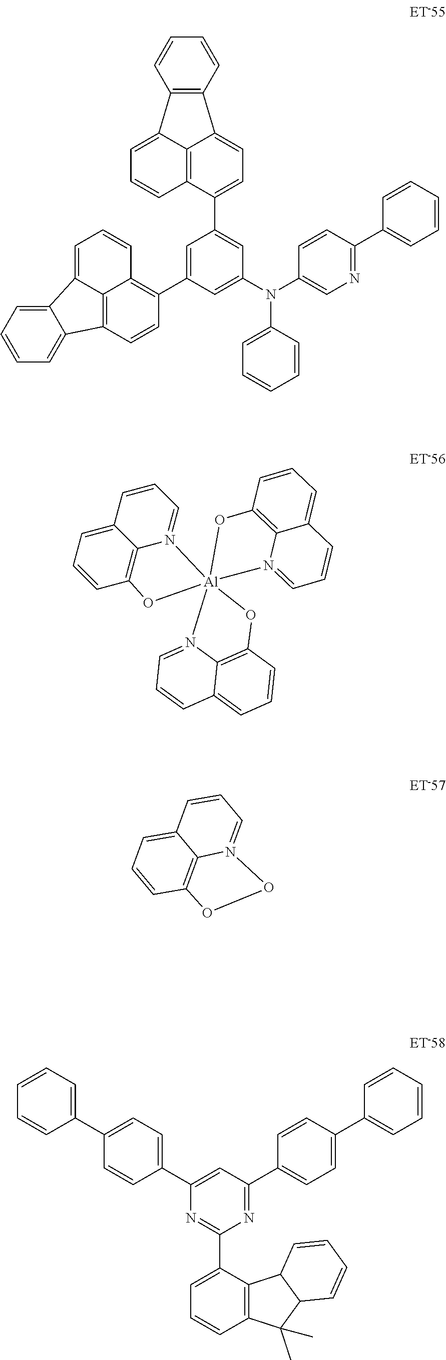

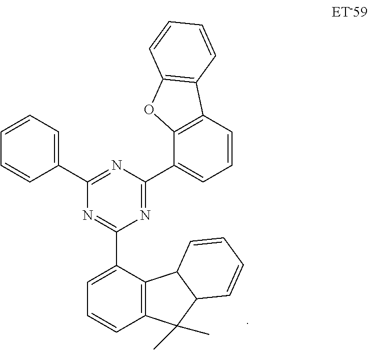 [SMILES: CC1(C)c2cccc(-c3nc(-c4ccccc4)nc(-c4cccc5c4oc4ccccc45)n3)c2C2C=CC=CC21]

In the present application, the electron transport layer 8 may further include an n-type dopant. The type of the n-type dopant is not particularly limited, and various n-type dopants known in the art can be used. For example, the following n-type dopant can he used:

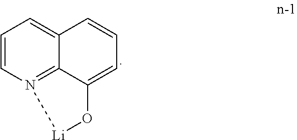

In the present application, the amount of the n-type dopant is not particularly limited, and can be an amount known to those skilled in the art.

In the present application, the material of the cathode electrode 9 is not particularly limited, and can be selected from, but not limited to, magnesium-silver mixture, magnesium-aluminum mixture, LiF/Al, ITO, Al and other metals, metal mixture, metal oxide and the like.

The fifth aspect of the present application provides a display device, comprising the Organic electroluminescent device provided by the present application, which has excellent display effects. The display device includes, but is not limited to, display, television, mobile communication terminal, tablet computer and the like.

The method for preparing the organic electroluminescent device of the present application is not particularly limited, and any method known in the art can be adopted. For example, the organic electroluminescent device can be prepared by the following preparation method;

(1) cleaning a reflective anode electrode 2 on a substrate of an OLED device for top light-emitting, wherein in the cleaning machine, the steps of medicine washing, water washing, brush washing, high-pressure water washing, and air knife drying and the like are respectively carried out, and then performing a heating treatment;

(2) vacuum evaporating a hole injection material on the reflective anode electrode 2 as a hole injection layer 3;

(3) vacuum evaporating a hole transport material on the hole injection layer 3 as a hole transport layer 4;

(4) vacuum evaporating an electron blocking layer material on the hole transport layer 4 as an electron blocking layer 5;

(5) vacuum evaporating a luminescent layer 6 on the electron blocking layer 5, wherein the luminescent layer 6 contains a host material and a guest material;

(6) vacuum evaporating a hole blocking layer material on the luminescent layer 6 as a hole blocking layer 7;

(7) vacuum evaporating an electron transport material on the hole blocking layer 7 as an electron transport layer 8;

(8) vacuum evaporating a cathode material on the electron transport layer gas a cathode electrode 9.

The above description is only the structure and preparation method of a typical organic electroluminescent device. It should be understood that the present application is not limited to this structure. The guest material of the luminescent layer can be used for organic electroluminescent device with any structure, and the organic electroluminescent device can be prepared by any preparation method known in the art.

The synthetic method of the compound of the present application is not particularly limited, and any method known to those skilled in the art can be used for synthesis. The synthesis process of the compound of the present application is illustrated by the following examples.

### Synthesis Example

### Synthesis Example 1: Synthesis of Compound G1

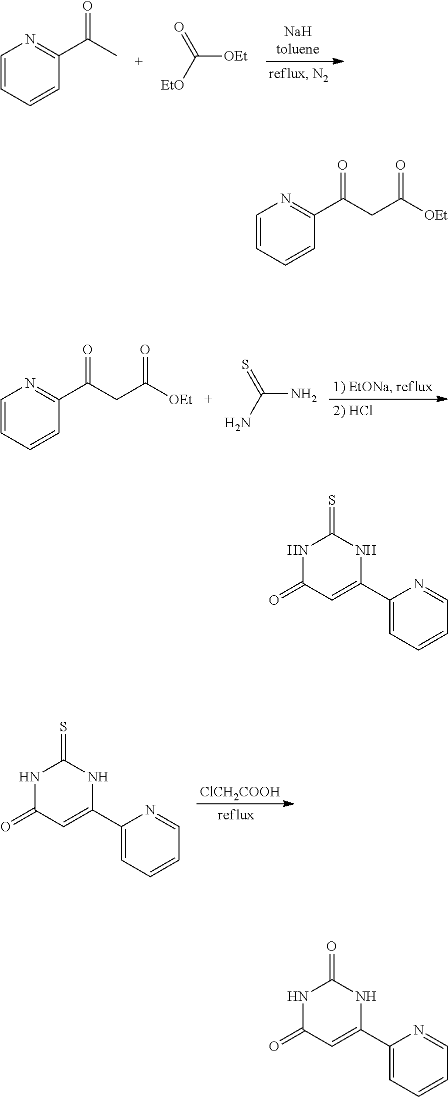

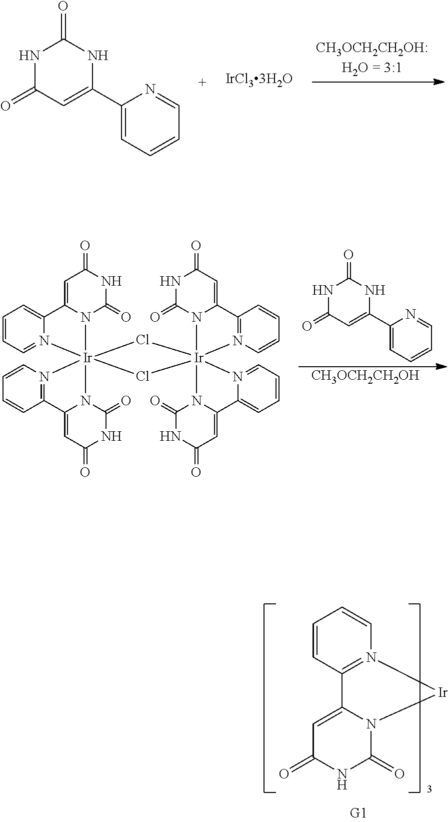

(1) Synthesis of ligand 6-(pyridin-2-yl)-2,4(1H,3H)-pyrimidinedione

a) 240 mL of toluene was added into a 1000 mL three-necked bottle. Nitrogen was introduced for bubbling for 30 min. 11.1 g of sodium hydride (the mass fraction of sodium hydride was 60%, 277.5 mmol) and 23.4 g of diethyl carbonate (198.4 mmol) were added under the protection of nitrogen, and the mixture was heated to 115° C. to reflux. 12.064 g of 2-acetylpyridine (99.6 mmol) was dissolved in 60 mL of toluene, which was added dropwise into the reaction system, and reacted for 5 h. 40 mL glacial acetic acid and 120 mL ice water were mixed homogeneously to quench the reaction. The aqueous phase was separated from the organic phase. The aqueous phase was extracted with toluene. The organic phases were combined, washed with ice water to near neutral pH, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 10:1) to obtain 14.11 g of ethyl 3-oxo-3-(pyridin-2-yl) propionate as a light brown transparent liquid with a yield of 73%. Et in the structural formula represents ethyl.

¹H NMR (600 MHz, CDCl₃) δ 7.58 (d, J=0.9 Hz, 1H), 7.24 (d, J=3.6 Hz, 1H), 6.54 (dd, J₁=3.6 Hz, J₂=1.6 Hz, 1H), 4.17 (q, J=7.2 Hz, 2H), 3.81 (s, 2H), 1.22 (s, J=7.2 Hz, 3H).

b) 1500 mL of ethanol was added into a 2000 mL three-necked bottle, nitrogen was introduced for bubbling for 30 min, 8.2 g of metallic sodium (356 mmol) was added under the protection of nitrogen to dissolve completely, then 53 g of ethyl 3-oxo-3-(pyridin-2-yl) propionate (274 mmol) and 27.1 g of thiourea (356 mmol) were added, and the mixture was heated to 95° C. to reflux and reacted for 24 h. The resulting mixture was evaporated under a reduced pressure to remove the reaction solvent. water was added to completely dissolve the residue, and the pH was adjusted to 6-8 with 2 M hydrochloric acid until the precipitation was complete. The solid was filtered under a reduced pressure, and the filter residue was washed with water and petroleum ether successively, dried under vacuum to obtain 16.7 g of 6-(pyridin-2-yl)-2-thio-4(1H,3H)-pyrimidirione as a white powdery solid with a yield of 30%.

¹H NMR (400 MHz, DMSO-d₆) δ 12.70 (s, 1H), 11.34 (s, 1H), 8.75 (s, 1H), 8.17 (s, 1H), 8.01. (s, 1H), 7.62 (s, 1H), 6.69 (s, 1H),

c) 375 mL of water was added into a 1000 mL three-necked bottle. 31.8 g of chloroacetic acid (336.5 mmol) was dissolved into water, and 15 g of 6-(pyridin-2-yl)-2-thio-4(1H,3H)-pyrimidinone (73.1 mmol) was added. The mixture was heated to 105° C. to reflux and reacted for 24 h. The resulting mixture was cooled to room temperature, and the pH was adjusted to 6-7 with 2 M sodium hydroxide solution until the precipitation was complete. The solid was filtered under a reduced pressure, and the filter residue was washed with water and petroleum ether successively, dried under vacuum to obtain 6.13 g of 6-(pyridin-2-yl)-2,4(1H,3H)-pyrimidinedione as a white powdery solid with a yield of 44.4% and a purity of 98.21%.

¹H NMR (400 MHz, DMSO-d₆) δ 11.23 (s, 1H), 10.60 (s, 1H), 8.72 (s, 1H), 8.11 (s, 1H), 7.99 (s, 1H), 7.57 (s, 1H), 6.33 (s, 1H).

(2) Synthesis of Compound G1

a) 60 mL of ethylene glycol monomethyl ether and 20 mL of water were added into a 250 mL three-necked bottle. Nitrogen was introduced for bubbling for 30 min. 2.15 g of 6-(pyridin-2-yl)-2,4(1H,3H)-pyrimidinedione (11.36 mmol) and 1 g of iridium trichloride trihydrate (2.84 mmol) were added successively under the protection of nitrogen, and the mixture was heated to 110° C. to reflux and reacted for 24 h. The resulting mixture was cooled to room temperature, filtered under a reduced pressure. The filter residue was washed with a mixed solution of water and acetone (the volume ratio of water to acetone was 1:1) and petroleum ether successively, dried under vacuum to obtain 1.4 g of iridium complex dimer as a dark red solid with a yield of 82%.

b) 22 mL of ethylene glycol monomethyl ether was added into a 100 mL three-necked bottle. Nitrogen was introduced for bubbling for 30 min, 362.4 mg of iridium complex dimer (0.3 mmol), 227 mg of 6-(pyridin-2-yl)-2,4(1H,3H)-pyrimidinedione (1.2 mmol) and 414.6 mg of potassium carbonate (3 mmol) were added successively under the protection of nitrogen, and the mixture was heated to 125° C. to reflux and reacted for 12 h. The resulting mixture was cooled to room temperature, quenched with 15 mL of water, and extracted with dichloromethane. The organic phase was washed with saturated NaCl solution, and dried with anhydrous sodium sulfate. The resulting mixture was evaporated under a reduced pressure to remove the solvent, separated by silica gel column chromatography (using a mixed solution of dichloromethane and methanol with a volume ratio of 20:1), and 317.8 mg of compound was obtained as a bright red solid with a yield of 70%.

¹H NMR (600 MHz, CDCl₃)δ 9.97 (s, 3H), 8.63 (m, 3H), 7.42 (m, 6H), 7.24 (m, 3H), 6,60 (m, 3H). MS (MALDI-TOF) m/z [M+H]⁺ calcd. for IrC₂₇H₁₉O₆N₉ 758.109, found 758.138.

### Synthesis Example 2: Synthesis of Compound G2

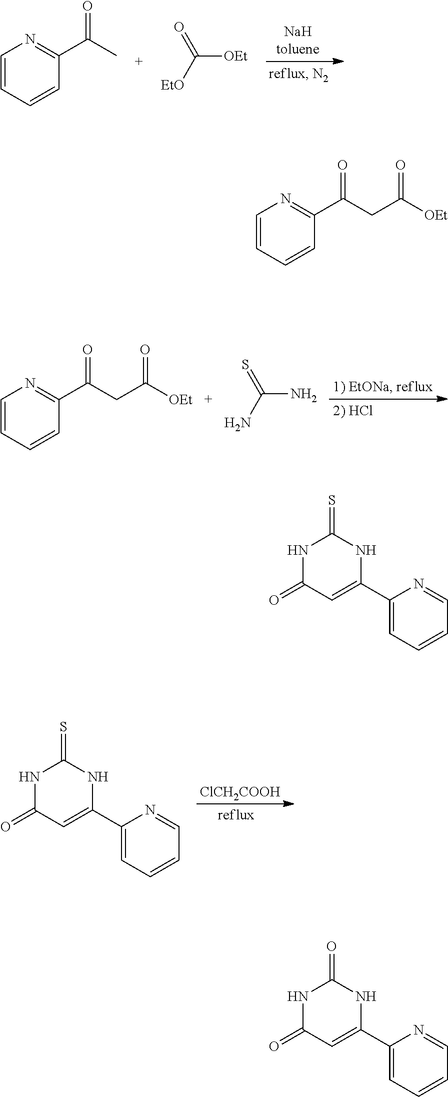

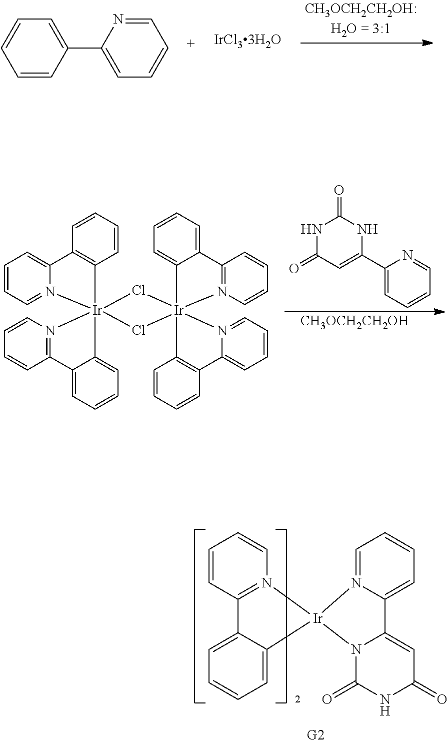

(1) Synthesis of ligand 6-(pyridin-2-yl)-2,4(1H,3H)-pyrimidinedione

a) 240 mL of toulene was added into a 1000 mL three-necked bottle. Nitrogen was introduced for bubbling for 30 min. 11.1 g of sodium hydride (the mass fraction of sodium hydride was 60%, 277.5 mmol) and 23.4 g of diethyl carbonate (198.4 mmol) were added under the protection of nitrogen, and the mixture was heated to 115° C. to reflux. 12.064 g of 2-acetylpyridine (99.6 mmol) was dissolved in 60 mL of toluene, which was added dropwise into the reaction system, and reacted for 5 h. 4-0 mL glacial acetic acid and 120 mL ice water were mixed homogeneously to quench the reaction. The aqueous phase was separated from the organic phase. The aqueous phase was extracted with toluene. The organic phases were combined, washed with ice water to near neutral pH, and dried with anhydrous sodium sulfate. The resulting mixture was evaporated under a reduced pressure to remove the solvent, separated by silica gel column chromatography (using a mixed solution of petroleum ether and ethyl acetate with a volume ratio of 10:1) to obtain 14.11 g of ethyl 3-oxo-3-(pyridin-2-yl) propionate as a light brown transparent liquid with a yield of 73%.

¹H NMR (600 MHz, CDCl₃) δ 7.58 (d, J=0.9 Hz, 1H), 7.24 (d, J=3.6 Hz, 1H), 6.54 (dd, J₁=3.6 Hz, J₂=1.6 Hz, 1H), 4.17 (q, J=7.2 Hz, 2H), 3.81 (s, 2H), 1.22 (s, J=7.2 Hz, 3H).

b) 1500 mL of ethanol was added into a 2000 mL three-necked bottle. Nitrogen was introduced for bubbling for 30 min. 8.2 g of metallic sodium (356 mmol) was added under the protection of nitrogen to dissolve completely, then 53 g of ethyl 3-oxo-3-(pyridin-2-yl) propionate (274 mmol) and 27.1 g of thiourea (356 mmol) were added, and the mixture was heated to 95 to reflux and reacted for 24 h. The resulting mixture was evaporated under a reduced pressure to remove the reaction solvent. Water was added to completely dissolve the residue, and the pH was adjusted to 6-8 with 2 M hydrochloric acid until the precipitation was complete. The solid was filtered under a reduced pressure, and the filter residue was washed with water and petroleum ether successively, dried under vacuum to obtain 16.7 g of 6-(pyridin-2-yl)-2-thio-4(1H,3H)-pyrimidinone as a white powdery solid with a yield of 30%.

¹H NMR (400 MHz, DMSO-d₆) δ 12.70 (s, 1H), 11.34 (s, 1H), 8.75 (s, 1H), 8.17 (s, 1H), 8.01 (s, 1H), 7.62 (s, 1H), 6.69 (s, 1H).

c) 375 mL of water was added into a 1000 mL three-necked bottle. 31.8 g of chloroacetic acid (336.5 mmol) was dissolved. into water, and 15 g of 6-(pyridin-2-yl)-2-thio-4(1H,3H)-pyrimidinone (73.1 mmol) was added. The mixture was heated to 105° C. to reflux and reacted for 24 h. The resulting mixture was cooled to room temperature, and the pH was adjusted to 6-7 with 2 M. sodium hydroxide solution until the precipitation was complete. The solid was filtered under a reduced pressure, and the filter residue was washed with water and petroleum ether successively, dried under vacuum to obtain 6.13 g of 6-(pyridin-2-yl)-2,4(1H,3H)-pyrimidinedione as a white powdery solid with a yield of 44.4% and a purity of 98.21%.

¹H NMR (400 MHz, DMSO-d₆) δ 11.23 (s, 1H), 10.60 (s, 1H), 8.72 (s, 8.11 (s, H), 7.99 (s, 1H), 7.57 (s, 1H), 6.33 (s, 1H).

(2) Synthesis of Compound G2

a) 630 mL of toluene, 473 mL of water and 126 mL of ethanol were added into a 2000 mL three-necked bottle. Nitrogen was introduced for bubbling for 30 min. 105 g of potassium carbonate (759 mmol). 8.5 g of tetrakis(triphenylphosphine)palladium (7.34 mmol). 40 g of 2-bromopyridine (253 mmol) and 37.1 g of phenylboronic acid (304 mmol) were added successively under the protection of nitrogen, and the mixture was heated to 105° C. to reflux and. reacted for 12 h. The reaction was quenched with 300 mL of water. The aqueous phase was separated from the organic phase. The aqueous phase was extracted with ethyl acetate. The organic phases were combined, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 10:1) to obtain 31.8 g of 2-phenylpyridine as a pale yellow transparent liquid with a yield of 81% and a purity of 99.05%.

¹H NMR (400 MHz, CDCl₃) δ 8.70 (m, 1H), 8.00 (m, 2H), 7.75 (m, 2H), 7.45 (m, 3H), 7.25 (m, 1H).

b) 60 mL of ethylene glycol monomethyl ether and 20 mL of water were added into a 250 mL three-necked bottle. Nitrogen was introduced for bubbling for 30 min. 1.76 g of 2-phenylpyridine (.11.36 mmol) and 1 g of iridium trichloride trihydrate (2.84 mmol) were added successively under the protection of nitrogen, and the mixture was heated to 110° C. to reflux and reacted for 24 h. The resulting mixture was cooled to room temperature, and filtered wider a reduced pressure. The filter residue was washed with a mixed solution of water and acetone (the volume ratio of water to acetone was 1:1) and petroleum ether successively, and dried under vacuum to obtain 1.28 g of iridium complex dimer as a yellow solid with a yield of 84%.

c) 22 mL of ethylene glycol monomethyl ether was added into a 100 mL three-necked bottle. Nitrogen was introduced for bubbling for 30 min. 321.6 mg of iridium complex dimer (0.3 mmol), 227 mg of 6-(pyridin-2-yl)-2,4(1H,3H)-pyrimidinedione (1.2 mmol) and 414.6 mg of potassium carbonate (3 mmol) were added successively under the protection of nitrogen, and the mixture was heated to 125° C. to reflux and reacted for 12 h. The resulting mixture was cooled to room temperature, quenched with 15 mL of water, and extracted with dichloromethane. The organic phase was washed with saturated NaCl solution, and dried with anhydrous sodium sulfate, evaporated under a reduced pressure to remove the solvent, and separated by silica gel column chromatography (using a mixed solution of dichloromethane and methanol with a volume ratio of 20:1) to obtain 300 mg of compound G2 as a orange solid with a yield of 73%.

¹H NMR (600 MHz, CDCl₃) δ 8.46 (d, <I ==6.4 Hz, 1H), 8.02 (d, 7.8 Hz, 1H), 7.86 (m, 6H), 7.69 (m, 2H), 7.62 (n, 2H), 7.35 (d, J=6.1 Hz. 1H), 7.07 (t, J=6.6 Hz, 1H), 6.96 (t, J=8.0 Hz, 1H), 6.83 (m, 4H), 6.28 (m, 2H), 6.22 (d, J=7.6 Hz, 1H). MS (MALDI-TOF) m/z [M+H]⁺ calcd. for IrC₃₁H₂₃O₂N₅ 690.148, found 690.215,

### Synthesis Example 3: Synthesis of Compound G3

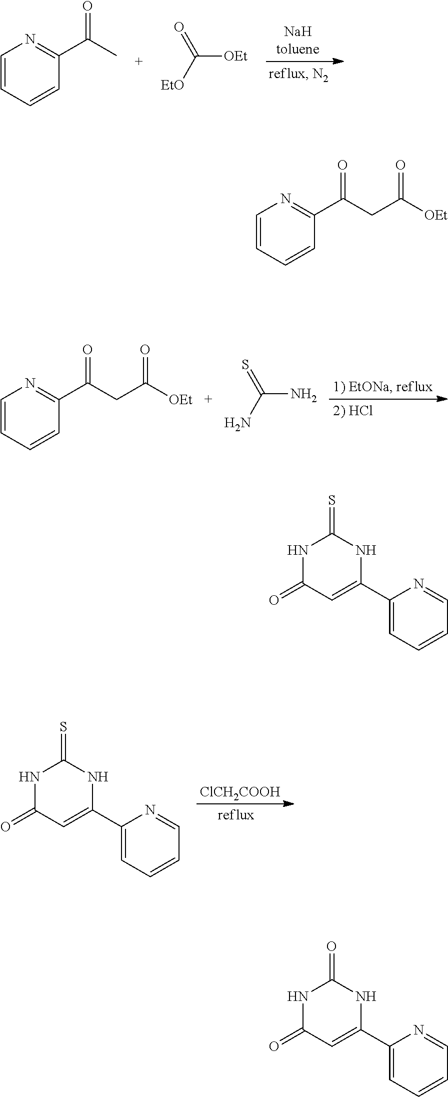

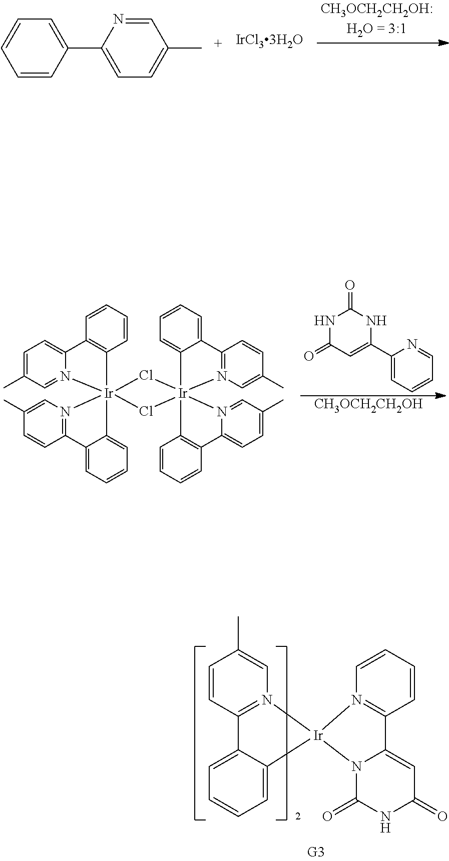

(1) Synthesis of ligand 6-(pyridin-2-yl)-2,4(1H,3H)-pyrimidinedione

a) 240 mL of toluene was added into a 1000 mL three-necked bottle. Nitrogen was introduced for bubbling for 30 min. 11.1 g of sodium hydride (the mass fraction of sodium hydride was 60%, 277.5 mmol) and 23.4 g of diethyl carbonate (198.4 mmol) were added under the protection of nitrogen, and the mixture was heated to 115° C. to reflux. 12.064 g of 2-acetylpyridine (99.6 mmol) was dissolved in 60 mL of toluene, which was added dropwise into the reaction system, and reacted for 5 h. 40 mL glacial acetic acid and 120 mL ice water were mixed homogenously to quench the reaction. The aqueous phase was separated from the organic phase. The aqueous phase was extracted with toluene. The organic phases were combined, washed with ice water to near neutral pH, and dried with anhydrous sodium sulfate. The resulting mixture was evaporated under a reduced pressure to remove the solvent, separated by silica gel column chromatography (using a mixed solution of petroleum ether and ethyl acetate with a volume ratio of 10:1) to obtain 14.11 g of ethyl 3-oxo-3-(pyridin-2-yl) propionate as a light brown transparent liquid with a yield of 73%.

¹NMR (600 MHz, CDCl₃) δ 7.58 (d, J=0.9 Hz, 1H), 7.24 (d, J=3.6 Hz, 1H), 6.54 (dd, J₁=3.6 Hz, J₂=1.6 Hz, 1H), 4.17 (q, J=7.2 Hz, 2H), 3.81 (s, 2H), 1.22 (s, J=7.2 Hz, 3H).

b) 1500 mL of ethanol was added into a 2000 mL three-necked bottle. Nitrogen was introduced for bubbling for 30 min. 8.2 g of metallic sodium (356 mmol) was added under the protection of nitrogen to dissolve completely. Then, 53 g of ethyl 3-oxo-3-(pyridin-2-yl) propionate (274 mmol) and 27.1 g of thiourea (356 mmol) were added, and the mixture was heated to 95° C. to reflux and reacted for 24 h. The resulting mixture was evaporated under a reduced pressure to remove the reaction solvent. Water was added to completely dissolve the residue, and the pH was adjusted to 6-8 with 2 M hydrochloric acid until the precipitation was complete. The solid was filtered under a reduced pressure, and the filter residue was washed with water and petroleum ether successively, and dried under vacuum to obtain. 16.7 g of 6-(pyridin-2-yl)-2-thio-4(1H,3H)-pyrimidinone as a white powdery solid with a yield of 30%.

¹H NMR (400 MHz, DMSO-d₆) δ 12.70 (s, 1H), 11.34 (s, 1H), 8.75 (s, 1H), 8.17 (s, 1H), 8.01 (s, 1H), 7.62 (s, 1H), 6.69 (s, 1H).

c) 375 mL of water was added into a 1000 mL three-necked bottle. 31.8 g of chloroacetic acid (336.5 mmol) was dissolved into water, and 15 g of 6-(pyridin-2-yl)-2-thio-4(1H,3H)-pyrimidinone (73.1 mmol) was added. The mixture was heated to 105° C. to reflux and reacted for 24 h. The resulting mixture was cooled to room temperature, and the pH was adjusted to 6-7 with 2 M sodium hydroxide solution until the precipitation was complete. The solid was filtered under a reduced pressure, and the filter residue was washed with water and petroleum ether successively, and dried under vacuum to obtain 6.13 g of 6-(pyridin-2-yl)-2,4(1 H,3H)-pyrimidinedione as a white powdery solid with a yield of 44.4% and a purity of 98.21%.

¹H NMR (400 MHz, DMSO-d₆) δ 11.23 (s. H), 10.60 (s, 1H), 8.72 (s, 1H), 8.11 (s, 1H), 7.99 (s, 1H), 7.57 (s, 1H), 6.33 (s, 1H).

(2) Synthesis of Compound G3

a) 630 mL of toluene, 473 mL of water and 1.26 mL of ethanol were added into a 2000 ml. three-necked bottle. Nitrogen was introduced for bubbling for 30 min. 105 g of potassium carbonate (759 mmol), 8.5 g of tetrakis(triphenylphosphine)palladium (7.34 mmol), 43.5 g of 5-methyl-2-bromopyridine (253 mmol) and 37.1 g of phenylboronic acid (304 mmol) were added successively under the protection of nitrogen, and the mixture was heated to 105 reflux and reacted for 12 h. The reaction was quenched with 300 mL of water. The aqueous phase was separated from the organic phase. The aqueous phase was extracted with ethyl acetate. The organic phases were combined, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 10:1) to obtain 34.5 g of 5-methyl-2-phenylpyridine as a pale yellow transparent liquid with a yield of 80.5%.

¹H NMR (400 MHz, CDCl₃) δ 8.70 (n, 1H), 8.00 (m, 2H), 7.75 (m, 2H), 7.45 (m, 3H), 7.25 m, 1H).

b) 30 mL of ethylene glycol monomethyl ether and 10 mL of water were added into a 100 mL three-necked bottle. Nitrogen was introduced for bubbling for 30 min. 959.5 mg of 5-methyl-2-phenylpyridine (5.67 mmol) and 0.5 g of iridium trichloride trihydrate (1.42 mmol) were added successively under the protection of nitrogen, and the mixture was heated to 110° C. to reflux and reacted for 24 h. The resulting mixture was cooled to room temperature, and filtered under a reduced pressure. The filter residue was washed with a mixed solution of water and acetone (the volume ratio of water to acetone was 1:1) and petroleum ether successively, and dried under vacuum to obtain 0.66 g of iridium complex dimer as a yellow solid with a yield of 82.4%.

c) 22 mL of ethylene glycol monomethyl ether was added into a 100 mL three-necked bottle. Nitrogen was introduced for bubbling for 30 min, 338.5 mg of iridium complex dimer (0.3 mmol), 227 mg of 6-(pyridin-2-yl)-2,4(1H,3H)-pyrimidinedione (1.2 mmol) and 414.6 mg of potassium carbonate (3 mmol) were added successively under the protection of nitrogen, and the mixture was heated to 125° C. to reflux and reacted for 12 h. The resulting mixture was cooled to room temperature, quenched with 15 mL of water, and extracted with dichloromethane. The organic phase was washed with saturated NaCl solution, and dried with anhydrous sodium sulfate. The resulting mixture was evaporated under a reduced pressure to remove the solvent, separated by silica gel column chromatography (using a mixed solution of dichloromethane and methanol with a volume ratio of 30:1) to obtain 300 mg of compound G3 as a yellow solid with a yield of 69.8%.

¹H NMR (600 MHz, CDCl₃) δ 8.21 (s, 1H), 8.03 (d, J=8.7 Hz, 1H), 7.88 (m, 1H), 7.78 (d, 8.3 Hz, 1H), 7.74 (m, 2H), 7.57 (d, J=7.9 Hz, 2H), 7.50 (t, J==10.4 Hz, 2H), 7.24 (m, 1H), 7.12 (s, 1H), 6.94 (t, J =7.7 Hz, 1H), 6.81 (m, 3H), 6,29 (m, 1H), 6.23 (m, 2H), 2.28 (s, 3H), 2.15 (s, 3H). MS (MALDI-TOF) m/z [M+H]⁺ calcd. for IrC₃₃H₂₇O₂N₅ 718.179, found 717.939.

### Synthesis Example 4: Synthesis of Compound G12

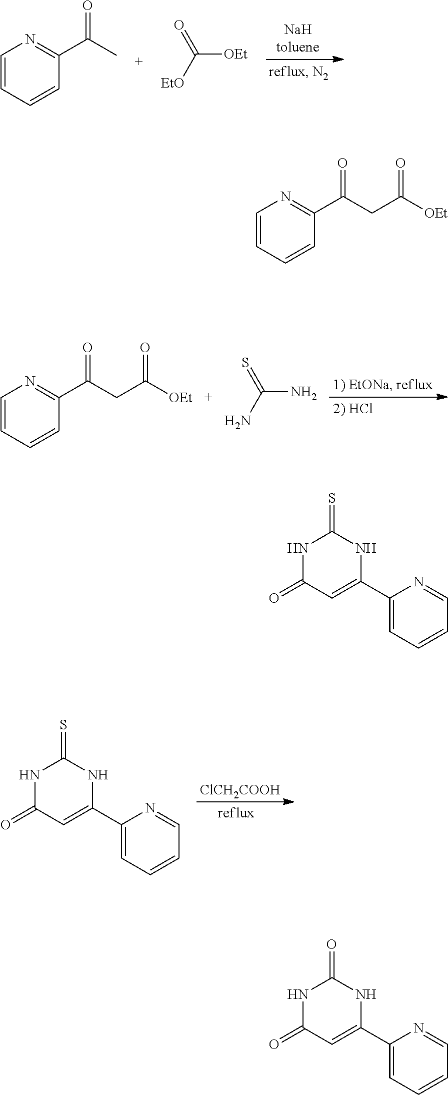

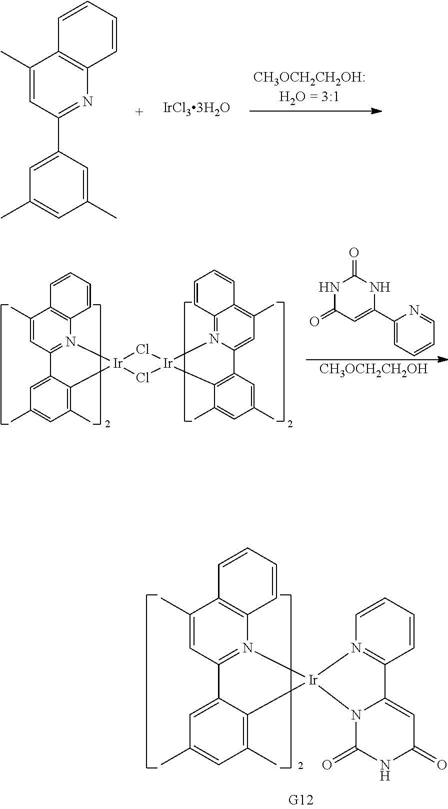

(1) Synthesis of ligand 6-(pyridin-2-yl)-2,4(1H,3H)-primidinedione

a) 240 mL of toluene was added into a 1000 ml, three-necked bottle. Nitrogen was introduced for bubbling for 30 min. 11.1 g of sodium hydride (the mass fraction of sodium hydride was 60%, 277.5 mmol) and 23.4 g of diethyl carbonate (198.4 mmol) were added under the protection of nitrogen, and the mixture was heated to 115° C. to reflux. 12.064 g of 2-acetylpyridine (99.6 mmol) was dissolved in 60 mL of toluene, which was added dropwise into the reaction system, and reacted for 5 h. 40 mL glacial acetic acid and 120 mL ice water were mixed homogeneously to quench the reaction. The aqueous phase was separated from the organic phase. The aqueous phase was extracted with toluene. The organic phases were combined, washed with ice water to near neutral pH, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 10:1) to obtain 14.11 g of ethyl 3-oxo-3-(pyridin-2-yl) propionate as a light brown transparent liquid with a yield of 73%.

¹H NMR (600 MHz, CDCl₃) δ 7.58 (d, J=0.9 Hz, 1H), 7.24 (d, J=3.6 Hz, 1H), 6.54 (dd, J₁=3.6 Hz, J₂=1.6 Hz, 1H), 4.17 (q, J=7.2 Hz, 2H), 3.81 (s, 2H), 1.22 (s, J=7.2 Hz, 3H).

b) 1500 mL of ethanol was added into a 2000 mL three-necked bottle. Nitrogen was introduced for bubbling for 30 min. 8.2 g of metallic sodium (356 mmol) was added under the protection of nitrogen to dissolve completely. Then 53 g of ethyl 3-oxo-3-(pyridin-2-yl) propionate (274 mmol) and 27.1 g of thiourea (356 mmol) were added, and the mixture was heated to 95 to reflux and reacted for 24 h. The resulting mixture was evaporated under a reduced pressure to remove the reaction solvent. Water was added to completely dissolve the residue, and the pH was adjusted to 6-8 with 2 M hydrochloric acid until the precipitation was complete. The solid was filtered under a reduced pressure, and the filter residue was washed with water and petroleum ether successively, and dried under vacuum to obtain 16.7 g of 6-(Pyridin-2-yl)-2-thio-4(1H,3H)-pyrimiditione as a white powdery solid with a yield of 30%.

¹H NMR (400 MHz, DMSO-d₆) δ 12.70 (s, 1H), 11.34 (s, 1H), 8.75 (s, 1H), 8.17 (s, 1H), 8.01 (s, 1H), 7.62 (s, 1H), 6,69 (s, 1H).

c) 375 mL of water was added into a 1000 mL three-necked bottle. 31.8 g of chloroacetic acid (336.5 mmol) was dissolved into water, and 15 g of 6-(pyridin-2-yl)-2-thio-4(1H,3H)-pyrimidinone (73.1 mmol) was added. The mixture was heated to 105° C. to reflux and reacted for 24 h. The resulting mixture was cooled to room temperature, and the pH was adjusted to 6-7 with 2 M sodium hydroxide solution until the precipitation was complete. The solid was filtered under a reduced pressure, and the filter residue was washed with water and petroleum ether successively, and dried under vacuum to obtain 6.13 g of 6-(pyridin-2-yl)-2,4(1H,3H)-pyrimidinedione as a white powdery solid with a yield of 44.4% and a purity of 98.21%.

¹H NMR (400 MHz, DMSO-d₆) δ 11.23 (s, 1H), 10.60 (s, 1H), 8.72 (s, 1 H), 8.11 (s, 1H), 7.99 (s, 1H), 7.57 (s, 1H), 6.33 (s, 1H).

(2) Synthesis of Compound G12

b) 30 mL of ethylene glycol monomethyl ether and 10 mL of water were added into a 100 mL three-necked bottle. Nitrogen was introduced for bubbling for 30 min. 1.4 g of 4-methyl-2-(3,5-dimethylphenyl)quinoline (5.67 mmol) and 0.5 g of iridium trichloride trihydrate (1.42 mmol.) were added successively under the protection of nitrogen, and the mixture was heated to 110° C. to reflux and reacted for 24 h. The resulting mixture was cooled to room temperature, and filtered under a reduced pressure. The filter residue was washed with water, ethanol and petroleum ether successively, and dried under vacuum to obtain 0.74 g of iridium complex dimer as a red solid with a yield of 73%.

b) 22 mL of ethylene glycol monomethyl ether was added into a 100 mL three-necked bottle. Nitrogen was introduced for bubbling for 30 min. 360.2 mg of iridium complex dimer (0.25 mmol), 189.2 mg of 6-(pyridin-2-yl)-2,4(1H,3H)-pyrimidinedione (1.0 mmol) and 345.5 mg of potassium carbonate (2.5 mmol) were added successively under the protection of nitrogen, and the mixture was reacted in an oil bath under 30′C for 18 h. The resulting mixture was cooled to room temperature, quenched with 15 mL of water, and extracted with dichloromethane. The organic phase was washed with saturated NaCI solution, and dried with anhydrous sodium sulfate. The resulting mixture was evaporated under a reduced pressure to remove the solvent, separated by silica gel column chromatography (using a mixed solution of dichloromethane and methanol with a volume ratio of 20:1) to obtain 330 mg of compound G12 as a bright red solid with a yield of 75.6%.

¹H NMR (600 MHz, CDCl₃) δ 8.50 (s, 1H), 8.39 (s, 1H), 8.14 (m ,6H), 7.65 (m, 4H), 7.39 (d, J=7.9 Hz ,1H), 7.35 (d, J=7.5 Hz, 1H), 7.24 (m, 1H), 7.17 (s, 1H), 7.14(s, 1H), 6.72(s, 1H), 6.70 (s, 1H), 6.23 (s, 1H), 2.64 (s, 3H), 2.55 (s, 3H), 2.36 (s, 3H), 2.28 (s, 3H), 2.25 (s, 3H), 2.19 (s, 3H). MS (MALDI-TOF) m/z [M+Na]⁺ calcd. for IrC₄₅H₃₈O₂N₅Na 896.255, found 896.000.

### Synthesis Example 5: Synthesis of Compound G14

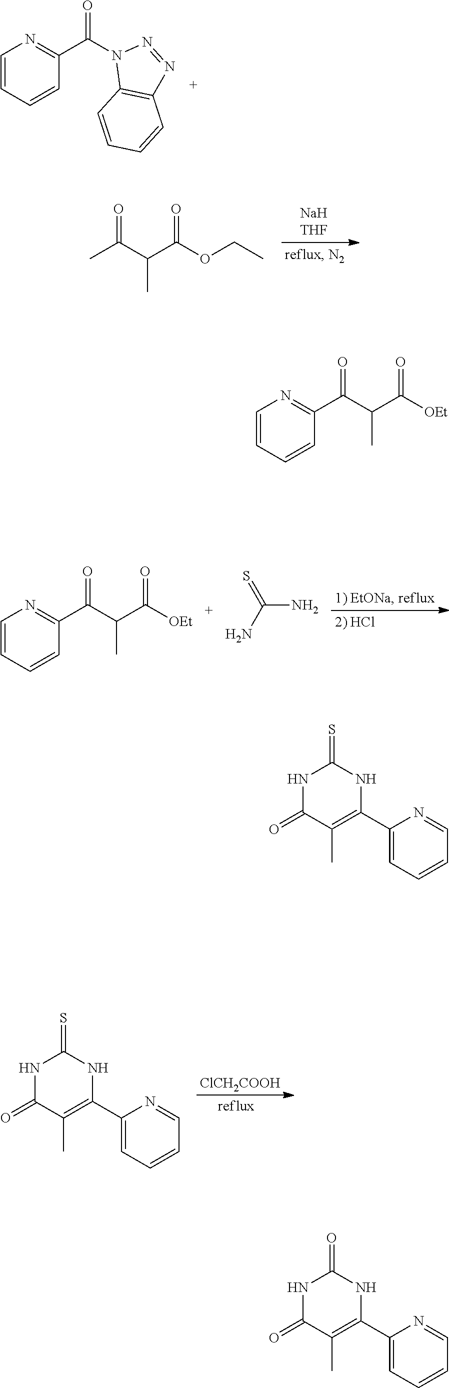

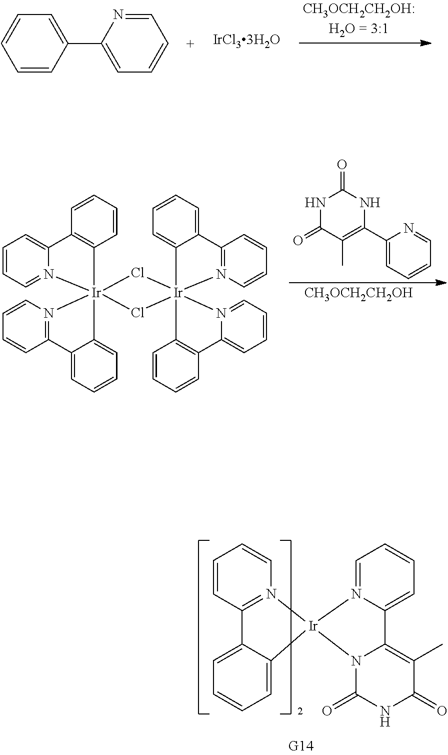

(1) Synthesis of ligand 5-methyl-6-(pyridin-2-yl)-2,4(1H,3H)-pyrimidinedione

a) 240 mL of dried tetrahydrofuran was added into a 1000 mL three-necked bottle. Nitrogen was introduced for bubbling for 30 min. 11.1 g of sodium hydride (the mass fraction of sodium hydride was 60%, 277.5 mmol) and 28.6 2 of ethyl 2-methyl-3-oxobutyrate (198.4 mmol) were added successively under the protection of nitrogen, and stirred at room temperature for 40 min. 22.3 g of 1-(pyridin-2-ylcarbonyl)benzotriazole (99.6 mmol) was dissolved in 60 mL of tetrahydrofuran, which was added dropwise to the reaction system, and reacted at room temperature for 12 h. 20 g of silica gel was added to quench the reaction. The resulting mixture was evaporated under a reduced pressure to remove the solvent, and separated by silica gel column chromatography (using a mixed solution of petroleum ether and ethyl acetate with a volume ratio of 6:1) to obtain 12.38 g of ethyl 2-methyl-3-oxo-3-(pyridin-2-yl) propionate was obtained as a light brown transparent liquid with a yield of 60%.

¹H NMR (600 MHz, CDCl₃) δ 8.66 (d, J=4.8 Hz, 1H), 8.08 (d, J=7.8 Hz, 1H), 7.85 (td, J₁=7.7 Hz, J₂=1.6 Hz, 1H), 7.48 (m, 1H), 4.71 (q, J=7.1 Hz, 1H) 4.13 (q, J=7.1 Hz, 2H), 1.5 (d, J=7.1 Hz, 3H), 1.14 (t, J=7.1 Hz, 3H).

b) 1500 mL of ethanol was added into a 2000 mL three-necked bottle. Nitrogen was introduced for bubbling for 30 min. 8.2 g of metallic sodium (356 mmol) was added under the protection of nitrogen to dissolve completely Then 56.8 g of ethyl 2-methyl-3-oxo-3-(pyridin-2-yl) propionate (274 mmol) and 27.1 g of thiourea (356 mmol) were added, and the mixture was heated to 95° C. to reflux and reacted for 24 h. The resulting mixture was evaporated under a reduced pressure to remove the reaction solvent. Water was added to completely dissolve the residue, and the pH was adjusted to 6-8 with 2 M hydrochloric acid until the precipitation was complete. The solid was filtered under a reduced pressure, and the filter residue was washed with water and petroleum ether successively, and dried under vacuum to obtain 18 g of 5-methyl-6-(pyridin-yl)-2-thio-4(1H,3H)-pyrimidinone as a white powdery solid with a yield of 30%.

¹H NMR (400 MHz, DMSO-d₆) δ 12.39 (s, 1H), 11.47 (s, 1H), 8.51 (s, 1H), 7.43 (s, 1H), 7.41 (s, 1H), 7.39 (s, 1H), 2.39 (s, 3H).

c) 375 mL of water was added into a 1000 mL three-necked bottle. 31.8 g of chloroacetic acid (336.5 mmol) was dissolved into water. and 16 g of 5-methyl-6-(pyridin-2-yl)-2-thio-4(1H,3H)-pyrimidinone (73.1 mmol) was added. The mixture was heated to 105 to reflux and reacted for 24 h. The resulting mixture was cooled to room temperature, and the pH was adjusted to 6-7 with 2 M sodium hydroxide solution until the precipitation was complete. The solid was filtered under a reduced pressure, and the filter residue was washed with water and petroleum ether successively, and dried under vacuum to obtain 7.43 g of 5-methyl-6-(pyridin-2-yl)-2,4(1H,3H)-pyrimidinedione as a white powdery solid with a yield of 50%.

¹H NMR (400 MHz, DMSO-d₆) δ 11.35 (s, 1H), 10.98 (s, 1H), 8.71 (s, 1H), 8.09 (s, 1H), 7.97 (s, 1H), 7.58 (s, 1H), 2.33 (s, 3H).

(2) Synthesis of Compound G14

a) 630 mL of toluene, 473 mL of water and 126 mL of ethanol were added into a 2000 mL three-necked bottle. Nitrogen was introduced for bubbling for 30 min. 105 g of potassium carbonate (759 mmol), 8.5 g of tetrakis(triphenylphosphine)palladium (7.34 mmol), 40 g of 2-bromopyridine (253 mmol) and 37.1 g of phenylboronic acid (304 mmol) were added successively under the protection of nitrogen, and the mixture was heated to 105° C. to reflux and reacted for 12 h. The reaction was quenched with 300 mL of water. The aqueous phase was separated from the organic phase. The aqueous phase was extracted with ethyl acetate. The organic phases were combined, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 10:1) to obtain 31.8 g of 2-phenylpyridine as a pale yellow transparent liquid. with a yield of 81% and a purity of 99.05%.

¹H NMR (400 MHz, CDCl₃) δ 8.70 (m, 1H), 8.00 (m, 2H), 7.75 (m, 2H), 7.45 (m, 3H), 7.25 m, 1H).

b) 60 mL of ethylene glycol monomethyl ether and 20 mL of water were added into a 250 mL three-necked bottle. Nitrogen was introduced for bubbling for 30 nun. 1.76 g of 2-phenylpyridine (11.36 mmol) and 1 g of iridium trichloride trihydrate (2.84 mmol) were added successively under the protection of nitrogen, and the mixture was heated to 110 to reflux and reacted for 24 h. The resulting mixture was cooled to room temperature, and filtered under a reduced pressure. The filter residue was washed with a mixed solution of water and acetone (the volume ratio of water to acetone was 1:1) and petroleum ether successively, and dried under vacuum to obtain 1.28 g of iridium complex diner as a yellow solid with a yield of 84%.

c) 22 mL of ethylene glycol monomethyl ether was added into a 100 mL three-necked bottle. Nitrogen was introduced for bubbling for 30 min. 321.6 mg of iridium complex dimer (0.3 mmol), 244 mg of 5-methyl-6-(pyridin-2-yl)-2,4(1H,3H)-pyrimidinedione (1.2 mmol) and 414.6 mg of potassium carbonate (3 mmol) were added successively under the protection of nitrogen, and the mixture was heated to 125° C. to reflux and reacted for 12 h. The resulting mixture was cooled to room temperature, quenched with 15 mL of water, and extracted with dichloromethane. The organic phase was washed with saturated NaCl solution, and dried with anhydrous sodium sulfate. The resulting mixture was evaporated under a reduced pressure to remove the solvent, and separated by silica gel column chromatography (using a mixed solution of dichloromethane and methanol with a volume ratio of 20:1) to obtain 310 mg of compound G14 as an orange yellow solid with a yield of 73.5%.

¹H NMR (600 MHz, CDCl₃) δ 8.51 (d, J=6.4 Hz, 1H), 8.06 (d, J=7.8 Hz, 1H), 7.86 (m, 6H), 7.68 (m, 2H), 7.65 (m, 2H), 7.33 (d, J=6.1 Hz, 1H), 7.07 (t, J=6.6 Hz, 1H), 6.96 (t, J=8.0 Hz, 1H), 6.83 (m., 4H), 6.28 (m, 2H), 2.21 (s, 3H). MS (MALDI-TOF) m/z [M+H]⁺ calcd. for IrC₃₂H₂₅O₂N₅ 704.164, found 704.055.

### Synthesis Example 6: Synthesis of Compound G21

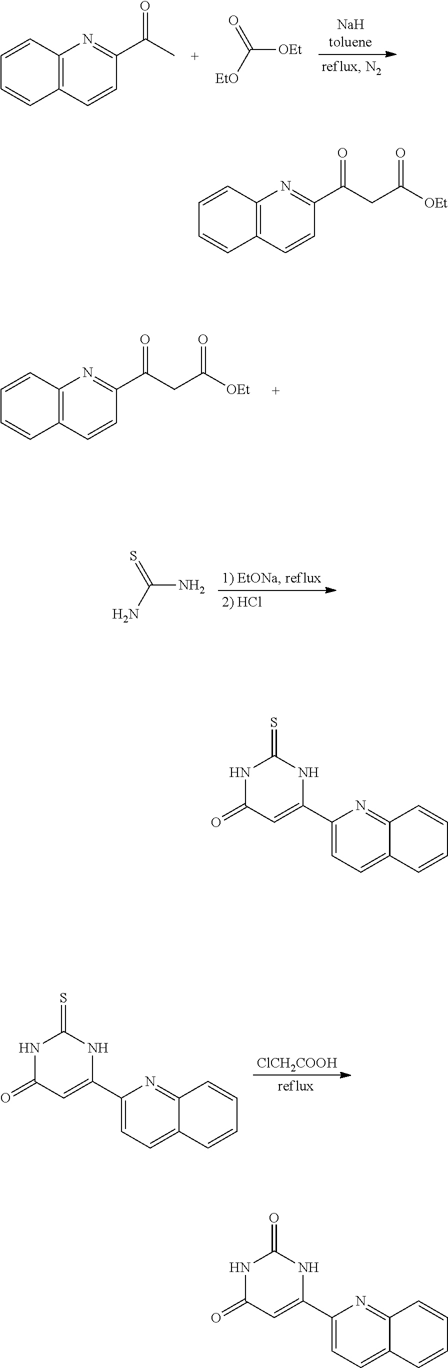

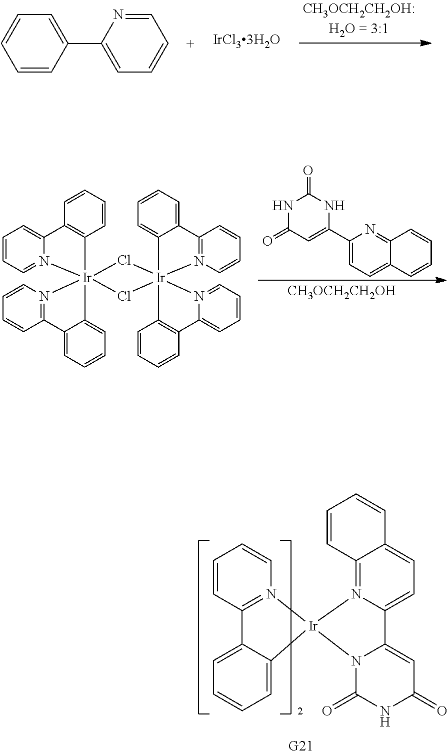

(1) Synthesis of ligand 6-(quino -yl)-2,4(1H,3H)-pyrimidinedione

a) 240 mL of toluene was added into a 1000 mL three-necked bottle. Nitrogen was introduced for bubbling for 30 min, 11.1 g of sodium hydride (the mass fraction of sodium hydride was 60%, 277.5 mmol) and 23.4 g of diethyl carbonate (198.4 mmol) were added under the protection of nitrogen, and the mixture was heated to 115° C. to reflux. 17.05 g of 2-acetylquinoline (99.6 mmol) was dissolved in 60 mL of toluene, which was added dropwise into the reaction system, and reacted for 12 h. 40 mL glacial acetic acid and 120 mL ice water were mixed homogeneously to quench the reaction. The aqueous phase was separated from the organic phase. The aqueous phase was extracted with toluene. The organic phases were combined, washed with ice water to near neutral pH, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 20:1) to obtain 15.75 g of ethyl 3-oxo-3-(quinolin-2-yl) propionate as a white solid with a yield of 65%.

¹H NMR (600 MHz, CDCl₃) δ 8.27 (d, J=8.3 Hz, 1H), 8.16 (t, J=7.2 Hz, 2H), 7.88 (d, J=8.2 Hz, 1H), 7.79 (t, 7.2 Hz, 1H), 7.64 (t, J=7.5 Hz, 1H), 4.36 (s, 2H), 4.22 (q, J=7.2 Hz, 2H), 1.26 (t, J=7.2 Hz, 3H).

b) 1500 mL of ethanol was added into a 2000 mL three-necked bottle. Nitrogen was introduced for bubbling for 30 min. 8.2 g of metallic sodium (356 mmol) was added under the protection of nitrogen to dissolve completely, then 66.7 g of ethyl 3-oxo-3-(quinolin-2-yl) propionate (274 mmol) and 27.1 g of thiourea (356 mmol) were added, and the mixture was heated to 95 to reflux and reacted for 24 h. The resulting mixture was evaporated under a reduced pressure to remove the reaction solvent. Water was added to completely dissolve the residue, and the pH was adjusted to 6-8 with 2 M hydrochloric acid until the precipitation was complete. The solid was filtered under a reduced pressure, and the filter residue was washed with, water and petroleum ether successively, and dried under vacuum to obtain 24.5 g of 6-(quinolin-2-yl)-2-thio-4(1H,3H)-pyrimidinone as a white powdery solid with a yield of 35%.

¹H NMR (400 MHz, DMSO-d₆) δ 12.39 (s, 1H), 12.05 (s, 1H), 8.75 (m, 1H), 7.93 (m, 2H). 7.50 (m, 2H), 7.26 (m, 1H), 6.69 (s, 1H).

c) 375 mL of water was added into a 1000 mL three-necked bottle. 31.8 g of chloroacetic acid (336.5 mmol) was dissolved into water, and 18.7 g of 6-(quinolin-2-yl)-2-thio-4(1H,3H)-pyrimidirione (73.1 mmol) was added. The mixture was heated to 105° C. to reflux and reacted for 24 h. The resulting mixture was cooled to room temperature, and the pH was adjusted to 6-7 with 2 M sodium hydroxide solution until the precipitation was complete. The solid was filtered under a reduced pressure, and the filter residue was washed with water and petroleum ether successively, and dried under vacuum to obtain 7.52 g of 6-(quinolin-2-yl),2,4(1H,3H)-pyrimidinedione as a white powdery solid with a yield of 43%.

¹H NMR (400 MHz, DMSO-d₆) δ 10.84 (s 1H), 9.98 (s, 1H), 8.65 (m, 1H), 7.87 (m, 2H), 7.38 (m, 2H), 7.31 (m, 1H ), 6.55 (s, 1H).

(2) Synthesis of Compound G21

a) 630 mL of toluene, 473 mL of water and 126 m of ethanol were added into a 2000 mL three-necked bottle. Nitrogen was introduced for bubbling for 30 min, 105 g of potassium carbonate (759 mmol), 8.5 g of tetrakis(triphenylphosphine)palladium (7.34 mmol), 40 g of 2-bromopyridine (253 mmol) and 37.1 g of phenylboronic acid (304 mmol) were added successively under the protection of nitrogen, and the mixture was heated to 105° C. to reflux and reacted for 12 h. The reaction was quenched with 300 mL of water. The aqueous phase was separated front the organic phase. The aqueous phase was extracted with ethyl acetate. The organic phases were combined, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 10:1) to obtain 31.8 g of 2-phenylpyridine as a pale yellow transparent liquid with a yield of 81% and a purity of 99.05%.

¹H NMR (400 MHz, CDCl₃) δ 8.70 (m, 1H), 8.00 (m, 2H), 7.75 (m, 2H). 7.45 (m, 3H), 7.25 (m, 1H).

b) 60 mL of ethylene glycol monomethyl ether and 20 mL of water were added into a 250 mL three-necked bottle. Nitrogen was introduced for bubbling for 30 min. 1.76 g of 2-phenylpyridine (11.36 mmol) and 1 g of iridium trichloride trihydrate (2.84 mmol) were added successively under the protection of nitrogen, and the mixture was heated to 110° C. to reflux and reacted for 24 h. The resulting mixture was cooled to room temperature, and filtered under a reduced pressure. The filter residue was washed with a mixed solution of water and acetone (the volume ratio of water to acetone was 1:1) and petroleum ether successively, and dried under vacuum to obtain 1.28 g of iridium complex dimer as a yellow solid with a yield of 84%.

c) 22 mL of ethylene glycol monomethyl ether was added into a 100 mL three-necked bottle. Nitrogen was introduced for bubbling for 30 min. 321.6 mg of iridium complex dimer (0.3 mmol), 287 mg of 6-(quinolin-2-yl)-2,4(1H,3H)-pyrimidinedione (1.2 mmol) and 414.6 mg of potassium carbonate (3 mmol) were added successively under the protection of nitrogen, and the mixture was heated to 125° C. to reflux and reacted for 12 h. The resulting mixture was cooled to room temperature, quenched with 15 mL of water, and extracted with dichloromethane. The organic phase was washed with saturated NaCl solution, and dried with anhydrous sodium sulfate. The resulting mixture was evaporated under a reduced pressure to remove the solvent, and separated by silica gel column chromatography (using a mixed solution of dichloromethane and methanol with a volume ratio of 20:1) to obtain 284 mg of compound G21 as an orange red solid with a yield of 64%.

¹H NMR (600 MHz, CDCl₃) δ 8.78 (d, J=6.3 Hz, 1H), 8.21 (d, 7.8 Hz, 1H), 7.80 (m, 8H), 7.71 (m, 2H), 7.61 (m, 2H), 7.33 (d, J=6.2 Hz, 1H), 7.07 (t, J=6.5 Hz, 1H), 6.96 (t, J=8.3 Hz, 1H), 6.79 (m, 4H), 6.26 (m, 2H), 6.16 (d, J=7.5 Hz, 1H). MS (MALDI-TOF) m/z calcd. for IrC₃₅H₂₅O₂N₅ 740.164, found 740.021.

### Synthesis Example 7: Synthesis of Compound G27

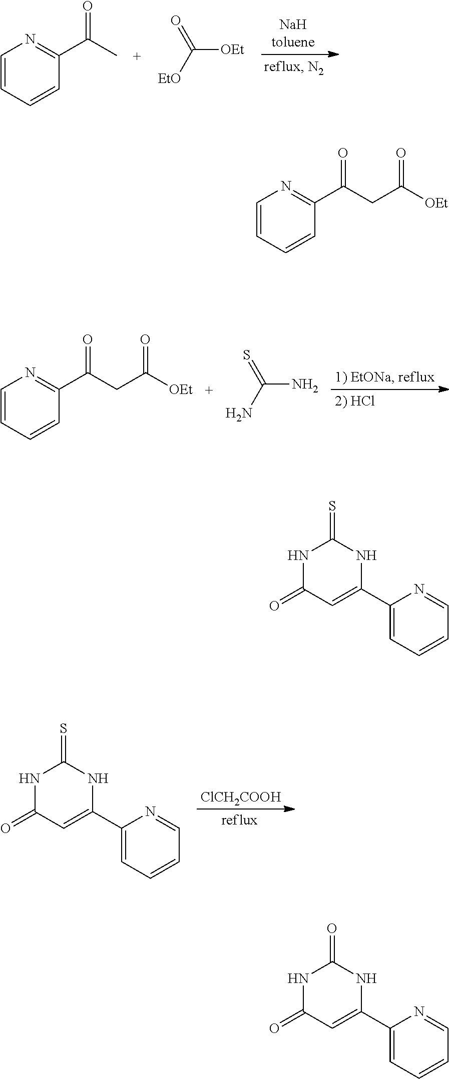

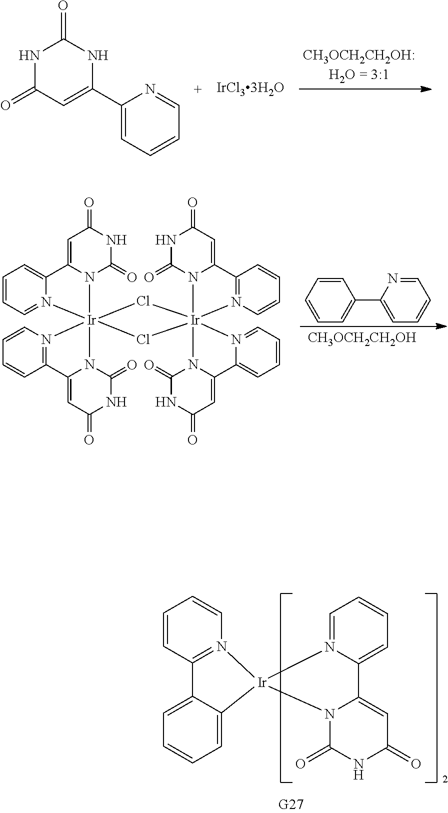

(1) Synthesis of ligand 6-(pyridin-2-yl)-2,4(1H,3H)-pyrimidinedione

a) 240 mL of toluene was added into a 1000 mL three-necked bottle. Nitrogen was introduced for bubbling for 30 min. 11.1 g of sodium hydride (the mass fraction of sodium hydride was 60%, 277.5 mmol) and 23.4 g of diethyl carbonate (198.4 mmol) were added under the protection of nitrogen, and the mixture was heated to 115° C. to reflux. 12.064 g of 2-acetylpyridine (99.6 mmol) was dissolved in 60 mL of toluene, which was added dropwise into the reaction system, and reacted for 5 h. 40 mL glacial acetic acid and 120 mL ice water were mixed homogenously to quench the reaction. The aqueous phase was separated from the organic phase. The aqueous phase was extracted with toluene. The organic phases were combined, washed with ice water to near neutral pH, and dried with anhydrous sodium sulfate. The resulting mixture was evaporated under a reduced pressure to remove the solvent, and separated by silica gel column chromatography (using a mixed solution of petroleum ether and ethyl acetate with a volume ratio of 10:1) to obtain 14.11 a of ethyl .3-oxo-3-(pyridin-2-yl) propionate as a light brown transparent liquid with a yield of 73%.

¹H NMR (600 MHz, CDCl₃) δ 7.58 (d, J=0.9 Hz, 1H), 7.24 (d, J=3.6 Hz, 1H), 6.54 (dd, J₁=3.6 Hz, or, 1.6 Hz, 1H), 4.17 (q, J=7.2 Hz, 2H), 3.81 (s, 2H), 1.22 (s, J=7.2 Hz, 3H).

b) 1500 mL of ethanol was added into a 2000 mL three-necked bottle. Nitrogen was introduced for bubbling for 30 min. 8.2 g of metallic sodium (356 mmol) was added under the protection of nitrogen to dissolve completely. Then, 53 g of ethyl 3-oxo-3-(pyridin-2-yl) propionate (274 mmol) and 27.1 g of thiourea (356 mmol) were added, and the mixture was heated to 95° C. to reflux and reacted for 24 h. The resulting mixture was evaporated under a reduced pressure to remove the reaction solvent:, Water was added to completely dissolve the residue, and the pH was adjusted to 6-8 with 2 M hydrochloric acid until the precipitation was complete. The solid was filtered under a reduced pressure, and the filter residue was washed with water and petroleum ether successively, and dried under vacuum to obtain 16.7 g of 6-(pyridin-2-yl)-2-thio-4(1H,3H)-pyrimidinone as a white powdery solid with a yield of 30%.

¹H NMR (400 MHz, DMSO-d₆) δ 12.70 (s, 1H), 11.34 (s, 1H), 8.75 (s, 1H), 8.17 (s, 1H), 8.01 (s, 1H), 7.62 (s, 1H), 6.69 (s, 1H).

c) 375 mL of water was added into a 1000 mL three-necked bottle. 31.8 g of chloroacetic acid (336.5 mmol) was dissolved into water, and 15 g of 6-(pyridin-2-yl)-2-thio-4(1H,3H)-pyrimidinone (73.1 mmol) was added. The mixture was heated to 105° C. to reflux and reacted for 24 h. The resulting mixture was cooled to room temperature, and the pH was adjusted to 6-7 with 2 M sodium hydroxide solution until the precipitation was complete. The solid was filtered under a reduced pressure, and the filter residue was washed with water and petroleum ether successively, and dried under vacuum to obtain 6.13 g of 6-(pyridin-2-yl)-2,4(1H,3H)-pyrimidinedione as a white powdery solid with a yield of 44.4% and a purity of 98.21%.

¹H NMR (400 MHz, DMSO-d₆) δ 11.23 (s, 1H), 10.60 (s, 1H), 8.72 (s, 1H), 8.11 (s, 1H), 7.99 (s, 1H), 7.57 (s, 1H), 6.33 (s, 1H).

(2) Synthesis of Compound G27

a) 60 mL of ethylene glycol monomethyl ether and 20 mL of water were added into a 250 mL three-necked bottle. Nitrogen was introduced for bubbling for 30 min. 2.15 g of 6-(pyridin-2-yl)-2,4(1H,3H)-pyrimidinedione (11.36 mmol) and 1 g of iridium trichloride trihydrate (2.84 mmol) were added successively under the protection of nitrogen, and the mixture was heated to 110° C. to reflux and reacted for 24 h. The resulting mixture was cooled to room temperature, and filtered under a reduced pressure. The filter residue was washed with a mixed solution of water and acetone (the volume ratio of water to acetone was 1:1) and petroleum ether successively, and dried under vacuum to obtain 1.4 g of iridium complex dimer as a dark red solid with a yield of 82%.

b) 22 mL of ethylene glycol monamethyl ether was added into a 100 mL three-necked bottle. Nitrogen was introduced for bubbling for 30 min, 362.4 mg of iridium complex dimer (0.3 mmol), 186 mg of 2-phenylpyridine (1.2 mmol) and 414.6 mg of potassium carbonate (3 mmol) were added successively under the protection of nitrogen, and the mixture was heated to 125° C. to reflux for 24 h. The resulting mixture was cooled to room temperature, quenched with 15 mL of water, and extracted with dichloromethane. The organic phase was washed with saturated NaCl solution, and dried with anhydrous sodium sulfate. The resulting mixture was evaporated under a reduced pressure to remove the solvent, and separated by silica gel column chromatography (using a mixed solution of dichloromethane and methanol with a volume ratio of 20:1) to obtain 295 mg of compound G27 as an orange yellow solid with a yield of 68%.

¹H NMR (600 MHz, CDCl₃) δ 8.25 (s, 1H), 8.23 (s, 1H), 8.03 (m, 2H), 7.91 (m, 1H), 7.73 (m, 2H), 7.50 (m, 4H), 7.38 (m, 4H), 7.05 (m, 2H), 6.95 (m, 1H), 6.31 (s, 1H), 6.30 (s, 1H). MS (MALDI-TOF) m/z [M+H]⁺ calcd. for IrC₂₇H₁₉O₆N₉ 724.128, found 724.363.

Other compounds of the present application were synthesized by methods similar to those in Synthesis Examples 1-7.

### Example 1

A indium tin oxide (ITO) transparent conductive layer with a thickness of 130 nm was coated on a glass plate, which was ultrasonically treated in a commercial cleaning agent, rinsed in deionized water, ultrasonically deoiled in acetone-ethanol mixed solvent, dried in a clean environment until the water was completely removed, washed with ultraviolet light and ozone, and bombarded with low-energy cation beams.

Then, the above glass substrate with anode was placed in a vacuum chamber, and vacuumized to less than 10⁻⁵ torr. A hole injection layer was evaporated under vacuum on the anode layer film, wherein the material of the hole injection layer comprised a hole injection layer material HT-34 and a p-type dopant p-1. The evaporation was performed by using a multi-source co-evaporation method, and the evaporation rate of the hole injection layer material HT-34 was adjusted to 0.1 nm/s. The evaporation rate of p-type dopant p-I was 3% of that of the hole injection layer material HT-34, The total thickness of the evaporated film was 10 nm.

Then, a hole transport layer was evaporated under vacuum on the hole injection layer by using a hole transport layer material HT-34. The evaporation rate was 0.1 nm/s, and the thickness of the evaporated film was 112 nm.

Then, an electron blocking layer was evaporated under vacuum on the hole transport layer by using an electron blocking layer material EB-05. The evaporation rate was 0.1 nm/s, and the thickness of the evaporated film was 10 nm.

Then, a luminescent layer was evaporated on the electron blocking layer, wherein the luminescent layer comprised a host material RH-11. and a guest material G1 provided by the present application. A mass ratio of the host material RH-11 to the guest material G1 was 97:3. The evaporation was performed by using a multi-source co-evaporation method. The evaporation rate of the host material was adjusted to 0.1 nm/s. The evaporation rate of the guest material was 3% of that of the host material RH-11 The total thickness of the evaporated film was 20 nm,

Then, a hole blocking layer was evaporated under vacuum on the luminescent layer by using a hole blocking layer material HB-05, The evaporation rate was 0.1 nm/s, and the thickness of the evaporated film was 5 nm.

Then, an electron transport layer was evaporated under vacuum on the hole blocking layer, wherein a material of the electron transport layer comprised an electron transport material ET-43 and n-type dopant n-1. A mass ratio of the electron transport material ET-43 to the n-type dopant n-1 was 1:1. The evaporation was performed by using a multi-source co-evaporation method, and the evaporation rate of the electron transport material ET-43 was adjusted to 0.1 nm/s. The evaporation rate of n-type dopant n-1 was 3% of that of the electron transport material ET-43. The total thickness of the evaporated film was 35 nm.

Finally, a cathode with a thickness of 18 nm was evaporated on the electron transport layer. The evaporation rate was 0.1 nm/s. A cathode material was a mixture of magnesium and aluminum, and a mass ratio of magnesium to aluminum was 1:9.

### Examples 2-13

The procedure was the same as that in Example 1, except GI was replaced by compounds G2. G3, G8, G9, G10, G12, G14, G19, G21, G22, G23 and G27, respectively.

### Comparative Example 1

The procedure was the same as that in Example 1, except G1 was replaced by compound RPD-8.

### Comparative Example 2

The procedure was the same as that in Example 1, except G1 was replaced by compound RPD-1.5.

### Test Method for the Performance of the Organic Electroluminescent Device

Under the same brightness, the driving voltage, current efficiency and the lifetime of the organic electroluminescent device prepared in Examples and Comparative Examples were measured by using a digital source meter and a brightness meter. Specifically; the voltage was raised at a rate of 0.1 V/s. The driving voltage was the voltage when the brightness of the organic electroluminescent device reached 6000 nit, and the current density was measured at this time. The ratio of the brightness to the current density was current efficiency. The LT95 lifetime was measured as follows: using a luminance meter, keeping the current constant under the brightness of 6000 nit, and measuring the consumed time when the brightness of the organic electroluminescent device was decreased to 5700 cd/m². The unit was hour,

TABLE 1
Performance Comparison of Devices in Examples and Comparative Examples

| | Host | Guest | | | | | | |
|---|---|---|---|---|---|---|---|---|
| | Material of | Material of | Driving | Current | LT95 | Initial | Evaporation | Luminous |
| | Luminescent | Luminescent | Voltage | Efficiency | Lifetime | Brightness | Temperature | Wavelength |
| | Layer | Layer | (V) | (cd/Å) | (h) | (nit) | (° C.) | (nm) |
| Example 1 | RH11 | G1 | 4.0 | 50.7 | 293 | 6000 | 345 | 610 |
| Example 2 | RH11 | G2 | 4.1 | 50.3 | 300 | 6000 | 339 | 610 |
| Example 3 | RH11 | G3 | 4.0 | 50.9 | 306 | 6000 | 343 | 611 |
| Example 4 | RH11 | G8 | 4.0 | 49.5 | 294 | 6000 | 350 | 595 |
| Example 5 | RH11 | G9 | 4.0 | 58.9 | 308 | 6000 | 347 | 620 |
| Example 6 | RH11 | G10 | 4.0 | 58.5 | 314 | 6000 | 349 | 625 |
| Example 7 | RH11 | G12 | 3.9 | 59.0 | 316 | 6000 | 337 | 610 |
| Example 8 | RH11 | G14 | 4.1 | 56.3 | 305 | 6000 | 339 | 620 |
| Example 9 | RH11 | G19 | 4.2 | 55.1 | 310 | 6000 | 346 | 630 |
| Example 10 | RH11 | G21 | 4.0 | 56.3 | 305 | 6000 | 338 | 633 |
| Example 11 | RH11 | G22 | 4.3 | 54.6 | 308 | 6000 | 344 | 630 |
| Example 12 | RH11 | G23 | 4.2 | 50.0 | 299 | 6000 | 359 | 595 |
| Example 13 | RH11 | G27 | 4.0 | 50.8 | 302 | 6000 | 345 | 610 |
| Comparative | RH11 | RPD-8 | 4.5 | 45.5 | 289 | 6000 | 362 | 622 |
| Example 1 | | | | | | | | |
| Comparative | RH11 | RPD-15 | 4.5 | 47.3 | 286 | 6000 | 370 | 637 |
| Example 2 | | | | | | | | |

As can be seen from the data in the above table, the organic electroluminescent devices were prepared in Examples 1 to 13 by using the compounds G1, G2, G3, G8, G9, G10, G12, G14, G19, G21, G22, G23 and G27 provided by the present application as the guest materials of the luminescent layer. Compared with the organic electroluminescent devices prepared in Comparative Example 1 and Comparative Example 2, in which the materials known in the prior art were used as the guest materials of the luminescent layer of the organic electroluminescent device, the devices of the present application had lower driving voltage, higher current efficiency and longer LT95 lifetime. Therefore, using the compound of the present application as the guest material of the luminescent layer of the organic electroluminescent device can effectively adjust the luminous wavelength, improve the luminous efficiency and prolong the service life of the device. In addition, when the compound provided by the present application is used as the guest material of the luminescent layer for preparing the luminescent layer, the evaporation temperature of the luminescent layer is lower, which is beneficial to the processing of the organic electroluminescent device.

The above examples are only the preferred examples of the present application, and are not used to limit the protection scope of the present application, any modification, equivalent substitution, improvement and the like made within the spirit and principles of the present application are included in the protection scope of the present application.

1. A compound having a structure as shown in formula (I): 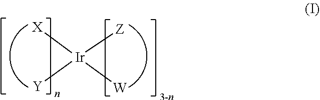
wherein,
X-Y is a diaryl bidentate ligand, a ligating atom for X and Y is C or N, and X-Y is a bivalent radical of a compound or a bivalent radical of a derivative of a compound selected from the group consisting of: 2-(1-naphthyl)benzoxazole, 2-phenylbenzoxazole, 2-phenylbenzothiazole, thienylpyridine, phenylpyridine, benzothiophenpyridine, phenylimine, vinylpyridine, arylquinoline, arylisoquinoline, pyridylnaphthalene, pyridylpyrrole, pyridylimidazole, pyridylindazole, phenylimidazole, phenyltriazole, phenylindole, phenylpyrimidine, phenylpyridazine, bipyridine and biphenyl;
Z-W is a diaryl bidentate ligand containing a natural heterocyclic ring, a ligating atom for Z is C or N, and Z is a bivalent radical of a compound or a bivalent radical of a derivative of a compound selected from the group consisting of: benzene, naphthalene, pyridine, imidazole, pyrrole, tetrahydropyrrole, piperidine, morpholine, quinoline, isoquinoline, pyrimidine, pyrazine, pyridazine, 1,3,4-triazole, tetrazole, oxazole and thiazole; a ligating atom for W is N, and W is a bivalent radical of a compound or a bivalent radical of a derivative of a compound selected from the group consisting of: adenine, guanine, thymine, cytosine and uracil; and
n is selected from the group consisting of 0, 1 and 2.

2. The compound according to claim 1, wherein,
when X-Y is the bivalent radical of a derivative of the compound selected from the group consisting of: 2-(1-naphthyl)benzoxazole, 2-phenylbenzoxazole, 2-phenylbenzothiazole, thienylpyridine, phenylpyridine, benzothiophenpyridine, phenylimine, vinylpyridine, arylquinoline, arylisoquinoline, pyridylnaphthalene, pyridylpyrrole, pyridylimidazole, pyridylindazole, phenylimidazole, phenyltriazole, phenylindole, phenylpyrimidine, phenylpyridazine, bipyridine and biphenyl, the derivative of the compound is a substituted compound, and the substituent is each independently selected from the group consisting of: halogen, unsubstituted C₁-C₁₀ alkyl or C₁-C₁₀ alkyl substituted by halogen, unsubstituted C₆-C₁₄ aryl or C₆-C₁₄ aryl substituted by halogen, and unsubstituted C₆-C₁₄ arylalkoxy or C₆-C₁₄ arylalkoxy substituted by halogen;
when Z is the bivalent radical of a derivative of the compound selected from the group consisting of: benzene, naphthalene, pyridine, imidazole, pyrrole, tetrahydropyrrole, piperidine, morpholine, quinoline, isoquinoline, pyrimidine, pyrazine, pyridazine, 1,3,4-triazole, tetrazole, oxazole and thiazole, the derivative of the compound is a substituted compound, and the substituent is each independently selected from the group consisting of: hydrogen, deuterium, halogen, unsubstituted C₁-C₁₀ alkyl or C₁-C₁₀ alkyl substituted by Ra, unsubstituted C₃-C₁₀ cycloalkyl or C₃-C₁₀ cycloalkyl substituted by Ra, unsubstituted C₆-C₁₄ aryl or C₆-C₁₄ aryl substituted by Ra, unsubstituted C₂-C₁₄ heteroaryl or C₂-C₁₄ heteroaryl substituted by Ra, unsubstituted C₁-C₁₀ alkoxy or C₁-C₁₀ alkoxy substituted by Ra, and unsubstituted amino or amino substituted by Ra; the heteroatom in the heteroaryl is selected from the group consisting of 0, S and N; the substituent Ra of each group is each independently selected from the group consisting of deuterium, halogen, nitro, cyano, C₁-C₄ alkyl, phenyl, biphenyl, terphenyl and naphthyl;
when W is the bivalent radical of a derivative of the compound selected from the group consisting of: adenine, guanine, thymine, cytosine and uracil, the derivative of the compound is a substituted compound, and the substituent is each independently selected from the group consisting of: hydrogen, deuterium, halogen, unsubstituted C₁-C₁₀ alkyl or C₁-C₁₀ alkyl substituted by Ra, unsubstituted C₃-C₁₀ cycloalkyl or C₃-C₁₀ cycloalkyl substituted by Ra, unsubstituted C₆-C₁₄ aryl or C₆-C₁₄ aryl substituted by Ra, unsubstituted C₂-C₁₄ heteroaryl or C₂-C₁₄ heteroaryl substituted by Ra, unsubstituted C₁-C₁₀ alkoxy or C₁-C₁₀ alkoxy substituted by Ra, and unsubstituted amino or amino substituted by Ra; the heteroatom in the heteroaryl is selected from the group consisting of O, S and N; the substituent Ra of each group is each independently selected from the group consisting of deuterium, halogen, nitro, cyano, C₁-C₄ alkyl, phenyl, biphenyl, terphenyl and naphthyl.

3. The compound according to claim 1, wherein X-Y is the bivalent radical of the compound selected from the group consisting of: 2-(1-naphthyl)benzoxazole, 2-phenylbenzoxazole, 2-phenylbenzothiazole, thienylpyridine, phenylpyridine, benzothiophenpyridine, phenylimine, vinylpyridine, arylquinoline, arylisoquinoline, pyridylnaphthalene, pyridylpyrrole, pyridylimidazole, pyridylindazole, phenylimidazole, phenyltriazole, phenylindole, phenylpyrimidine, phenylpyridazine, bipyridine, biphenyl, 5-methyl-2-phenylpyridine, 5-methyl-2-(2,4-difluorophenyl)pyridine, 2-(2,4-difluorophenyl)-5-trifluoromethylpyridine, 2-(2,4-difluorophenyl)pyrimidine, 2-(3,4-difluorophenyl)-1-(2,4,6-trimethylphenyl)imidazole, 1,3-diethyl-5-(3-fluorophenyl)triazole, 1-(3,5-dimethylphenyl)isoquinoline, 6-isopropyl-1-(3,5-dimethylphenyl)isoquinoline, 2-(3,5-dimethylphenyl)quinoline, 4-methyl-2-(3,5-dimethylphenyl)quinoline, 2′,4′-difluoro-2,3′-bipyridine, 1-methyl-3-(4-methylphenyl)-2,3-dihydroimidazole, 6-phenyl-3-(2,4,6-trimethylphenoxy)pyridazine, 1-(4-sec-butylphenyl)isoquinoline, 3-isopropyl-2-(3-methylphenyl)quinoline, and 5-methyl-2-(3,5-dimethylphenyl)pyridine.

4. The compound according to claim 1, which has one of the following general formulae: 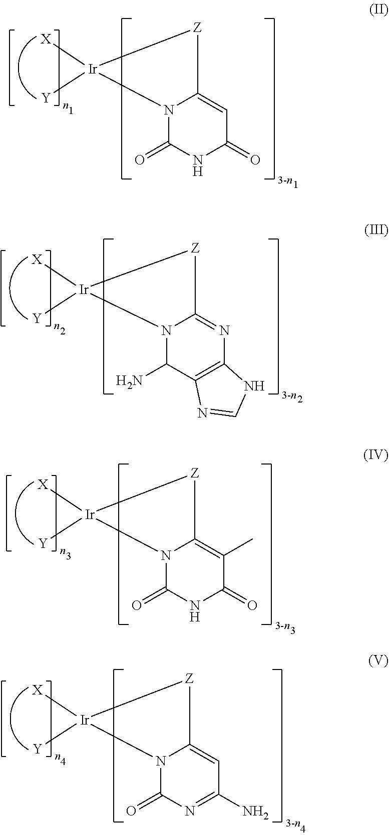
wherein,
n₁-n₄ are each independently selected from the group consisting of 0, 1 and 2.

5. The compound according to claim 1, which has one of the following general formulae: 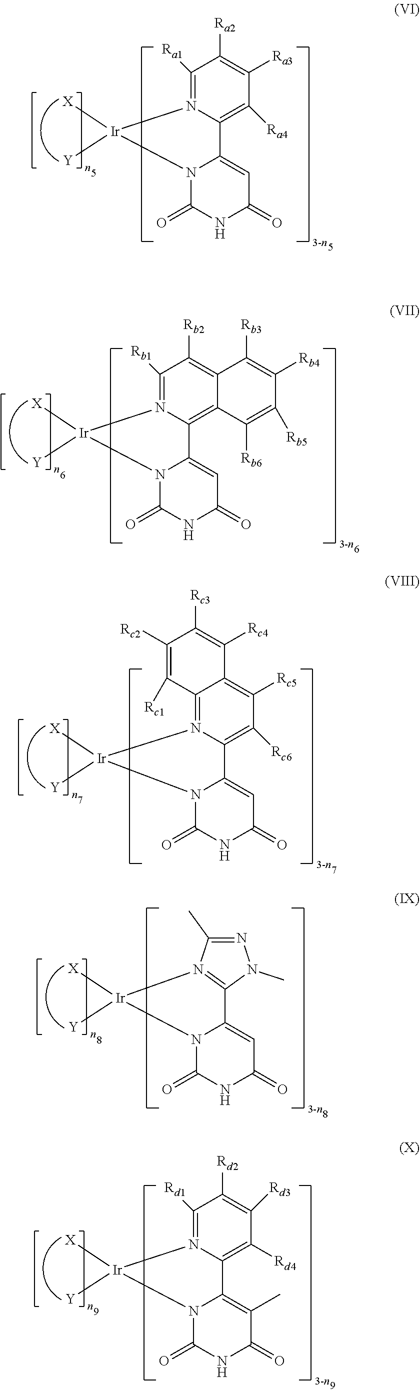 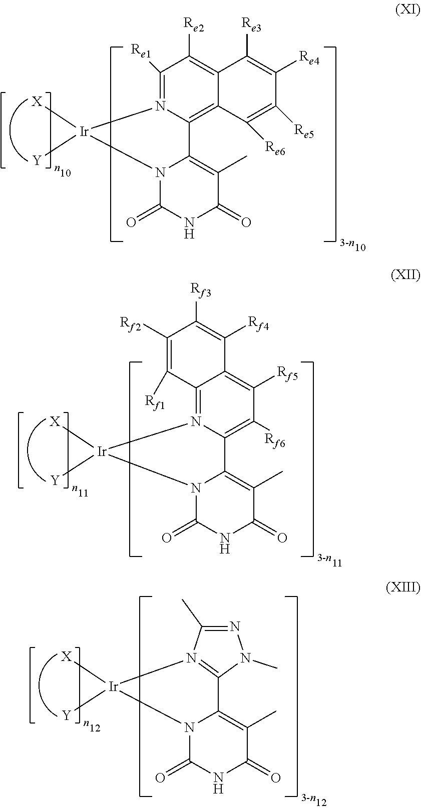
wherein,
Rₐ₁-Rₐ₄, R_{b1}-R_{b6}, R_{c1}-R_{c6}, R_{d1}-R_{d4}, Rₑ₁-Rₑ₆, and R_{f1}-R_{f6} are each independently selected from the group consisting of hydrogen, deuterium, halogen, unsubstituted C₁-C₁₀ alkyl or C₁-C₁₀ alkyl substituted by Ra, unsubstituted C₃-C₁₀ cycloalkyl or C₃-C₁₀ cycloalkyl substituted by Ra, unsubstituted C₆-C₁₄ aryl or C₆-C₁₄ aryl substituted by Ra, unsubstituted C₂-C₁₄ heteroaryl or C₂-C₁₄ heteroaryl substituted by Ra, unsubstituted C₃-C₁₀ alkoxy or C₁-C₁₀ alkoxy substituted by Ra, and unsubstituted amino or amino substituted by Ra;
the heteroatom in the heteroaryl is selected from the group consisting of O, S and N;
the substituent Ra of each group is each independently selected from the group consisting of deuterium, halogen, nitro, cyano, C₁-C₄ alkyl, phenyl, biphenyl, terphenyl and naphthyl;
n₅-n₁₂ are each independently selected from the group consisting of 0, 1 and 2.

6. The compound according to claim 1, which is selected from any one of the following structures G1-G30:

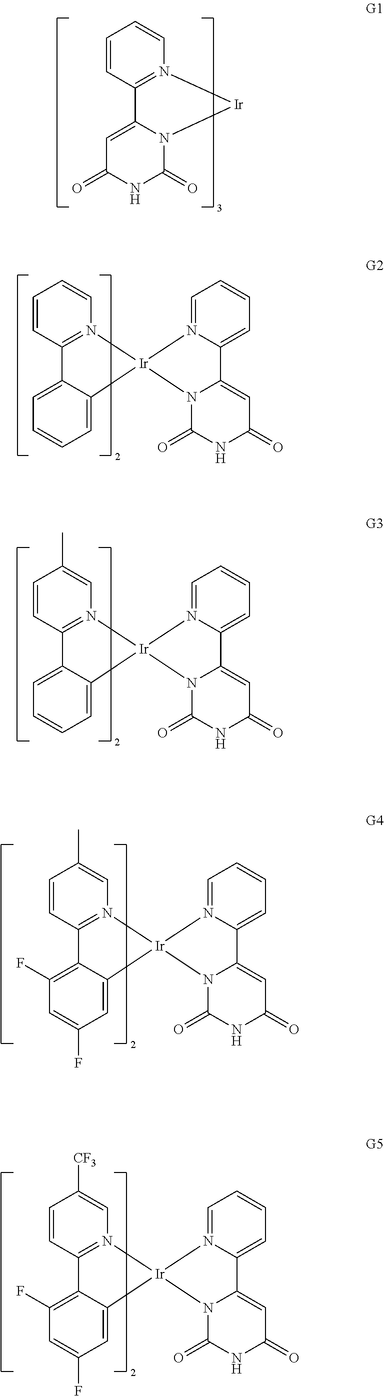

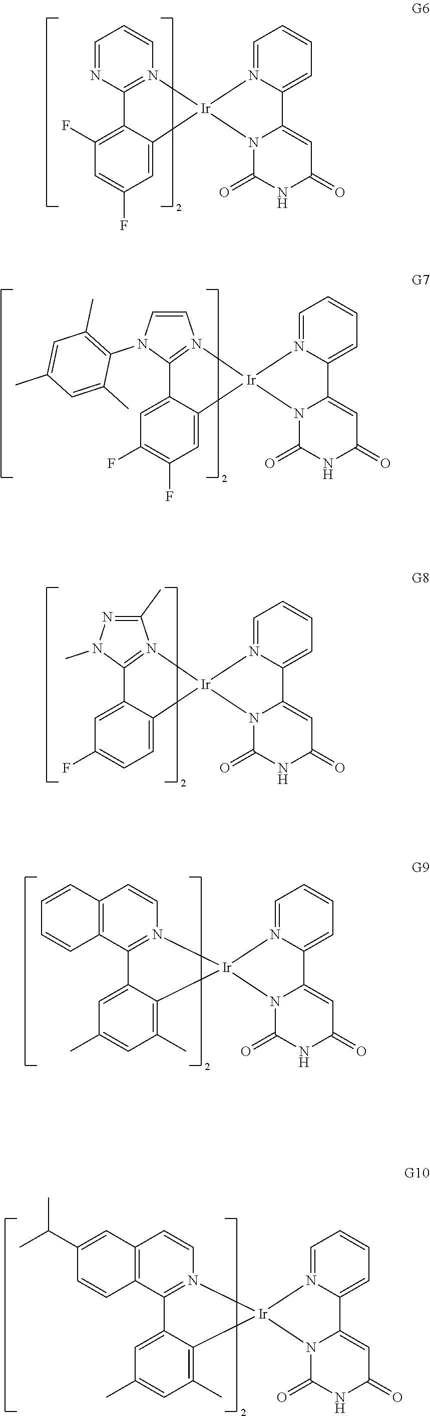

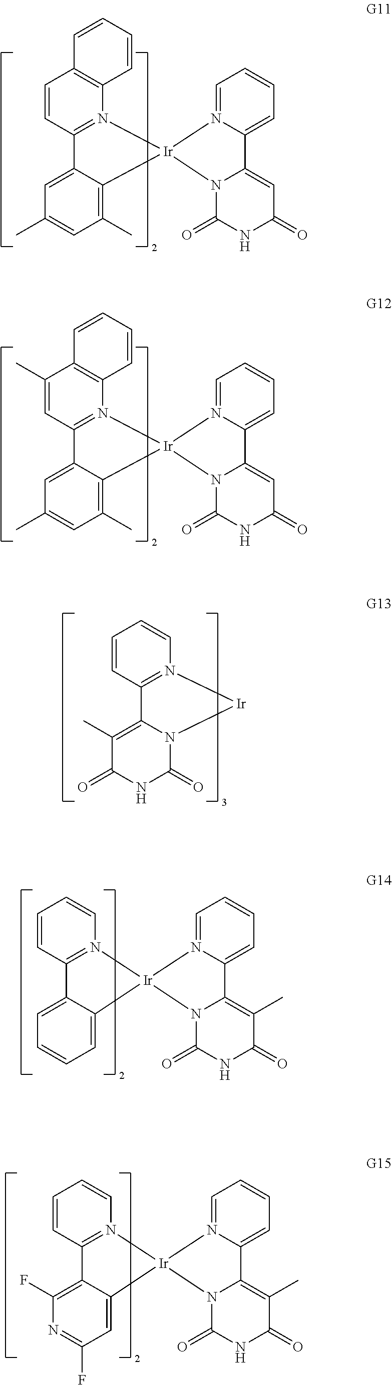

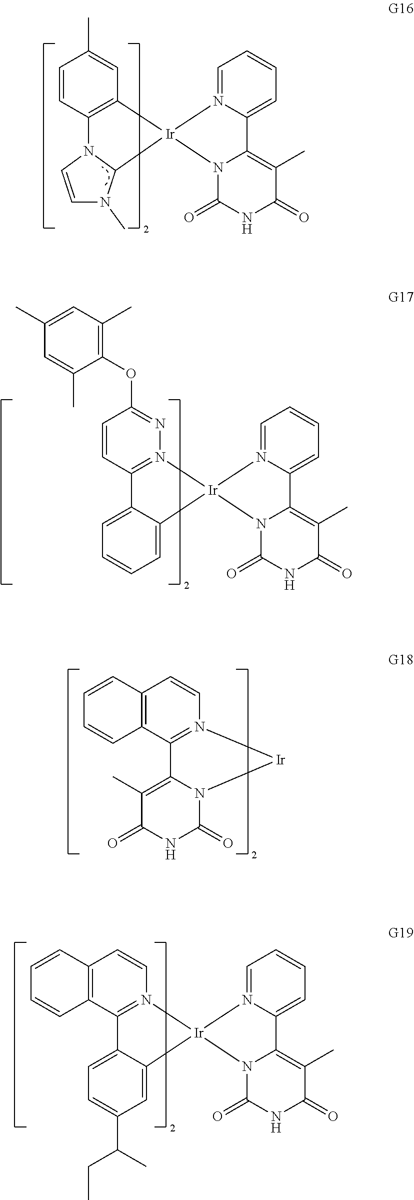

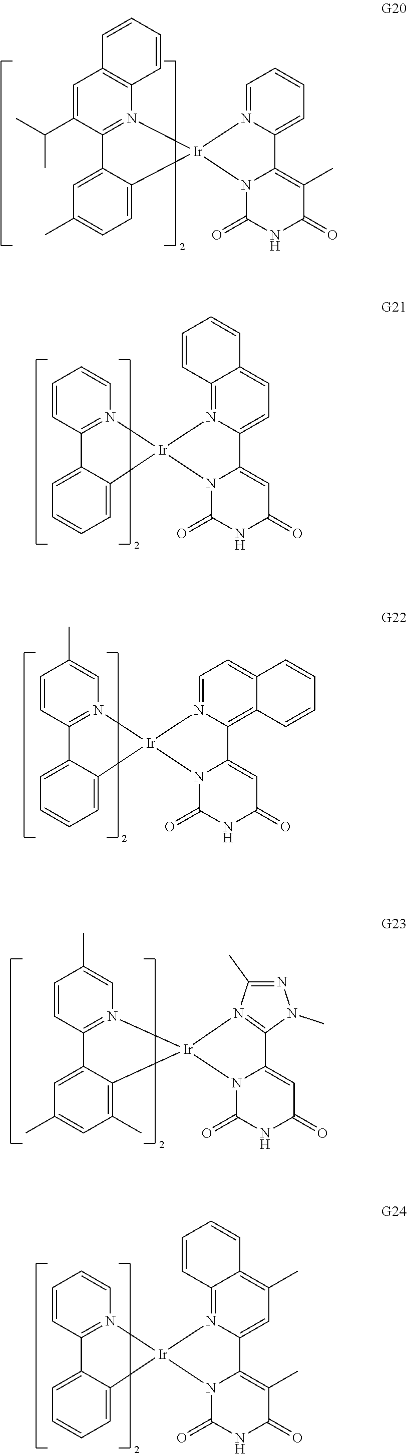

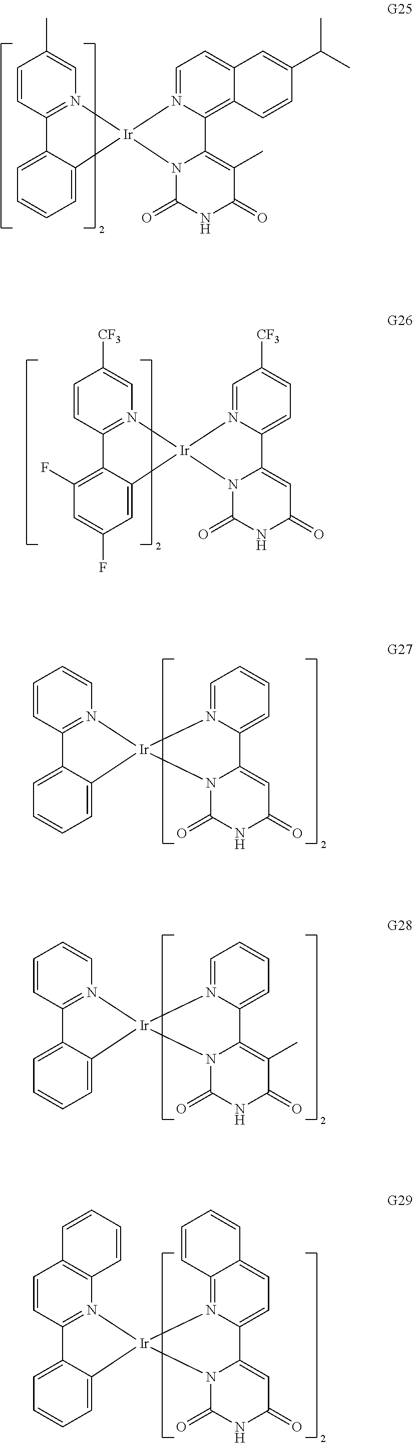

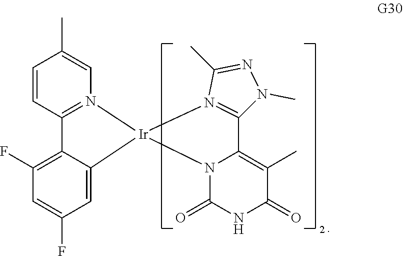

7. Use of the compound according to claim 1 as a material for a functional layer of an organic electroluminescent device.

8. The use according to claim 7, wherein the functional layer is a luminescent layer.

9. The use according to claim 8, wherein the luminescent layer has an evaporation temperature of 330 to 370° C.

10. A guest material of luminescent layer, comprising at least one of the compound according to claim 1.

11. An organic electroluminescent device, comprising at least one of the guest material of luminescent layer according to claim 10.

12. A display device, comprising the organic electroluminescent device according to claim 11.
